(19) United States
(12) Patent Application Publication
(10) Pub. No.: US 2024/0321886 A1
(43) Pub. Date: Sep. 26, 2024

(54) STACKED INTEGRATED CIRCUIT DEVICES

(71) Applicant: Samsung Electronics Co., Ltd., Suwon-si (KR)

(72) Inventors: Kyunghee Cho, Suwon-si (KR); Myungil Kang, Suwon-si (KR); Kyungho Kim, Suwon-si (KR); Kyowook Lee, Suwon-si (KR); Seunghun Lee, Suwon-si (KR)

(21) Appl. No.: 18/605,400

(22) Filed: Mar. 14, 2024

(30) Foreign Application Priority Data
Mar. 21, 2023 (KR) 10-2023-0036922

(51) Int. Cl. H01L 27/092; H01L 29/06; H01L 29/417; H01L 29/423; H01L 29/775; H01L 29/786

(52) U.S. Cl. CPC H01L 27/092; H01L 29/0673; H01L 29/41733; H01L 29/42392; H01L 29/775; H01L 29/78696

(57) ABSTRACT

A stacked integrated circuit device includes a plurality of transistors including a pair of pull-up transistors in a first layer, a pair of pull-down transistors in a second layer that is at a different vertical level than the first layer, and a pair of pass-gate transistors in the first or second layer, a contact configured to electrically connect a source/drain region of one of the pull-up transistors, a source/drain region of one of the pull-down transistors, and a source/drain region of one of the pass-gate transistors to one another, a gate contact configured to connect a gate electrode of the other pull-up transistor to a gate electrode of the other pull-down transistor, and an upper wire on the contact and the gate contact, the upper wire extending in a first horizontal direction and being connected to the contact and the gate contact.

### CROSS-REFERENCE TO RELATED APPLICATION

This application is based on and claims priority under 35 U.S.C. § 119 to Korean Patent Application No. 10-2023-0036922, filed on Mar. 21, 2023, in the Korean Intellectual Property Office, the disclosure of which is incorporated by reference herein in its entirety.

### BACKGROUND

This disclosure relates to integrated circuit devices, and more particularly, to stacked integrated circuit devices.

With the development of electronics technology, down-scaling of integrated circuit devices has rapidly progressed. In addition, to increase the integration density of integrated circuit devices, there has been research into stacked integrated circuit devices.

### SUMMARY

This disclosure provides stacked integrated circuit devices having increased operational reliability and reduced difficulty in manufacturing processes. Connecting nodes of transistors in the stacked integrated circuit via an upper wire allows for more flexibility in arranging the transistors without sacrificing performance criteria. Additionally, conventional processes for arranging the transistors can be used with the disclosed techniques, thereby reducing the difficulty of creating stacked integrated circuits with a high degree of integration. For example, a shared contact for the transistors can be formed through the upper wire, thus avoiding the necessity of using a separate photomask to form the shared contact.

In general, innovative aspects of the subject matter described in this specification can be embodied in a stacked integrated circuit device including a plurality of transistors including a pair of pull-up transistors in a first layer, a pair of pull-down transistors in a second layer that is at a different vertical level than the first layer, and a pair of pass-gate transistors in one of the first layer and the second layer, a contact configured to electrically connect a source/drain region of one pull-up transistor of the pair of pull-up transistors, a source/drain region of one pull-down transistor of the pair of pull-down transistors, and a source/drain region of one pass-gate transistor of the pair of pass-gate transistors to one another, a gate contact configured to connect a gate electrode of the other pull-up transistor to a gate electrode of the other pull-down transistor, and an upper wire on the contact and the gate contact, the upper wire extending in a first horizontal direction and being connected to the contact and the gate contact.

Another innovative aspect of the subject matter described in this specification can be embodied in a stacked integrated circuit device including a plurality of nanosheets extending in a first horizontal direction, a plurality of gate electrodes extending in a second horizontal direction that is orthogonal to the first horizontal direction, a plurality of transistors respectively formed at intersections between the plurality of nanosheets and the plurality of gate electrodes, the plurality of transistors including a pair of first transistors in a first layer, a pair of second transistors in a second layer that is at a higher vertical level than the first layer, and a pair of third transistors in one of the first layer and the second layer, a plurality of lower contacts connected to respective source/drain regions of transistors in the first layer among the plurality of transistors, a plurality of upper contacts connected to respective source/drain regions of transistors in the second layer among the plurality of transistors, a plurality of gate contacts connected to the plurality of gate electrodes, a plurality of via contacts configured to connect the plurality of lower contacts to the plurality of upper contacts overlapping with the plurality of lower contacts in a vertical direction, and a plurality of upper wires connected to the plurality of upper contacts and the plurality of gate contacts, wherein a source/drain region of one first transistor of the pair of first transistors is connected to one lower contact among the plurality of lower contacts, a source/drain region of one second transistor of the pair of second transistors is connected to one upper contact among the plurality of upper contacts, a source/drain region of one third transistor of the pair of third transistors is connected to one of the one lower contact and the one upper contact, the one lower contact and one upper contact are electrically connected to each other by one via contact among the plurality of via contacts, one gate electrode among the plurality of gate electrodes includes a gate electrode of the other first transistor and a gate electrode of the other second transistor and is connected to one gate contact among the plurality of gate contacts, and the one upper contact and the one gate contact are connected to one upper wire among the plurality of upper wires.

Another innovative aspect of the subject matter described in this specification can be embodied in a stacked integrated circuit device including a plurality of nanosheets extending in a first horizontal direction, a plurality of gate electrodes extending in a second horizontal direction that is orthogonal to the first horizontal direction, a plurality of transistors respectively formed at intersections between the plurality of nanosheets and the plurality of gate electrodes, the plurality of transistors including a pair of pull-up transistors in a first layer, a pair of pull-down transistors in a second layer that is at a higher vertical level than the first layer, and a pair of pass-gate transistors in the second layer, and some of the plurality of transistors forming static random access memory (SRAM), a plurality of lower contacts connected to respective source/drain regions of the pair of pull-up transistors, a plurality of upper contacts connected to respective source/drain regions of the pair of pull-down transistors and the pair of pass-gate transistor, a plurality of gate contacts connected to the plurality of gate electrodes, a plurality of via contacts configured to connect a lower contact among the plurality of lower contacts to an upper contact among the plurality of upper contacts, the lower contact overlapping with the upper contact in a vertical direction, and a plurality of upper wires connected to the plurality of upper contacts and the plurality of gate contacts, the plurality of upper wires extending in the first horizontal direction and being in a third layer that is at a higher vertical level than the second layer, wherein a source/drain region of one pull-up transistor of the pair of pull-up transistors is connected to one lower contact among the plurality of lower contacts, a source/drain region of one pull-down transistor of the pair of pull-down transistors and a source/drain region of one pass-gate transistor of the pair of pass-gate transistors is connected to one upper contact among the plurality of upper contacts, the one lower contact and one upper contact are electrically connected to each other by one via contact among the plurality of via contacts, one gate electrode among the plurality of gate electrodes includes a gate electrode of the other pull-up transistor and a gate electrode of the other pull-down transistor and is connected to one gate contact among the plurality of gate contacts, and the one upper contact and the one gate contact are connected to one upper wire among the plurality of upper wires.

### BRIEF DESCRIPTION OF THE DRAWINGS

FIG. 1 is an example of an equivalent circuit diagram of a stacked integrated circuit device.

FIGS. 2A to 2C are examples of conceptual diagrams illustrating the configurations of stacked integrated circuit devices.

FIG. 3 is a schematic perspective view of one of the stacked integrated circuit devices of FIG. 2A. FIGS. 4A to 4D show schematic layouts of the stacked integrated circuit device of FIG. 3.

FIGS. 5A to 5E are cross-sectional views taken along parts of a line of FIGS. 4A-4D.

FIGS. 6A and 6B are cross-sectional views of examples of stacked integrated circuit devices.

FIGS. 7A to 7E show schematic layouts of an example of a stacked integrated circuit device.

FIG. 8 is a schematic perspective view of one of the stacked integrated circuit devices of FIG. 2A. FIGS. 9A to 9D show schematic layouts of an example of the stacked integrated circuit device of FIG. 8.

FIGS. 10A to 10E are cross-sectional views illustrating an example of the stacked integrated circuit device of FIG. 8.

FIGS. 11A to 11F show schematic layouts of an example of a stacked integrated circuit device.

FIG. 12 is a schematic perspective view of one of the stacked integrated circuit devices of FIG. 2B. FIGS. 13A to 13D show schematic layouts of the stacked integrated circuit device of FIG. 12.

FIGS. 14A to 14E are cross-sectional views illustrating the stacked integrated circuit device of FIG. 12.

FIGS. 15A to 15F show schematic layouts of an example of a stacked integrated circuit device.

FIG. 16 is a schematic perspective view of one of the stacked integrated circuit devices of FIG. 2B. FIGS. 17A to 17D show schematic layouts of an example of the stacked integrated circuit device of FIG. 16.

FIGS. 18A to 18E are cross-sectional views illustrating an example of the stacked integrated circuit device of FIG. 16.

FIGS. 19A to 19E show schematic layouts of an example of a stacked integrated circuit device.

FIG. 20, FIGS. 21A and 21B, FIGS. 22A to 22D, FIGS. 23A to 23D, FIGS. 24A to 24D, FIGS. 25A to 25D, FIGS. 26A to 26D, FIGS. 27A to 27D, FIGS. 28A to 28D, FIGS. 29A to 29D, FIGS. 30A to 30D, FIGS. 31A to 31D, FIGS. 32A to 32E, FIGS. 33A to 33E, FIGS. 34A to 34E, FIGS. 35A to 35E, FIGS. 36A to 36E, FIGS. 37A to 37E, FIGS. 38A to 38E, and FIGS. 39A to 39E are cross-sectional views of stages in an example of a method of manufacturing a stacked integrated circuit device.

### DETAILED DESCRIPTION OF THE EMBODIMENTS

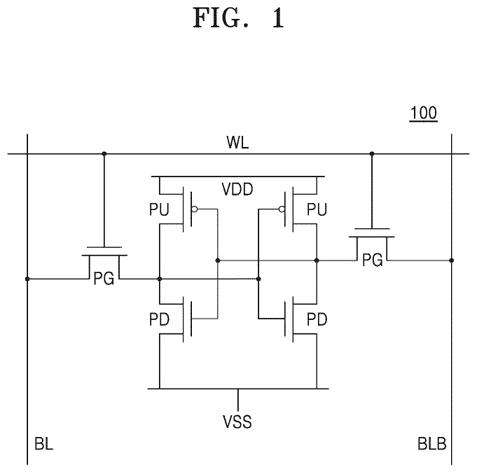

FIG. 1 is an example of an equivalent circuit diagram of a stacked integrated circuit device 100.

Referring to FIG. 1, the stacked integrated circuit device 100 may include a plurality of transistors. At least some of the transistors may form static random access memory (SRAM). SRAM is a type of RAM that uses a latching circuit to store at least one bit. FIG. 1 shows an equivalent circuit of the SRAM included in the stacked integrated circuit device 100.

The SRAM may include six metal-oxide semiconductor field-effect transistors (MOSFETs). The six MOSFETs may include two pull-up transistors PU, two pull-down transistors PD, and two pass-gate transistors PG. A pull-up transistor PU and a pull-down transistor PD corresponding thereto may form an inverter, and two inverters constituted by two pull-up transistors PU and two pull-down transistors PD may be cross-connected to each other. For example, the gate of the pull-up transistor PU of one inverter and the gate of the pull-down transistor PD of the inverter may be respectively connected to the source of the pull-up transistor PU of the other inverter and the source of the pull-down transistor PD of the other inverter. Two pass-gate transistors PG may control access during read and write operations performed on a memory cell that includes two inverters cross-connected to each other. For example, the source of one pass-gate transistor PG may be electrically connected to the respective sources of a pull-up transistor PU and a pull-down transistor PD of one inverter and the respective gates of a pull-down transistor PD and a pull-up transistor PU of the other inverter, the gate of the pass-gate transistor PG may be electrically connected to a word line WL, and the drain of the pass-gate transistor PG may be electrically connected to a bit line BL. The source of the other pass-gate transistor PG may be electrically connected to the respective gates of the pull-up transistor PU and the pull-down transistor PD of one inverter and the respective sources of the pull-down transistor PD and the pull-up transistor PU of the other inverter, the gate of the pass-gate transistor PG may be electrically connected to the word line WL, and the drain of the pass-gate transistor PG may be electrically connected to a complementary bit line BLB. The drain of a pull-up transistor PU may be connected to a power supply VDD, and the drain of a pull-down transistor PD may be connected to a ground VSS.

During a read operation, the word line WL may be set to be high (e.g., logic state “1”) so that two pass-gate transistors PG activate access to a memory cell. When the word line WL is activated, a value (e.g., “0” or “1”) of the memory cell may be read through the bit line BL and/or the complementary bit line BLB. For example, when the logic state “1” is stored in the memory cell and the word line WL turns on the two pass-gate transistors PG, the bit line BL may read “1” and the complementary bit line BLB may read “0”. During a write operation, for example, when a command is executed to write “1” to the memory cell, the word line WL may be set to be high such that the two pass-gate transistors PG are turned on and the bit line BL may be set to a high voltage to override a value “0” stored in the memory cell. Accordingly, at least one bit may be stored in the SRAM and accessed.

Each of two pull-up transistors PU may be an n-type MOS (NMOS) transistor and each of two pull-up transistors PU may be a p-type MOS (PMOS) transistor. Both pass-gate transistors PG may be NMOS transistors or PMOS transistors.

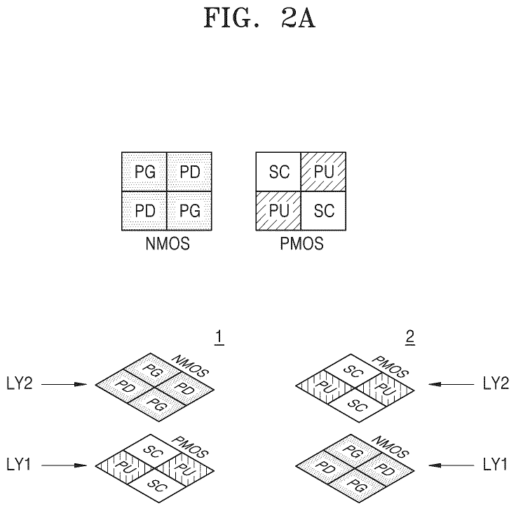

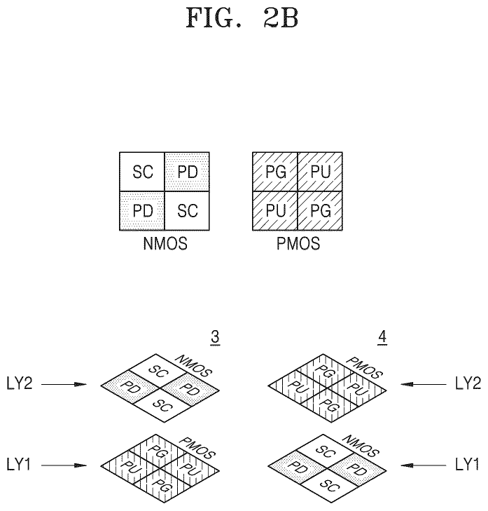

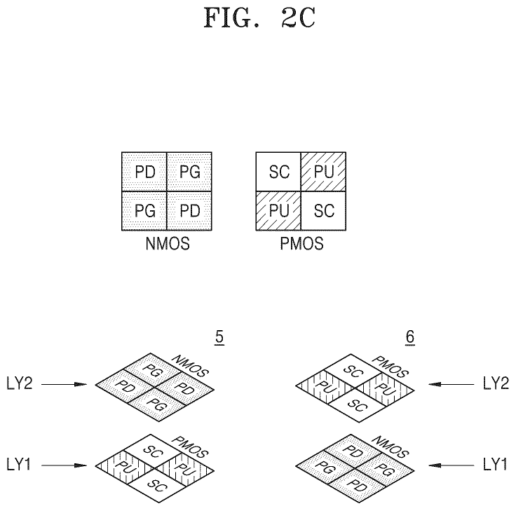

FIGS. 2A to 2C are conceptual diagrams illustrating the configurations of examples of stacked integrated circuit devices 1-6.

Referring to FIG. 2A, each of the stacked integrated circuit devices 1 and 2 may include SRAM, which includes two PMOS transistors corresponding to two pull-up transistors PU, two NMOS transistors corresponding to two pull-down transistors PD, and two NMOS transistors corresponding to two pass-gate transistors PG. Each of the stacked integrated circuit devices 1 and 2 may have a stack structure that includes a first layer LY1 and a second layer LY2 at different vertical levels. For example, each of the stacked integrated circuit devices 1 and 2 may have a stack structure in which the second layer LY2 is on the first layer LY1. The configurations of the first layer LY1 and the second layer LY2 of the stacked integrated circuit device 1 may be opposite to the configurations of the first layer LY1 and the second layer LY2 of the stacked integrated circuit device 2.

The stacked integrated circuit device 1 may have PMOS transistors in the first layer LY1 and NMOS transistors in the second layer LY2. In other words, the stacked integrated circuit device 1 may have two PMOS transistors corresponding to two pull-up transistors PU in the first layer LY1 and two NMOS transistors corresponding to two pull-down transistors PD and two NMOS transistors corresponding to two pass-gate transistors PG in the second layer LY2. Two shared contact structures SC may be in the first layer LY1 of the stacked integrated circuit device 1. The two pull-up transistors PU may be arranged in a diagonal direction, the two pull-down transistors PD may be arranged in a diagonal direction, and the two pass-gate transistors PG may be arranged in a diagonal direction. The pull-down transistors PD may be respectively on the pull-up transistors PU and the pass-gate transistors PG may be respectively on the shared contact structures SC.

The stacked integrated circuit device 2 may have NMOS transistors in the first layer LY1 and PMOS transistors in the second layer LY2. In other words, the stacked integrated circuit device 2 may have two NMOS transistors corresponding to two pull-down transistors PD and two NMOS transistors corresponding to two pass-gate transistors PG in the first layer LY1 and two PMOS transistors corresponding to two pull-up transistors PU in the second layer LY2. Two shared contact structures SC may be in the second layer LY2 of the stacked integrated circuit device 2. The pull-up transistors PU may be respectively on the pull-down transistors PD and the shared contact structures SC may be respectively on the pass-gate transistors PG.

A shared contact structure SC may have a similar configuration to a transistor in the same layer but may not include some components of the transistor so as not to operate as a transistor. For example, some of a shared contact structure SC may perform the function of a shared contact by electrically connecting a gate electrode of a pull-up transistor PU, a gate electrode of a pull-down transistor PD, a source/drain region of another pull-up transistor PU, a source/drain region of another pull-down transistor PD, and a source/drain region of a pass-gate transistor PG to one another. Some of another shared contact structure SC may perform the function of a shared contact by electrically connecting a source/drain region of a pull-up transistor PU, a source/drain region of a pull-down transistor PD, a gate electrode of another pull-down transistor PD, a gate electrode of another pull-up transistor PU, and a source/drain region of another pass-gate transistor PG to one another. In the implementations illustrated herein, the phrase source/drain region may be understood to mean a source terminal region or a drain terminal region of a transistor.

Here, a shared contact may refer to electrical connection among three source/drain regions and two gate electrodes of five transistors, and some components of a shared contact structure SC may perform at least part of the function of the shared contact.

For example, one transistor may include a channel region, a pair of source/drain regions, a gate electrode, and a pair of source/drain electrodes connected to the pair of source/drain regions. A shared contact structure SC may not include one source/drain region and one source/drain electrode connected thereto among the source/drain regions and the source/drain electrodes included in one transistor such that the other source/drain electrode connected to the other source/drain region may perform at least part of the function of a shared contact. A gate electrode of the shared contact structure SC may correspond to a dummy gate electrode that is not used for the operation of the stacked integrated circuit device 1 or 2.

Referring to FIG. 2B, each of the stacked integrated circuit devices 3 and 4 may include SRAM, which includes two PMOS transistors corresponding to two pull-up transistors PU, two NMOS transistors corresponding to two pull-down transistors PD, and two PMOS transistors corresponding to two pass-gate transistors PG. Each of the stacked integrated circuit devices 3 and 4 may have a stack structure in which the second layer LY2 is on the first layer LY1. The configurations of the first layer LY1 and the second layer LY2 of the stacked integrated circuit device 3 may be opposite to the configurations of the first layer LY1 and the second layer LY2 of the stacked integrated circuit device 4.

The stacked integrated circuit device 3 may have PMOS transistors in the first layer LY1 and NMOS transistors in the second layer LY2. In other words, the stacked integrated circuit device 3 may have two PMOS transistors corresponding to two pull-up transistors PU and two PMOS transistors corresponding to two pass-gate transistors PG in the first layer LY1 and two NMOS transistors corresponding to two pull-down transistors PD in the second layer LY2.

Two shared contact structures SC may be in the second layer LY2 of the stacked integrated circuit device 3. The pull-down transistors PD may be respectively on the pull-up transistors PU and the shared contact structures SC may be respectively on the pass-gate transistors PG.

The stacked integrated circuit device 4 may have NMOS transistors in the first layer LY1 and PMOS transistors in the second layer LY2. In other words, the stacked integrated circuit device 4 may have two NMOS transistors corresponding to two pull-down transistors PD in the first layer LY1 and two PMOS transistors corresponding to two pull-up transistors PU and two PMOS transistors corresponding to two pass-gate transistors PG in the second layer LY2. Two shared contact structures SC may be in the first layer LY1 of the stacked integrated circuit device 4. The pull-up transistors PU may be respectively on the pull-down transistors PD and the pass-gate transistors PG may be respectively on the shared contact structures SC.

Referring to FIG. 2C, each of the stacked integrated circuit devices 5 and 6 may include SRAM, which includes two PMOS transistors corresponding to two pull-up transistors PU, two NMOS transistors corresponding to two pull-down transistors PD, and two NMOS transistors corresponding to two pass-gate transistors PG. Each of the stacked integrated circuit devices 5 and 6 may have a stack structure in which the second layer LY2 is on the first layer LY1. The configurations of the first layer LY1 and the second layer LY2 of the stacked integrated circuit device 5 may be opposite to the configurations of the first layer LY1 and the second layer LY2 of the stacked integrated circuit device 6.

The stacked integrated circuit device 5 may have PMOS transistors in the first layer LY1 and NMOS transistors in the second layer LY2. In other words, the stacked integrated circuit device 5 may have two PMOS transistors corresponding to two pull-up transistors PU in the first layer LY1 and two NMOS transistors corresponding to two pull-down transistors PD and two NMOS transistors corresponding to two pass-gate transistors PG in the second layer LY2.

Two shared contact structures SC may be in the first layer LY1 of the stacked integrated circuit device 5. The pass-gate transistors PG may be respectively on the pull-up transistors PU and the pull-down transistors PD may be respectively on the shared contact structures SC.

The stacked integrated circuit device 6 may have NMOS transistors in the first layer LY1 and PMOS transistors in the second layer LY2. In other words, the stacked integrated circuit device 6 may have two NMOS transistors corresponding to two pull-down transistors PD and two NMOS transistors corresponding to two pass-gate transistors PG in the first layer LY1 and two PMOS transistors corresponding to two pull-up transistors PU in the second layer LY2. Two shared contact structures SC may be in the second layer LY2 of the stacked integrated circuit device 6. The pull-up transistors PU may be respectively on the pass-gate transistors PG and the shared contact structures SC may be respectively on the pull-down transistors PD.

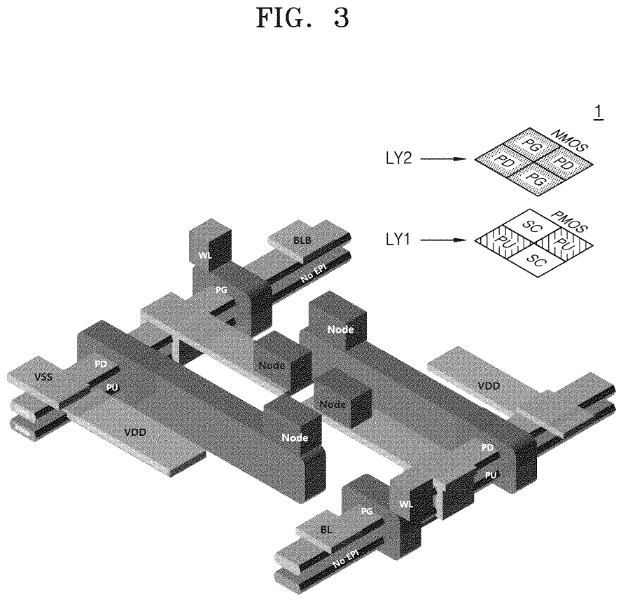

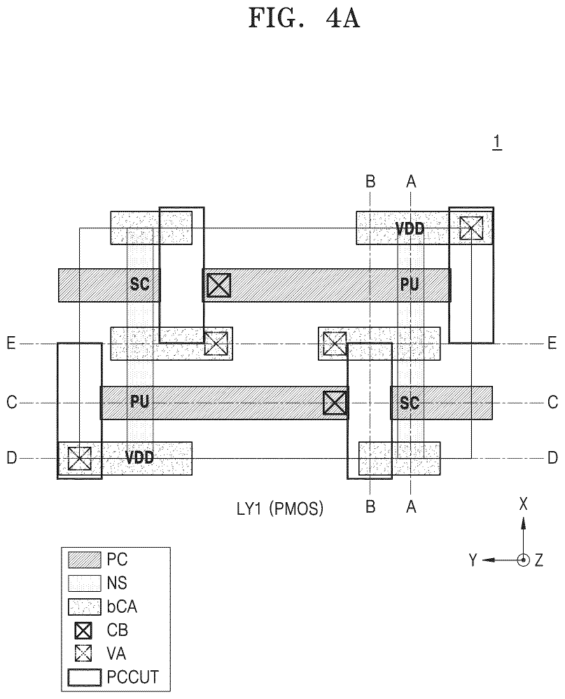

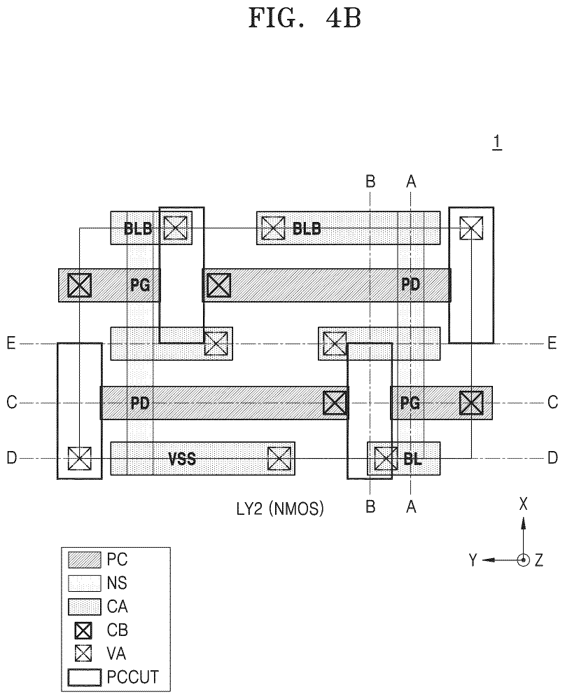

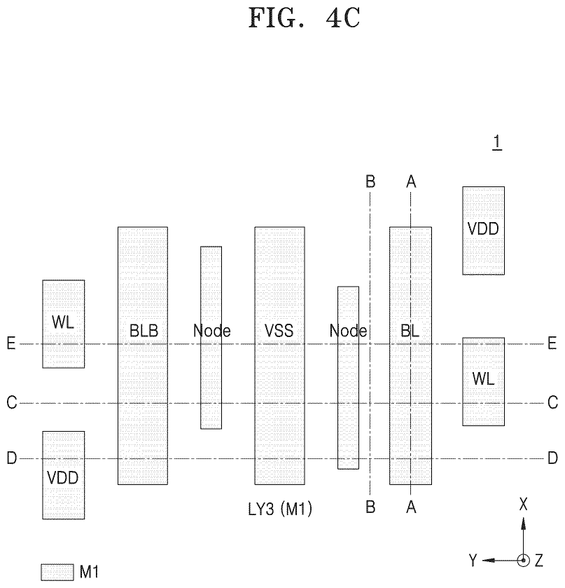

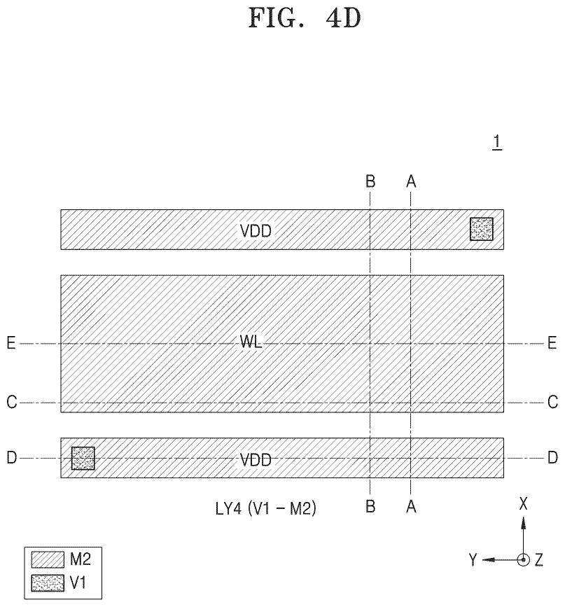

FIG. 3 is a schematic perspective view of the stacked integrated circuit device 1, and FIGS. 4A to 4D show schematic layouts of the stacked integrated circuit device 1.

Referring to FIGS. 3 to 4D, the stacked integrated circuit device 1 may include SRAM which includes two PMOS transistors corresponding to two pull-up transistors PU, two NMOS transistors corresponding to two pull-down transistors PD, and two NMOS transistors corresponding to two pass-gate transistors PG. The two pull-up transistors PU may be arranged in a direction that is diagonal to a first horizontal direction (the X direction) and a second horizontal direction (the Y direction), the two pull-down transistors PD may be arranged in a direction that is diagonal to the first horizontal direction (the X direction) and the second horizontal direction (the Y direction), and the two pass-gate transistors PG may be arranged in a direction that is diagonal to the first horizontal direction (the X direction) and the second horizontal direction (the Y direction).

The stacked integrated circuit device 1 may include a nanosheet NS, which extends in the first horizontal direction (the X direction), and a gate electrode PC, which extends in the second horizontal direction (the Y direction) that is orthogonal to the first horizontal direction (the X direction). A transistor of the first layer LY1 and a transistor of the second layer LY2, which overlap with each other in the vertical direction (the Z direction), may share one gate electrode PC with each other. Portions of a nanosheet NS and portions of a gate electrode PC, which respectively cross the portion of the nanosheet NS, may form transistors, e.g., a pull-up transistor PU, a pull-down transistor PD, and a pass-gate transistor PG. A portion No EPI (“no epitaxial”) among the portions of the nanosheet NS and the portions of the gate electrode PC, which respectively cross the portion of the nanosheet NS, may correspond to a shared contact structure SC that does not have an epitaxial layer forming a source/drain region. A gate electrode PC, which has a portion crossing a portion of a nanosheet NS of a shared contact structure SC and extends in the second horizontal direction (the Y direction), may be divided into at least two parts by a gate cut region PCCUT that extends in the first horizontal direction (the X direction). A plurality of gate cut regions PCCUT may be arranged in line in the second horizontal direction (the Y direction) and a plurality of gate cut regions PCCUT may be arranged in zigzag in the first horizontal direction (the X direction). A single gate cut region PCCUT may divide only a single gate electrode PC into two parts.

An upper contact CA and a lower contact bCA may be connected to source/drain regions of transistors including a pull-up transistor PU, a pull-down transistor PD, and a pass-gate transistor PG. The upper contact CA and the lower contact bCA may extend in the second horizontal direction (the Y direction). The upper contact CA may be connected to the ground VSS, the bit line BL, and the complementary bit line BLB. The lower contact bCA may be connected to the power supply VDD. The upper contact CA and the lower contact bCA may be referred to as a first contact and a second contact, respectively, or the second contact and the first contact, respectively.

A gate contact CB may be connected to a gate electrode PC. A via contact VA may be connected to the upper contact CA and the lower contact bCA, which connect three respective source/drain regions of the pull-up transistor PU, the pull-down transistor PD, and the pass-gate transistor PG. For example, the via contact VA may extend in the vertical direction (the Z direction) to connect some of a plurality of upper contacts CA to some of a plurality of lower contacts bCA, wherein the upper contacts CA respectively overlap with and correspond to the lower contacts bCA in the vertical direction (the Z direction).

The via contact VA connected to the upper contact CA, which connects three respective source/drain regions of the pull-up transistor PU, the pull-down transistor PD, and the pass-gate transistor PG, may be aligned with the gate contact CB connected to the gate electrode PC, which is shared by another pull-up transistor PU and another pull-down transistor PD in different layers, in the first horizontal direction (the X direction).

A plurality of first upper wires M1 may be in a third layer LY3 that is at a higher vertical level than the second layer LY2. The first upper wires M1 may extend in the first horizontal direction (the X direction). Each of the first upper wires M1 may correspond to the power supply VDD, the ground VSS, the word line WL, the bit line BL, the complementary bit line BLB, or a shared node Node. A first upper wire M1 corresponding to the shared node Node may connect the via contact VA to the gate contact CB, where the via contact VA and the gate contact CB are aligned with each other in the first horizontal direction (the X direction). Accordingly, a shared contact, which connects, to one another, three respective source/drain regions of a pull-up transistor PU, a pull-down transistor PD, and a pass-gate transistor PG and a gate electrode of each of another pull-up transistor PU and another pull-down transistor PD that are in different layers from each other, may be electrically connected to the first upper wire M1 corresponding to the shared node Node. The first upper wire M1 corresponding to the shared node Node may extend in the first horizontal direction (the X direction) and may be connected only to the via contact VA and the gate contact CB, which constitute the shared contact.

A plurality of second upper wires M2 may be in a fourth layer LY4 that is at a higher vertical level than the third layer LY3. A first upper wire M1 may be connected to a second upper wire M2 by a first upper via V1. The second upper wires M2 may extend in the second horizontal direction (the Y direction). Each of the second upper wires M2 may correspond to the power supply VDD or the word line WL. The first upper wire M1, the second upper wire M2, and the first upper via V1 may be respectively referred to as a first wire, a second wire, and a first via.

Because the stacked integrated circuit device 1 includes a pass-gate transistor PG that is an NMOS transistor, the stacked integrated circuit device 1 may have current-voltage (I-V) distribution characteristics similar to those of an integrated circuit device having SRAM implemented in a single layer and thus have increased operational reliability. Because a shared contact is formed through the first upper wire M1, a separate photomask for forming the shared contact is not required, and therefore, the difficulty in processes may be reduced.

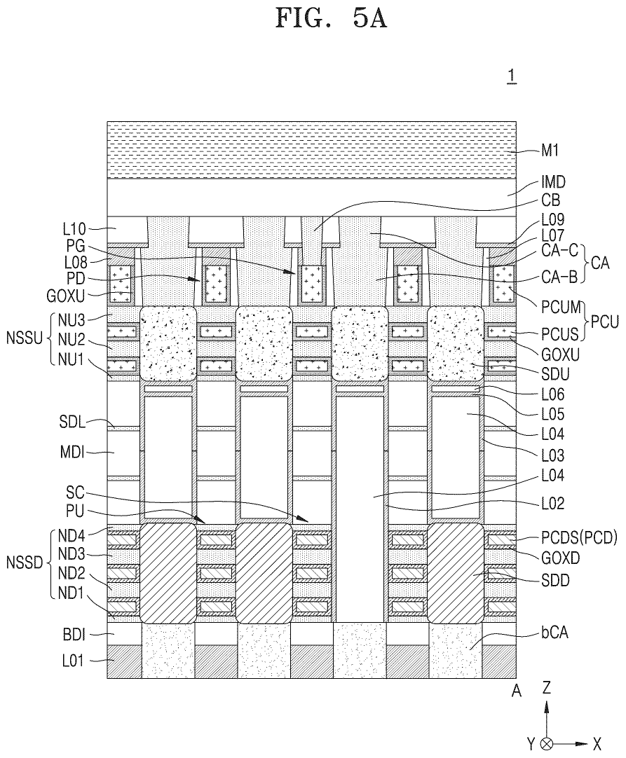

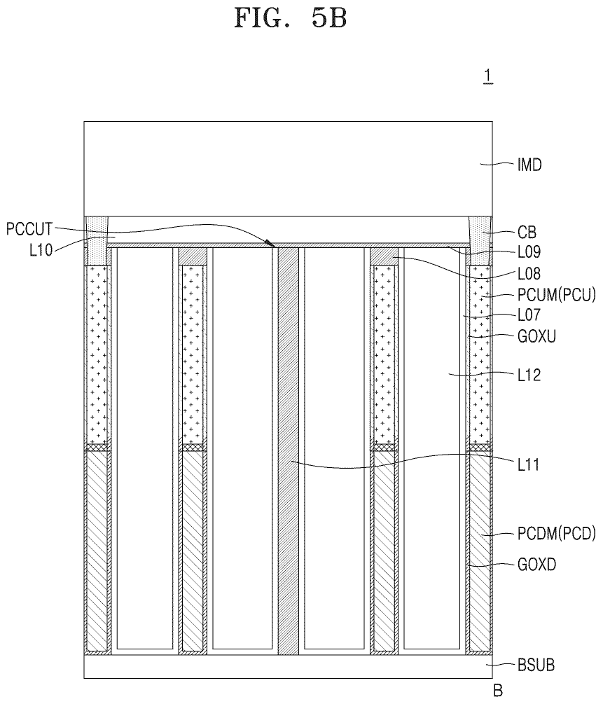

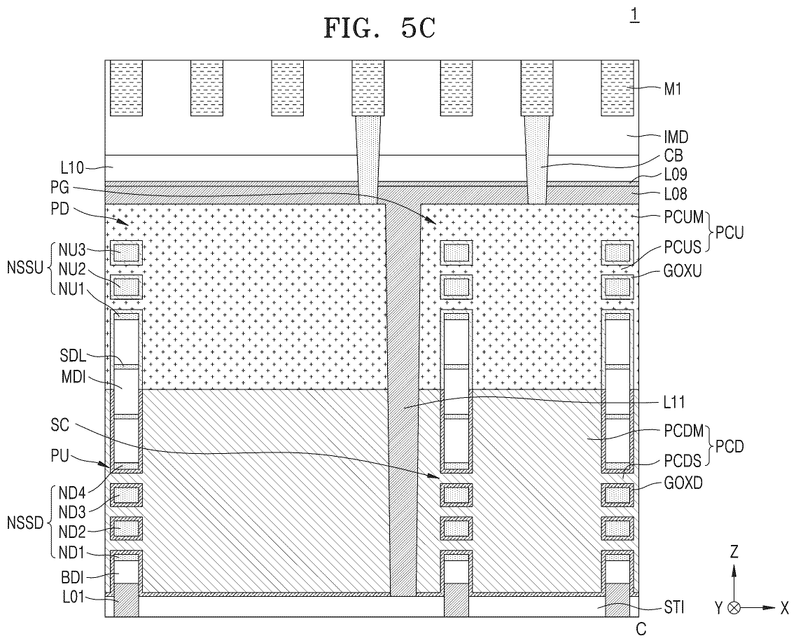

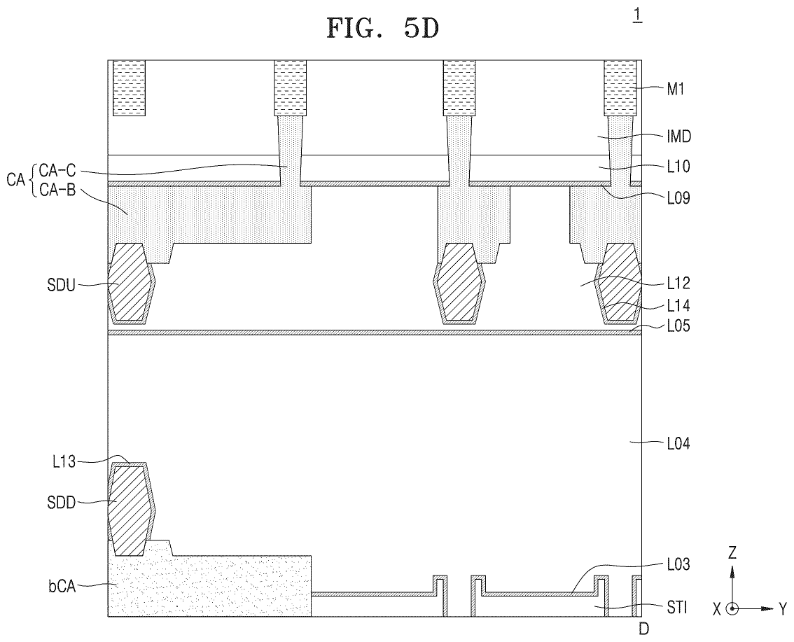

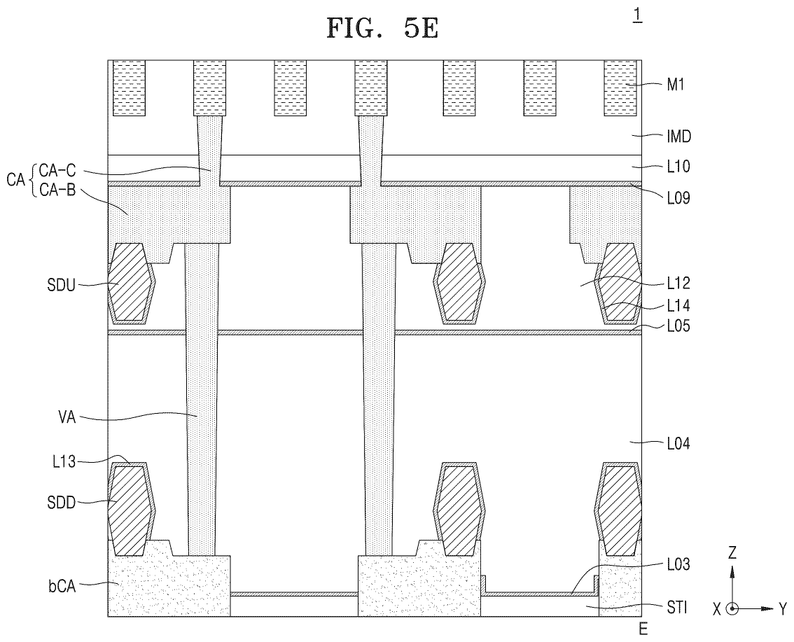

FIGS. 5A to 5E are cross-sectional views illustrating the stacked integrated circuit device 1. In detail, FIGS. 5A to 5E are cross-sectional views respectively taken along parts of lines A-A, B-B, C-C, D-D, and E-E, respectively, in FIGS. 4A to 4D.

Referring to FIGS. 5A to 5E, the stacked integrated circuit device 1 may include a lower nanosheet stack structure NSSD, which includes a plurality of lower nanosheets ND1, ND2, ND3, and ND4, and an upper nanosheet stack structure NSSU, which is above the lower nanosheet stack structure NSSD and includes a plurality of upper nanosheets NU1, NU2, and NU3. The lower nanosheet stack structure NSSD may be in the first layer LY1 in FIGS. 3 to 4D and the upper nanosheet stack structure NSSU may be in the second layer LY2 in FIGS. 3 to 4D. Each of the lower nanosheets ND1, ND2, ND3, and ND4 and the upper nanosheets NU1, NU2, and NU3 may extend in the first horizontal direction (the X direction). A lower source/drain region SDD may be at a side of the lower nanosheet stack structure NSSD in the first horizontal direction (the X direction) and may be connected to the lower nanosheets ND1, ND2, ND3, and ND4. An upper source/drain region SDU may be at a side of the upper nanosheet stack structure NSSU in the first horizontal direction (the X direction) and may be connected to the upper nanosheets NU1, NU2, and NU3. The lower source/drain region SDD may correspond to the source/drain region of a pull-up transistor PU. The upper source/drain region SDU may be shared, as a source/drain region, by a pull-down transistor PD and a pass-gate transistor PG, which are adjacent to each other in the first horizontal direction (the X direction).

A lower gate electrode PCD may surround the lower nanosheets ND1, ND2, ND3, and ND4. The lower gate electrode PCD may include a sub lower gate electrode PCDS, which is arranged among the lower nanosheets ND1, ND2, ND3, and ND4, and a main lower gate electrode PCDM, which surrounds the lower nanosheets ND1, ND2, ND3, and ND4 and the sub lower gate electrode PCDS. A lower gate insulating film GOXD may be between the lower gate electrode PCD and each of the lower nanosheets ND1, ND2, ND3, and ND4.

A lower insulating structure BDI may be below the lower nanosheet stack structure NSSD. A middle insulating structure MDI may be between the lower nanosheet stack structure NSSD and the upper nanosheet stack structure NSSU. A first insulating layer L01 may be below the lower insulating structure BDI. In some implementations, a plurality of middle insulating structures MDI are stacked in the vertical direction (the Z direction), and a slit semiconductor layer SDL is between the middle insulating structures MDI. Lower side surfaces of the middle insulating structures MDI and the slit semiconductor layer SDL and the top surface of the lower source/drain region SDD may be covered with a second insulating layer L02. Upper side surfaces of the middle insulating structures MDI and the slit semiconductor layer SDL may be covered with a third insulating layer L03. A fourth insulating layer L04 may fill a space defined by the second insulating layer L02 and the third insulating layer L03. A fifth insulating layer L05 may be on the fourth insulating layer L04, and a sixth insulating layer L06 may fill a space defined by the fifth insulating layer L05. A lower contact bCA connected to the lower source/drain region SDD may be below the lower source/drain region SDD.

An upper gate electrode PCU may surround the upper nanosheets NU1, NU2, and NU3. The upper gate electrode PCU may include a sub upper gate electrode PCUS, which is arranged among the upper nanosheets NU1, NU2, and NU3, and a main upper gate electrode PCUM, which surrounds the upper nanosheets NU1, NU2, and NU3 and the sub upper gate electrode PCUS. An upper gate insulating film GOXU may be between the upper gate electrode PCU and each of the upper nanosheets NU1, NU2, and NU3.

An upper contact CA connected to the upper source/drain region SDU may be on the upper source/drain region SDU. The upper contact CA may include a base part CA-B and a contact part CA-C on the base part CA-B. The base part CA-B may extend in the second horizontal direction (the Y direction). The width of the contact part CA-C in the first horizontal direction (the X direction) may be similar to or the same as the width of the contact part CA-C in the second horizontal direction (the Y direction). A side surface of the base part CA-B may be covered with a seventh insulating layer L07.

An eighth insulating layer L08 may be on the main upper gate electrode PCUM. The seventh insulating layer L07 may be between the base part CA-B and a stack structure of the main upper gate electrode PCUM and the eighth insulating layer L08. A ninth insulating layer L09 may be on the seventh insulating layer L07 and the eighth insulating layer L08. The ninth insulating layer L09 may cover a portion of the top surface of the base part CA-B, the top surface of the seventh insulating layer L07, and the top surface of the eighth insulating layer L08. A tenth insulating layer L10 may be on the ninth insulating layer L09. The contact part CA-C may be in the space defined by the side surfaces of the ninth insulating layer L09 and the tenth insulating layer L10.

A gate contact CB may pass through the tenth insulating layer L10, the ninth insulating layer L09, and the eighth insulating layer L08 to be in contact with the top surface of the upper gate electrode PCU, for example, the top surface of the main upper gate electrode PCUM. In some implementations, the contact part CA-C and the gate contact CB may be formed together.

An inter-wire insulating layer IMD may be on the upper contact CA, the gate contact CB, and the tenth insulating layer L10. A first upper wire M1 may be on the inter-wire insulating layer IMD. The second upper wire M2 and the first upper via V1 in FIG. 4D are omitted from FIGS. 5A to 5E.

The lower gate electrode PCD and the upper gate electrode PCU may overlap with each other in the vertical direction (the Z direction). The lower gate electrode PCD and the upper gate electrode PCU overlapping with each other in the vertical direction (the Z direction) may correspond to a gate electrode PC in FIGS. 4A and 4B. A plurality of lower gate electrodes PCD and a plurality of upper gate electrodes PCU respectively overlapping with the lower gate electrodes PCD in the vertical direction (the Z direction), i.e., a plurality of gate electrodes PC, may extend in the second horizontal direction (the Y direction) and may be separated from each other at substantially regular intervals in the first horizontal direction (the X direction). The seventh insulating layer L07 may be on the side surfaces of the gate electrodes PC, i.e., the side surfaces of the lower gate electrodes PCD and the upper gate electrodes PCU respectively overlapping with the lower gate electrodes PCD in the vertical direction (the Z direction). A plurality of lower gate insulating films GOXD and a plurality of upper gate insulating films GOXU may be between the side surfaces of the lower gate electrodes PCD and the upper gate electrodes PCU and the seventh insulating layer L07. A gate cut region PCCUT may be formed by removing a lower gate electrode PCD and an upper gate electrode PCU of one of the gate electrodes PC, which are arranged at substantially regular intervals in the first horizontal direction (the X direction), a lower gate insulating film GOXD surrounding the lower gate electrode PCD, and an upper gate insulating film GOXU surrounding the upper gate electrode PCU. The gate cut region PCCUT may be filled with an eleventh insulating layer L11.

A base substrate layer BSUB and an isolation film STI may be below the third insulating layer L03 to partially surround a lower portion of the first insulating layer L01 and a lower portion of the lower contact bCA. A portion of the base substrate layer BSUB may be removed and then filled with the isolation film STI. Thereafter, another portion of the base substrate layer BSUB may be removed and filled with the first insulating layer L01.

Some of a plurality of upper source/drain regions SDU may respectively overlap with a plurality of lower source/drain regions SDD in the vertical direction (the Z direction). A lower source/drain region SDD may not be arranged below each of the other upper source/drain regions SDU. A portion of the third insulating layer L03 covering the top surface of the isolation film STI may be below the other upper source/drain regions SDU. To form a shared contact structure SC described with reference to FIGS. 4A to 4D, at least one lower source/drain region SDD and a source/drain electrode, i.e., the lower contact bCA, which is connected to the lower source/drain region SDD, may not be formed in a region below the other upper source/drain regions SDU, where lower source/drain regions SDD respectively overlapping with the other upper source/drain regions SDU are not arranged in the region below the other upper source/drain regions SDU.

The upper contact CA and the lower contact bCA, which are respectively connected to an upper source/drain region SDU and a lower source/drain region SDD overlapping with the upper source/drain region SDU in the vertical direction (the Z direction), may be connected to each other by a via contact VA. The upper contact CA, which is connected to the upper source/drain region SDU shared, as a source/drain region, by one pull-down transistor PD and one pass-gate transistor PG, may be electrically connected to the lower contact bCA, which is connected to the lower source/drain region SDD corresponding to the source/drain region of one pull-up transistor PU, by the via contact VA. The via contact VA may extend in the vertical direction (the Z direction).

The fourth insulating layer L04 may surround the lower source/drain region SDD and the lower contact bCA. A twelfth insulating layer L12 may surround the upper source/drain region SDU and the base part CA-B of the upper contact CA. A thirteenth insulating layer L13 may be between the fourth insulating layer L04 and the lower source/drain region SDD. A fourteenth insulating layer L14 may be between the twelfth insulating layer L12 and the upper source/drain region SDU.

The lower nanosheets ND1, ND2, ND3, and ND4 and the upper nanosheets NU1, NU2, and NU3 may include a semiconductor material. The lower nanosheets ND1, ND2, ND3, and ND4 may include impurities of a different conductivity type than the upper nanosheets NU1, NU2, and NU3. For example, the lower nanosheets ND1, ND2, ND3, and ND4 may include impurities of a first conductivity type and the upper nanosheets NU1, NU2, and NU3 may include impurities of a second conductivity type. In some implementations, the first conductivity type may be p-type and the second conductivity type may be n-type. The lower nanosheet stack structure NSSD including the lower nanosheets ND1, ND2, ND3, and ND4 may constitute a PMOS transistor and the upper nanosheet stack structure NSSU including the upper nanosheets NU1, NU2, and NU3 may constitute an NMOS transistor. In some implementations, the number of lower nanosheets ND1, ND2, ND3, and ND4 included in the lower nanosheet stack structure NSSD may be greater than the number of upper nanosheets NU1, NU2, and NU3 included in the upper nanosheet stack structure NSSU. For example, the number of nanosheets included in a nanosheet stack structure constituting a PMOS transistor among the lower nanosheet stack structure NSSD and the upper nanosheet stack structure NSSU may be greater than the number of nanosheets included in a nanosheet stack structure constituting an NMOS transistor.

In some implementations, the first insulating layer L01, the second insulating layer L02, the third insulating layer L03, the fifth insulating layer L05, the eighth insulating layer L08, the ninth insulating layer L09, the eleventh insulating layer L11, the thirteenth insulating layer L13, and the fourteenth insulating layer L14 may include nitride. In some implementations, the fourth insulating layer L04, the sixth insulating layer L06, the tenth insulating layer L10, and the twelfth insulating layer L12 may include oxide. In some implementations, the lower insulating structure BDI, the middle insulating structure MDI, and the seventh insulating layer L07 may include oxynitride, oxide, or nitride.

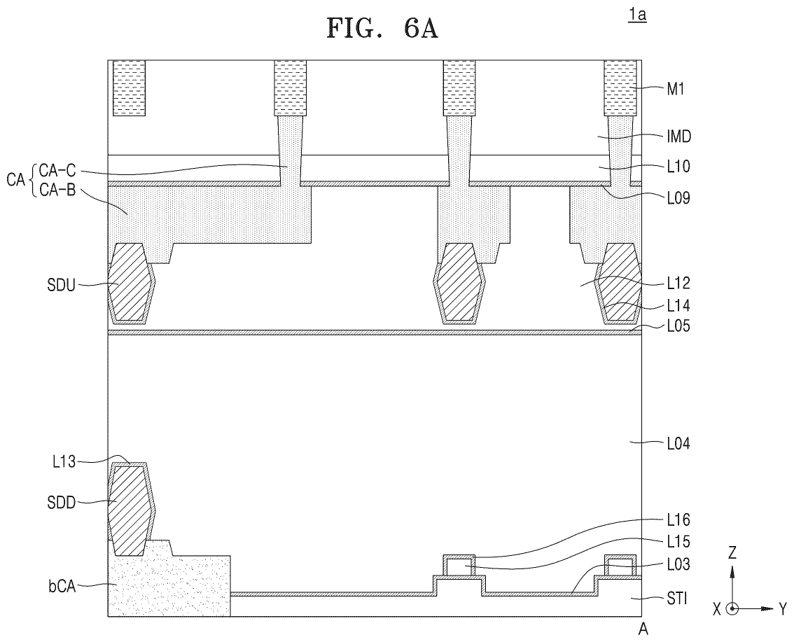

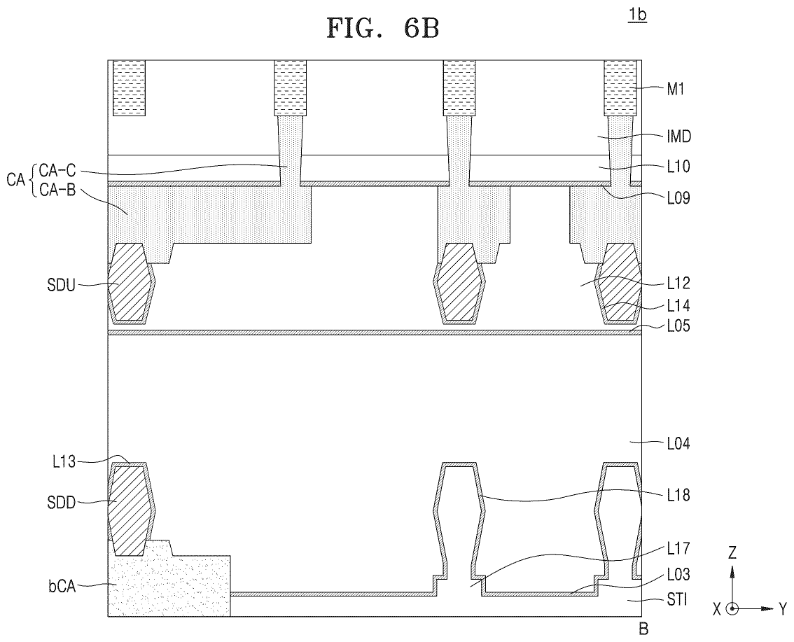

FIGS. 6A and 6B are respectively cross-sectional views of stacked integrated circuit devices. In detail, FIGS. 6A and 6B are respectively cross-sectional views taken along at least a part of the line D-D in FIGS. 4A to 4D.

Referring to FIG. 6A, in a stacked integrated circuit device 1a, a region below some of a plurality of upper source/drain regions SDU, in which lower source/drain regions SDD respectively overlapping with some upper source/drain regions SDU are not arranged, may correspond to a portion defined by forming a plurality of lower source/drain regions SDD and then removing at least one of the lower source/drain regions SDD to form a shared contact structure SC described with reference to FIGS. 4A to 4D.

A fifteenth insulating layer L15 on the third insulating layer L03 and a sixteenth insulating layer L16 covering the fifteenth insulating layer L15 may be below some upper source/drain regions SDU. In some implementations, a portion of the isolation film STI below the fifteenth insulating layer L15 and the sixteenth insulating layer L16 may protrude upward from the other portion thereof. In some implementations, the fifteenth insulating layer L15 may include oxide and the sixteenth insulating layer L16 may include nitride.

Referring to FIG. 6B, in a stacked integrated circuit device 1b, a region below some of a plurality of upper source/drain regions SDU, in which lower source/drain regions SDD respectively overlapping with some upper source/drain regions SDU are not arranged, may correspond to a portion defined by forming a plurality of lower source/drain regions SDD and then removing at least one of the lower source/drain regions SDD before forming the lower contact bCA to form a shared contact structure SC described with reference to FIGS. 4A to 4D.

The third insulating layer L03 may not be arranged below some upper source/drain regions SDU. A seventeenth insulating layer L17 on the isolation film STI and an eighteenth insulating layer L18 covering the seventeenth insulating layer L17 may be below some upper source/drain regions SDU. In some implementations, the seventeenth insulating layer L17 may include oxide and the eighteenth insulating layer L18 may include nitride.

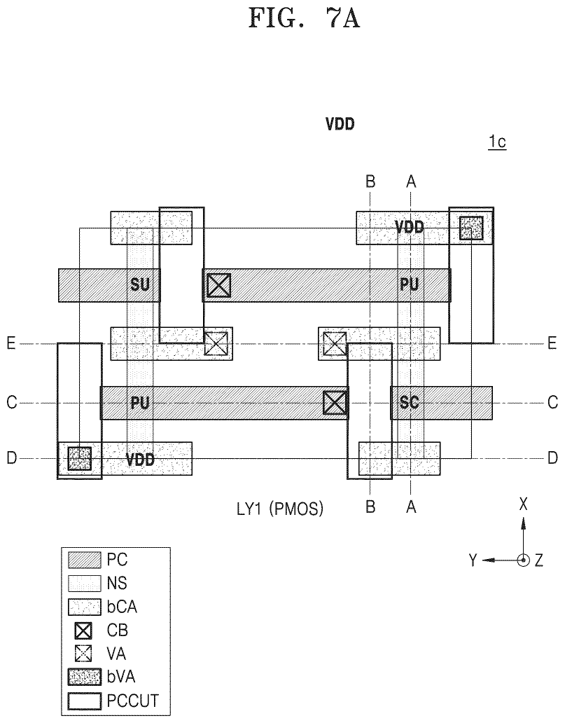

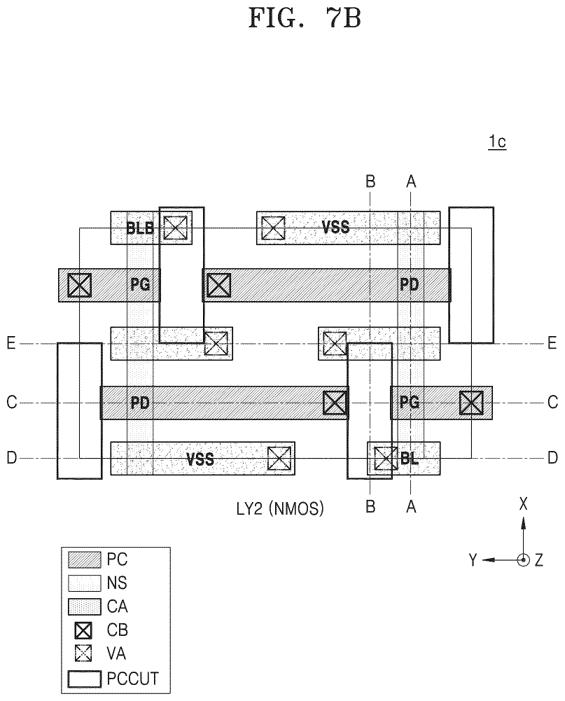

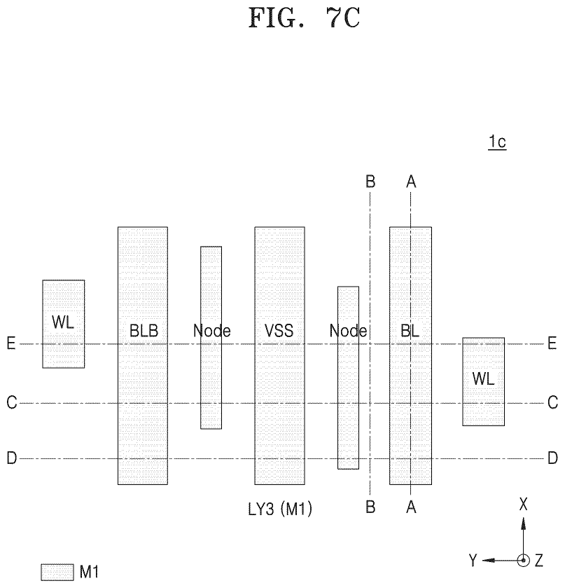

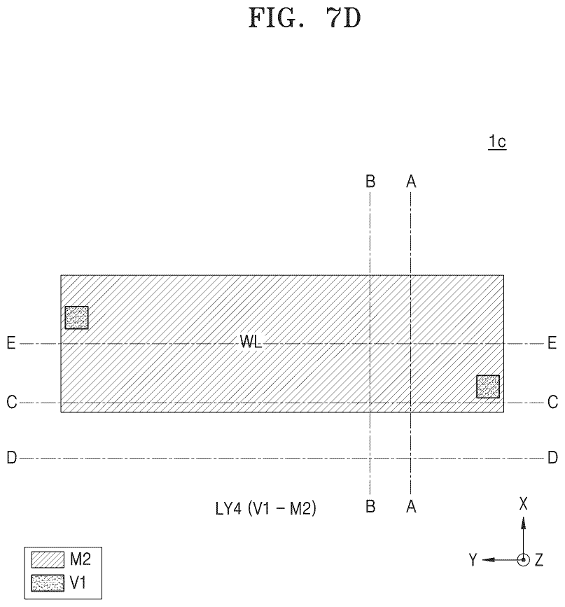

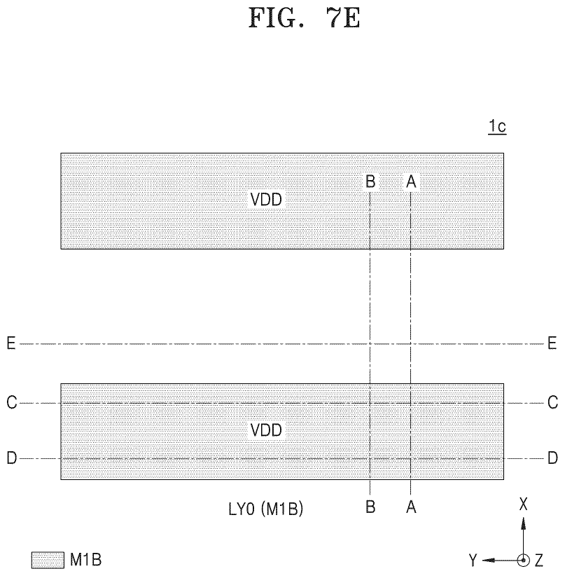

FIGS. 7A to 7E show schematic layouts of an example of a stacked integrated circuit device 1c. Referring to FIGS. 7A to 7E, in the stacked integrated circuit device 1c, a lower via contact bVA may be connected to a lower contact bCA connected to the power supply VDD. A plurality of first upper wires M1 in the third layer LY3 and a plurality of second upper wires M2 in the fourth layer LY4 may not include a power supply VDD. The stacked integrated circuit device 1c may include a plurality of first lower wires M1B in a zeroth layer LY0 that is lower than the first layer LY1. The first lower wires M1B may extend in the second horizontal direction (the Y direction). Each of the first lower wires M1B may correspond to the power supply VDD and may be connected to the lower via contact bVA.

The power supply VDD may be provided from the zeroth layer LY0 in a lower portion of the stacked integrated circuit device 1c and the ground VSS may be provided from the third layer LY3 in an upper portion of the stacked integrated circuit device 1c.

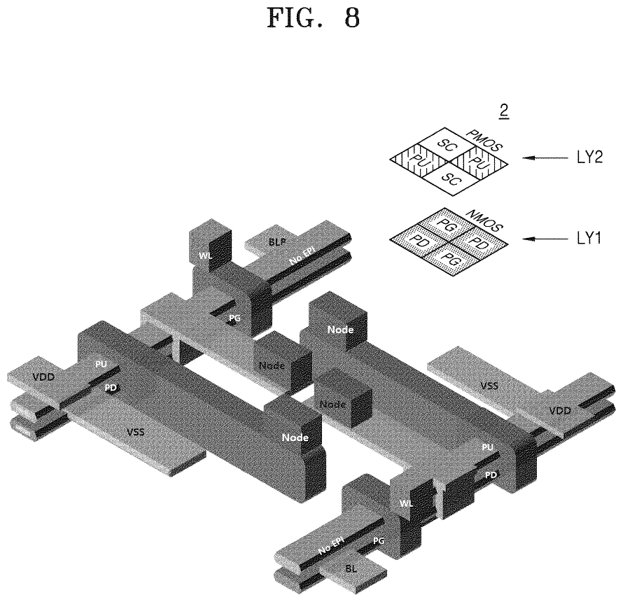

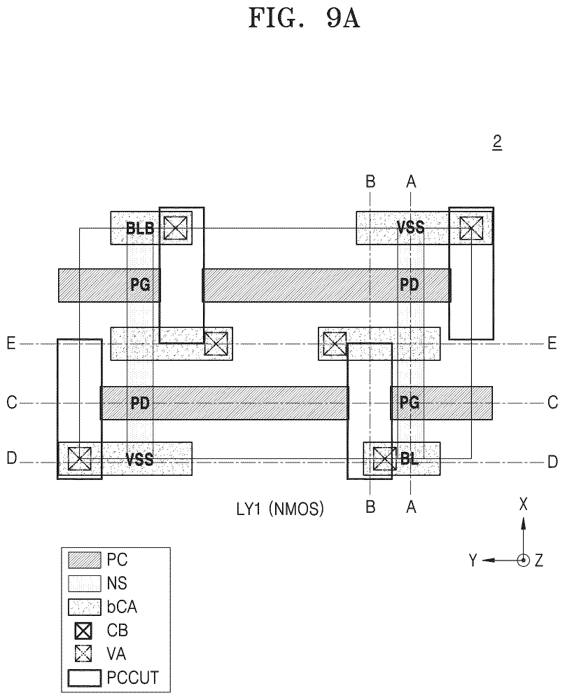

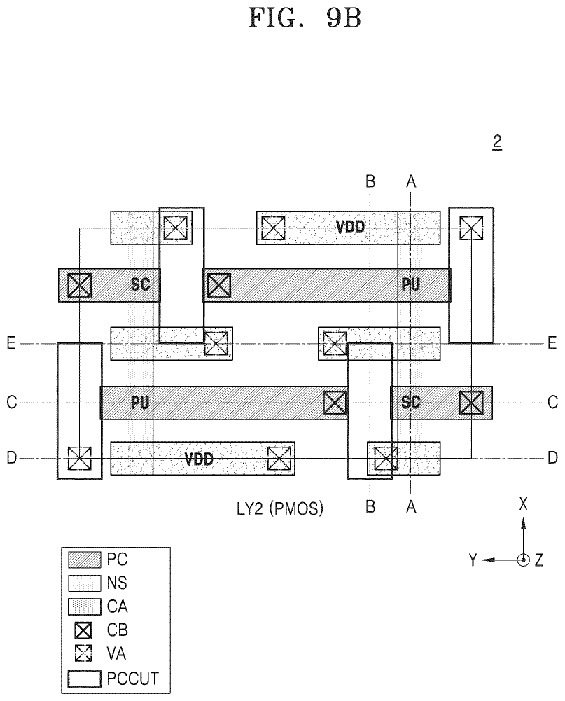

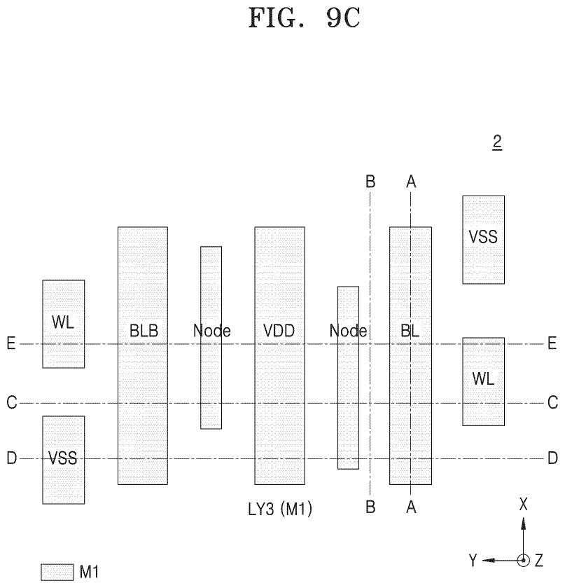

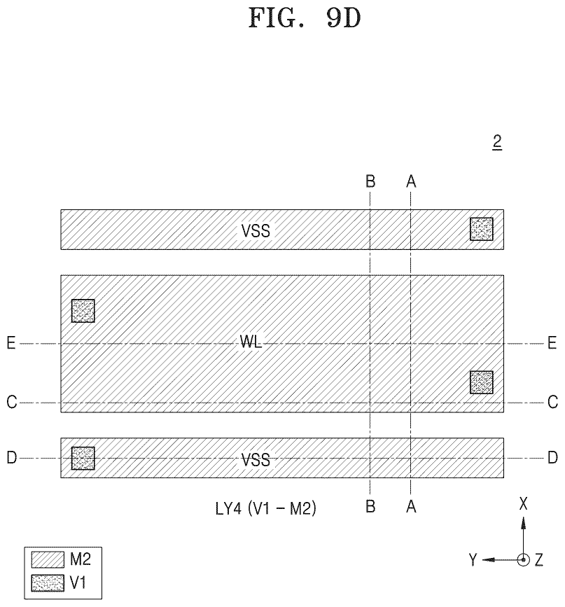

FIG. 8 is a schematic perspective view of the stacked integrated circuit device 2 of FIG. 2A. FIGS. 9A to 9D show schematic layouts of the stacked integrated circuit device 2.

Referring to FIGS. 8 to 9D, the stacked integrated circuit device 2 may include a nanosheet NS, which extends in the first horizontal direction (the X direction), and a gate electrode PC, which extends in the second horizontal direction (the Y direction) that is orthogonal to the first horizontal direction (the X direction). A portion No EPI among portions of the nanosheet NS and portions of the gate electrode PC, which respectively cross the portion of the nanosheet NS, may correspond to a shared contact structure SC that does not have an epitaxial layer forming a source/drain region. The gate electrode PC, which has a portion crossing a portion of the nanosheet NS of the shared contact structure SC and extends in the second horizontal direction (the Y direction), may be divided into at least two parts by a gate cut region PCCUT that extends in the first horizontal direction (the X direction).

An upper contact CA and a lower contact bCA may be connected to source/drain regions of transistors including a pull-up transistor PU, a pull-down transistor PD, and a pass-gate transistor PG. The upper contact CA and the lower contact bCA may extend in the second horizontal direction (the Y direction). The upper contact CA may be connected to the power supply VDD. The lower contact bCA may be connected to the ground VSS, the bit line BL, and the complementary bit line BLB.

A gate contact CB may be connected to the gate electrode PC. A via contact VA may be connected to the upper contact CA, which connects three respective source/drain regions of the pull-up transistor PU, the pull-down transistor PD, and the pass-gate transistor PG.

The via contact VA connected to the upper contact CA, which connects three respective source/drain regions of the pull-up transistor PU, the pull-down transistor PD, and the pass-gate transistor PG, may be aligned with the gate contact CB connected to the gate electrode PC, which is shared by another pull-up transistor PU and another pull-down transistor PD in different layers, in the first horizontal direction (the X direction).

A plurality of first upper wires M1 may be in the third layer LY3 that is at a higher vertical level than the second layer LY2. The first upper wires M1 may extend in the first horizontal direction (the X direction). Each of the first upper wires M1 may correspond to the power supply VDD, the ground VSS, the word line WL, the bit line BL, the complementary bit line BLB, or the shared node Node. A first upper wire M1 corresponding to the shared node Node may connect the via contact VA to the gate contact CB, wherein the via contact VA and the gate contact CB are aligned with each other in the first horizontal direction (the X direction).

A plurality of second upper wires M2 may be in the fourth layer LY4 that is at a higher vertical level than the third layer LY3. A first upper wire M1 may be connected to a second upper wire M2 by a first upper via V1. The second upper wires M2 may extend in the second horizontal direction (the Y direction). Each of the second upper wires M2 may correspond to the ground VSS or the word line WL.

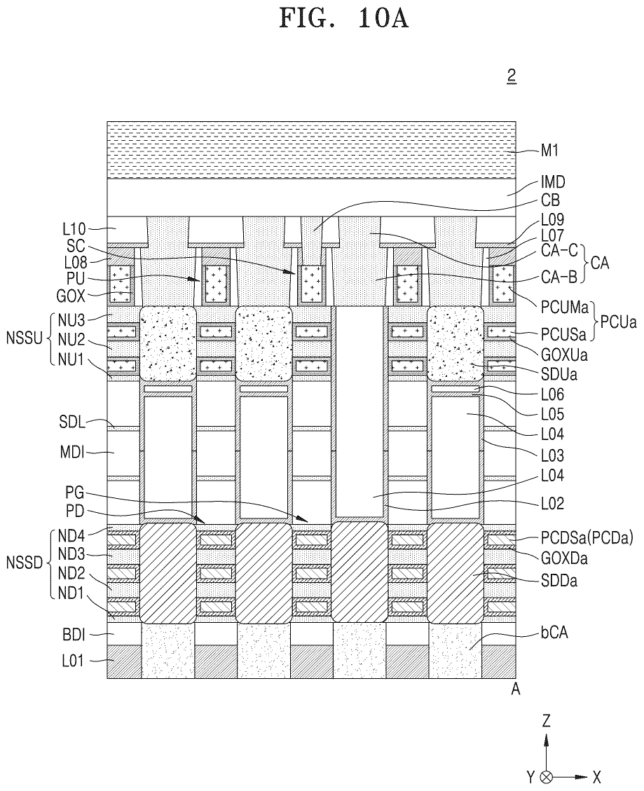

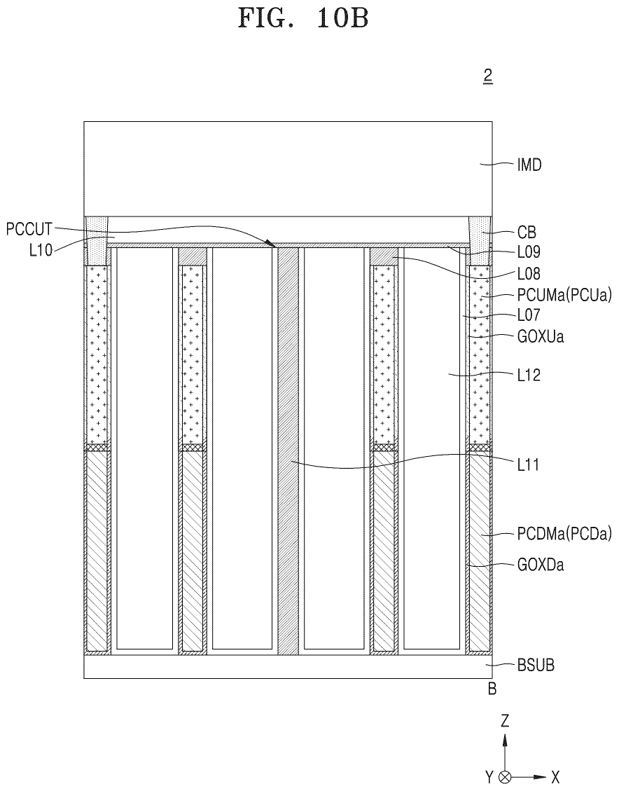

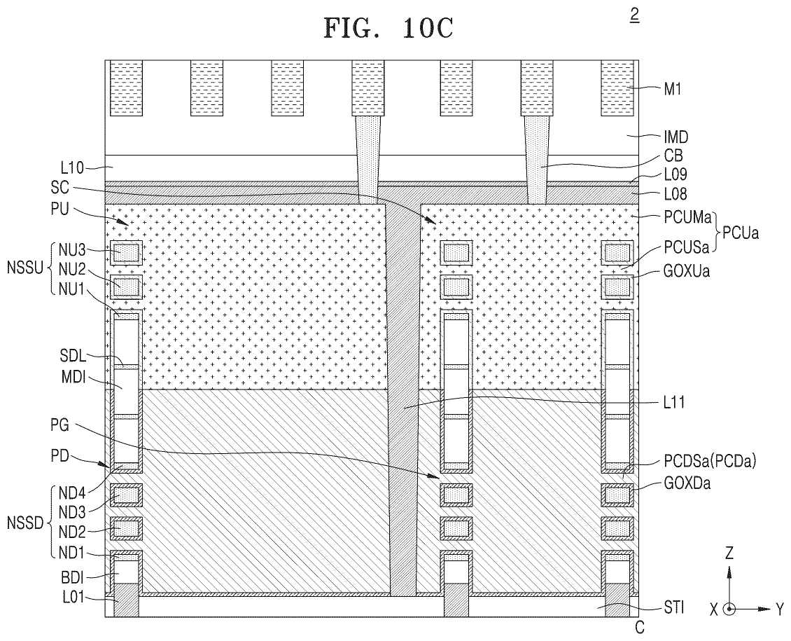

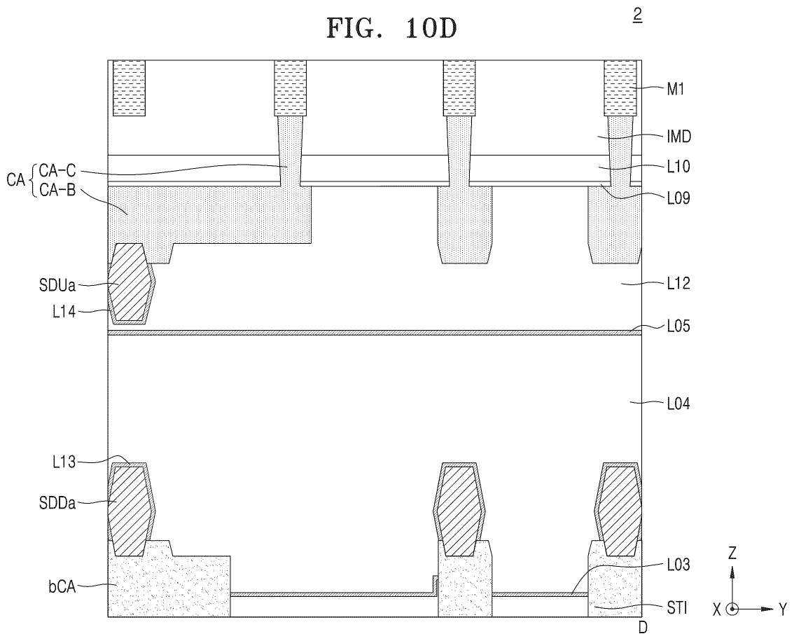

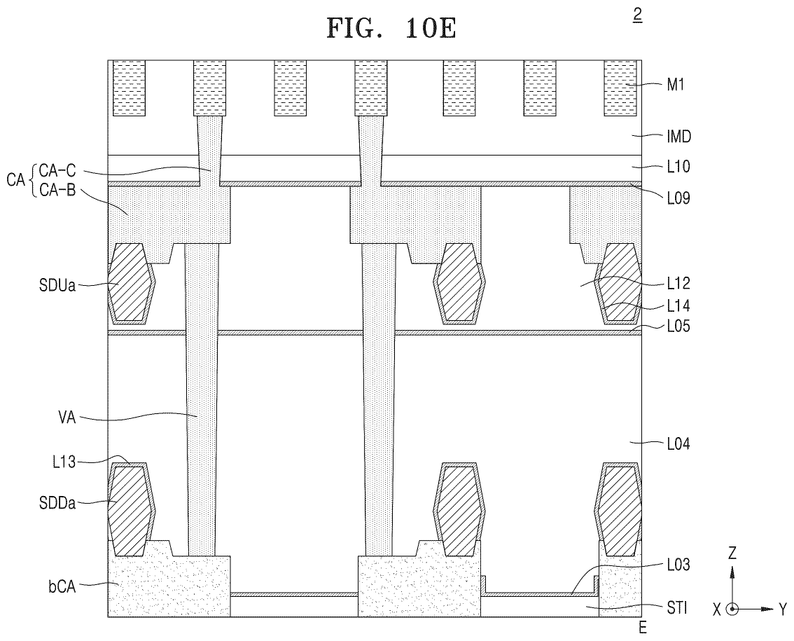

FIGS. 10A to 10E are cross-sectional views illustrating the stacked integrated circuit device 2. In detail, FIGS. 10A to 10E are cross-sectional views respectively taken along at least respective parts of lines A-A, B-B, C-C, D-D, and E-E in FIGS. 9A to 9D.

Referring to FIGS. 10A to 10E, the stacked integrated circuit device 2 may include a lower nanosheet stack structure NSSD, which includes a plurality of lower nanosheets ND1, ND2, ND3, and ND4, and an upper nanosheet stack structure NSSU, which is above the lower nanosheet stack structure NSSD and includes a plurality of upper nanosheets NU1, NU2, and NU3. The lower nanosheet stack structure NSSD may be in the first layer LY1 in FIGS. 8 to 9D and the upper nanosheet stack structure NSSU may be in the second layer LY2 in FIGS. 8 to 9D. Each of the lower nanosheets ND1, ND2, ND3, and ND4 and the upper nanosheets NU1, NU2, and NU3 may extend in the first horizontal direction (the X direction). A lower source/drain region SDDa may be at a side of the lower nanosheet stack structure NSSD in the first horizontal direction (the X direction) and may be connected to the lower nanosheets ND1, ND2, ND3, and ND4. An upper source/drain region SDUa may be at a side of the upper nanosheet stack structure NSSU in the first horizontal direction (the X direction) and may be connected to the upper nanosheets NU1, NU2, and NU3. The lower source/drain region SDDa may be shared, as a source/drain region, by a pull-down transistor PD and a pass-gate transistor PG, which are adjacent to each other in the first horizontal direction (the X direction). The upper source/drain region SDUa may correspond to the source/drain region of a pull-up transistor PU.

A lower gate electrode PCDa may surround the lower nanosheets ND1, ND2, ND3, and ND4. The lower gate electrode PCDa may include a sub lower gate electrode PCDSa, which is arranged among the lower nanosheets ND1, ND2, ND3, and ND4, and a main lower gate electrode PCDMa, which surrounds the lower nanosheets ND1, ND2, ND3, and ND4 and the sub lower gate electrode PCDSa. A lower gate insulating film GOXDa may be between the lower gate electrode PCDa and each of the lower nanosheets ND1, ND2, ND3, and ND4.

An upper gate electrode PCUa may surround the upper nanosheets NU1, NU2, and NU3. The upper gate electrode PCUa may include a sub upper gate electrode PCUSa, which is arranged among the upper nanosheets NU1, NU2, and NU3, and a main upper gate electrode PCUMa, which surrounds the upper nanosheets NU1, NU2, and NU3 and the sub upper gate electrode PCUSa. An upper gate insulating film GOXUa may be between the upper gate electrode PCUa and each of the upper nanosheets NU1, NU2, and NU3.

The lower gate electrode PCDa and the upper gate electrode PCUa may overlap with each other in the vertical direction (the Z direction). The lower gate electrode PCDa and the upper gate electrode PCUa overlapping with each other in the vertical direction (the Z direction) may correspond to the gate electrode PC in FIGS. 9A and 9B. A plurality of lower gate electrodes PCDa and a plurality of upper gate electrodes PCUa respectively overlapping with the lower gate electrodes PCDa in the vertical direction (the Z direction), i.e., a plurality of gate electrodes PC, may extend in the second horizontal direction (the Y direction) and may be separated from each other at substantially regular intervals in the first horizontal direction (the X direction). A gate cut region PCCUT may be formed by removing a lower gate electrode PCDa and an upper gate electrode PCUa of one of the gate electrodes PC, which are arranged at substantially regular intervals in the first horizontal direction (the X direction), the lower gate insulating film GOXDa surrounding the lower gate electrode PCDa, and the upper gate insulating films GOXUa surrounding the upper gate electrode PCUa.

Some of a plurality of lower source/drain regions SDD may respectively overlap with a plurality of upper source/drain regions SDU in the vertical direction (the Z direction). An upper source/drain region SDU may not be arranged above each of the other lower source/drain regions SDD. To form the shared contact structure SC described with reference to FIGS. 9A to 9D, at least one upper source/drain region SDU may not be formed in a region above the other lower source/drain regions SDD, wherein upper source/drain regions SDU respectively overlapping with the other lower source/drain regions SDD are not arranged in the region.

The upper contact CA and the lower contact bCA, which are respectively connected to an upper source/drain region SDU and a lower source/drain region SDD overlapping with the upper source/drain region SDU in the vertical direction (the Z direction), may be connected to each other by a via contact VA. The upper contact CA, which is connected to the upper source/drain region SDU corresponding to the source/drain region of one pull-up transistor PU, may be electrically connected to the lower contact bCA, which is connected to the lower source/drain region SDD shared, as a source/drain region, by one pull-down transistor PD and one pass-gate transistor PG, by the via contact VA. The via contact VA may extend in the vertical direction (the Z direction).

The lower nanosheets ND1, ND2, ND3, and ND4 may include impurities of a different conductivity type than the upper nanosheets NU1, NU2, and NU3. For example, the lower nanosheets ND1, ND2, ND3, and ND4 may include impurities of the second conductivity type and the upper nanosheets NU1, NU2, and NU3 may include impurities of the first conductivity type. The lower nanosheet stack structure NSSD including the lower nanosheets ND1, ND2, ND3, and ND4 may constitute an NMOS transistor and the upper nanosheet stack structure NSSU including the upper nanosheets NU1, NU2, and NU3 may constitute a PMOS transistor.

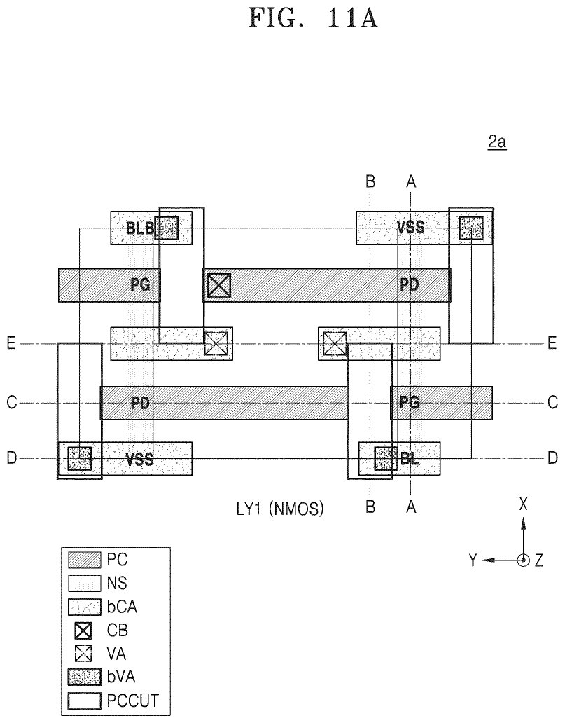

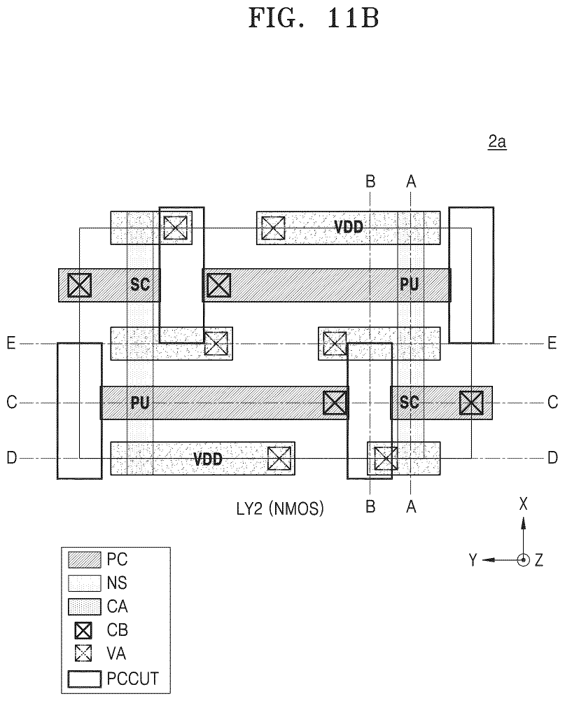

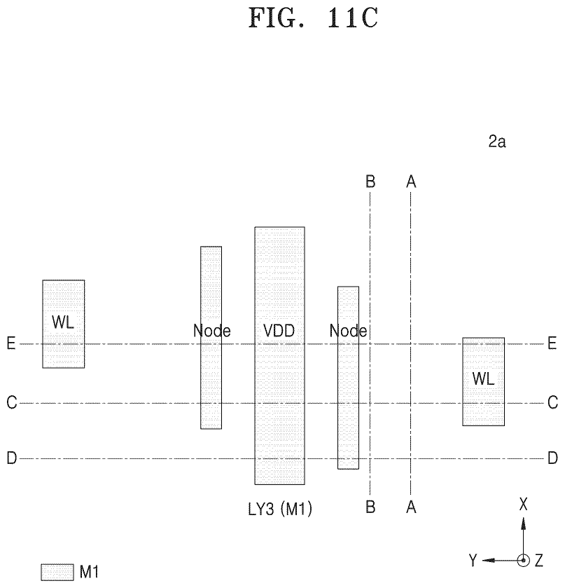

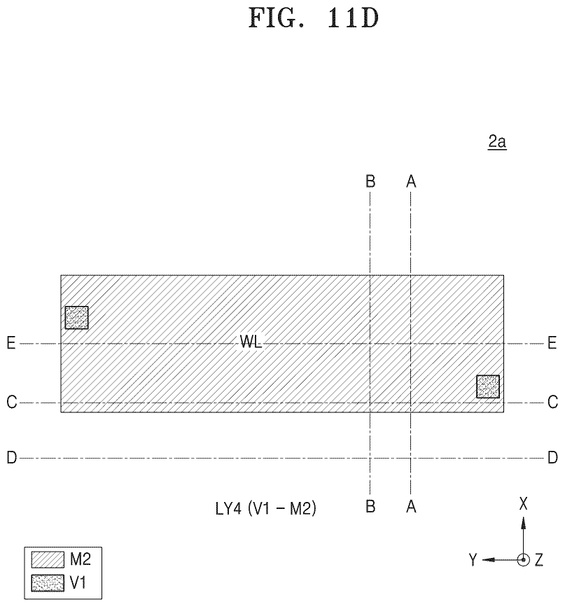

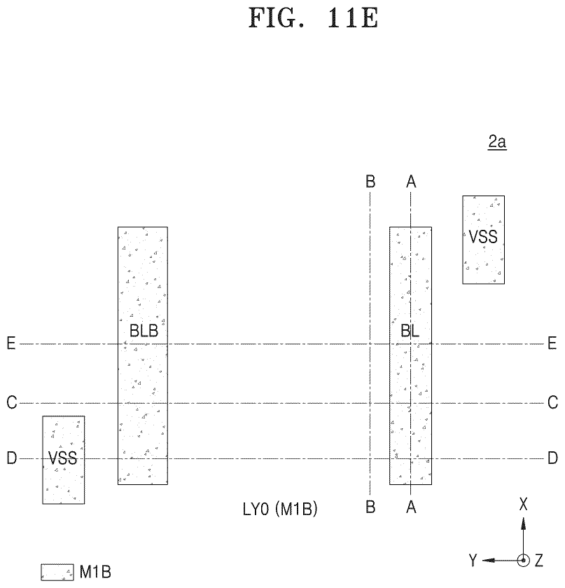

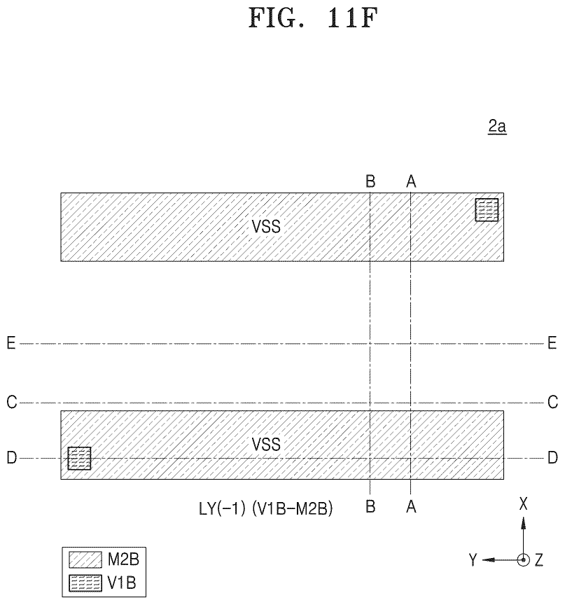

FIGS. 11A to 11F show schematic layouts of an example of a stacked integrated circuit device. Referring to FIGS. 11A to 11F, in a stacked integrated circuit device 2a, a lower via contact bVA may be connected to a lower contact bCA, which is connected to the ground VSS, the bit line BL, and the complementary bit line BLB. A plurality of first upper wires M1 in the third layer LY3 and a plurality of second upper wires M2 in the fourth layer LY4 may not include a ground VSS, a bit line BL, and a complementary bit line BLB. The stacked integrated circuit device 2a may include a plurality of first lower wires M1B in the zeroth layer LY0 that is lower than the first layer LY1. The first lower wires M1B may extend in the first horizontal direction (the X direction). Each of the first lower wires M1B may correspond to the ground VSS, the bit line BL, or the complementary bit line BLB and may be connected to the lower via contact bVA.

A plurality of second lower wires M2B may be in a basement layer LY(-1) that is at a lower vertical level than the zeroth layer LY0. A first lower wire M1B may be connected to a second lower wire M2B by a first lower via V1B. The second lower wires M2B may extend in the second horizontal direction (the Y direction). The second lower wires M2B may correspond to the ground VSS.

The ground VSS may be provided from the basement layer LY(-1) in a lower portion of the stacked integrated circuit device 2a and the power supply VDD may be provided from the third layer LY3 in an upper portion of the stacked integrated circuit device 2a.

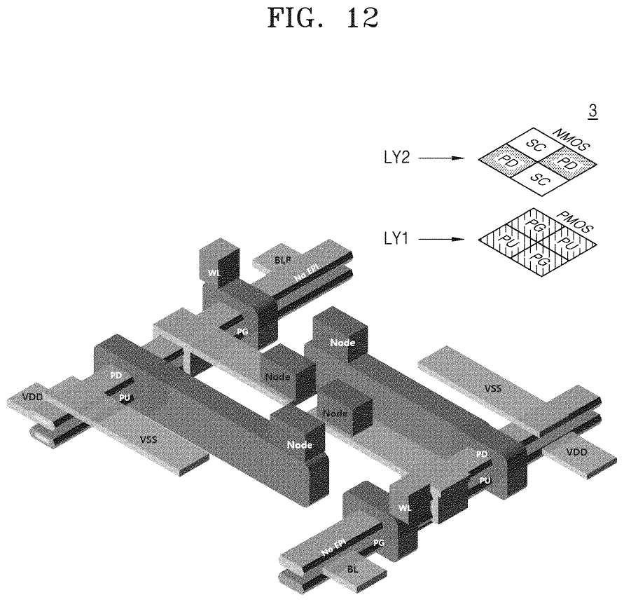

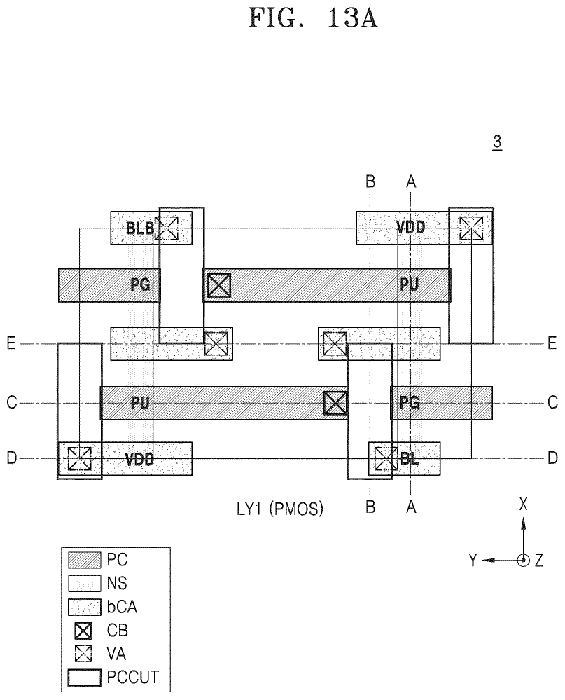

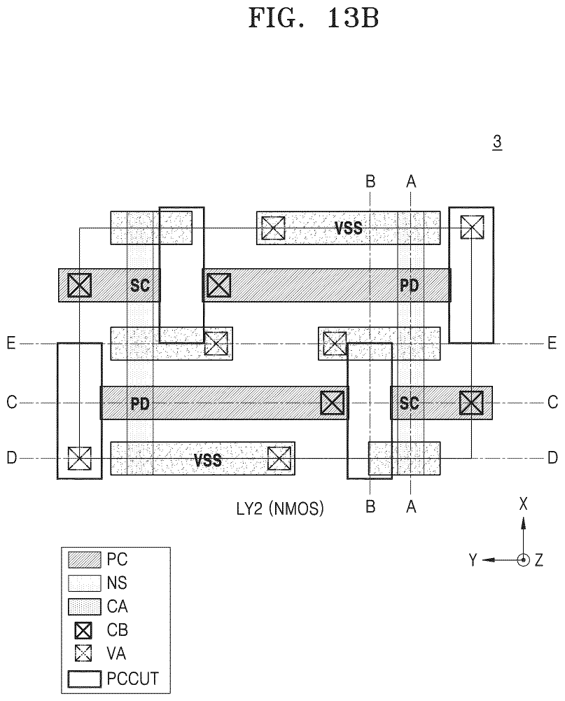

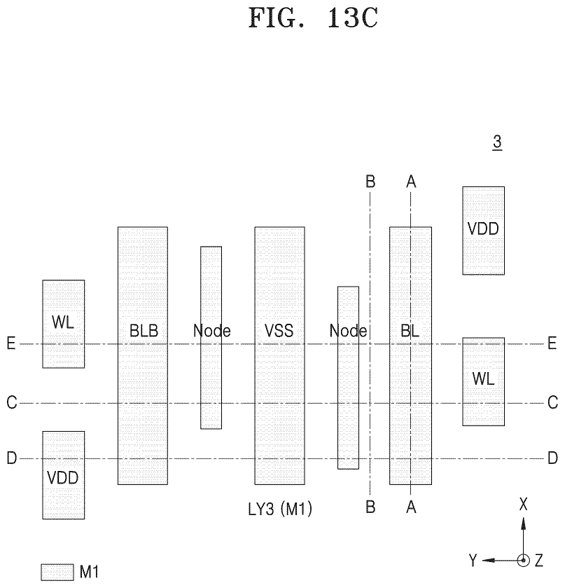

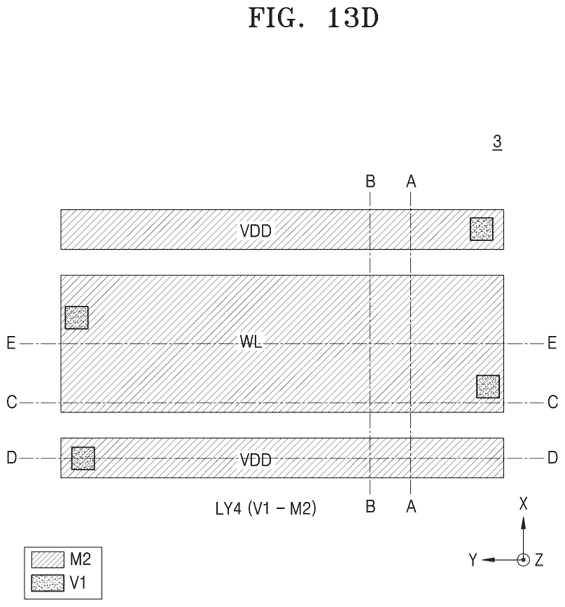

FIG. 12 is a schematic perspective view of the stacked integrated circuit device 3. FIGS. 13A to 13D show schematic layouts of the stacked integrated circuit device 3.

Referring to FIGS. 12 to 13D, the stacked integrated circuit device 3 may include a nanosheet NS, which extends in the first horizontal direction (the X direction), and a gate electrode PC, which extends in the second horizontal direction (the Y direction) that is orthogonal to the first horizontal direction (the X direction). A portion No EPI among the portions of the nanosheet NS and the portions of the gate electrode PC, which respectively cross the portion of the nanosheet NS, may correspond to a shared contact structure SC that does not have an epitaxial layer forming a source/drain region. The gate electrode PC, which has a portion crossing a portion of the nanosheet NS of the shared contact structure SC and extends in the second horizontal direction (the Y direction), may be divided into at least two parts by a gate cut region PCCUT that extends in the first horizontal direction (the X direction).

An upper contact CA and a lower contact bCA may be connected to source/drain regions of transistors including a pull-up transistor PU, a pull-down transistor PD, and a pass-gate transistor PG. The upper contact CA and the lower contact bCA may extend in the second horizontal direction (the Y direction). The upper contact CA may be connected to the power supply VDD, the bit line BL, and the complementary bit line BLB. The lower contact bCA may be connected to the ground VSS.

A gate contact CB may be connected to the gate electrode PC. A via contact VA may be connected to the upper contact CA, which connects three respective source/drain regions of the pull-up transistor PU, the pull-down transistor PD, and the pass-gate transistor PG.

The via contact VA connected to the upper contact CA, which connects three respective source/drain regions of the pull-up transistor PU, the pull-down transistor PD, and the pass-gate transistor PG, may be aligned with the gate contact CB connected to the gate electrode PC, which is shared by another pull-up transistor PU and another pull-down transistor PD in different layers, in the first horizontal direction (the X direction).

A plurality of first upper wires M1 may be in the third layer LY3 that is at a higher vertical level than the second layer LY2. The first upper wires M1 may extend in the first horizontal direction (the X direction). Each of the first upper wires M1 may correspond to the power supply VDD, the ground VSS, the word line WL, the bit line BL, the complementary bit line BLB, or the shared node Node. A first upper wire M1 corresponding to the shared node Node may connect the via contact VA and the gate contact CB, wherein the via contact VA and the gate contact CB are aligned with each other in the first horizontal direction (the X direction).

A plurality of second upper wires M2 may be in the fourth layer LY4 that is at a higher vertical level than the third layer LY3. A first upper wire M1 may be connected to a second upper wire M2 by a first upper via V1. The second upper wires M2 may extend in the second horizontal direction (the Y direction). Each of the second upper wires M2 may correspond to the power supply VDD or the word line WL.

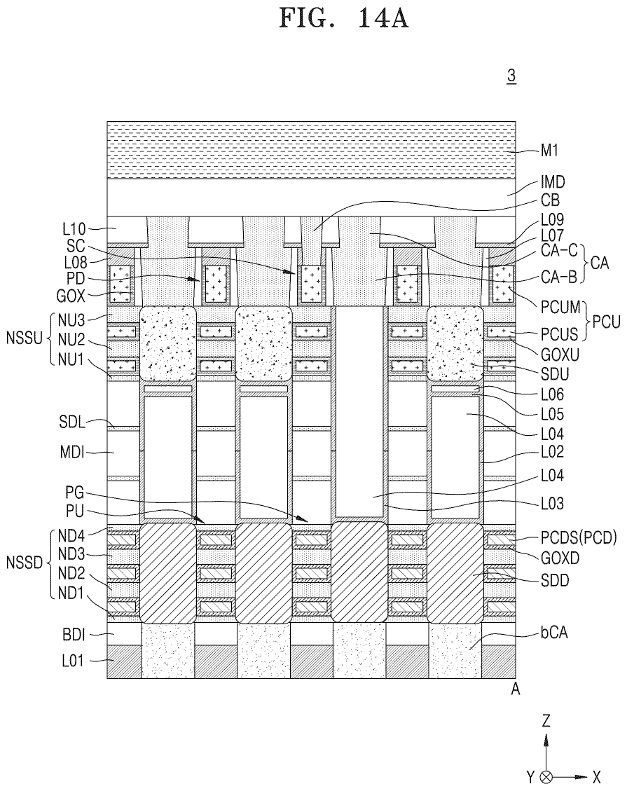

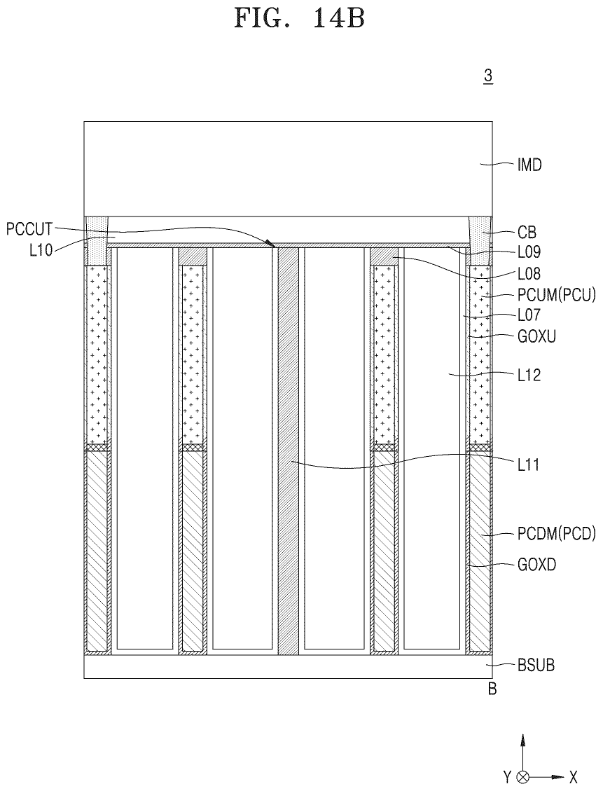

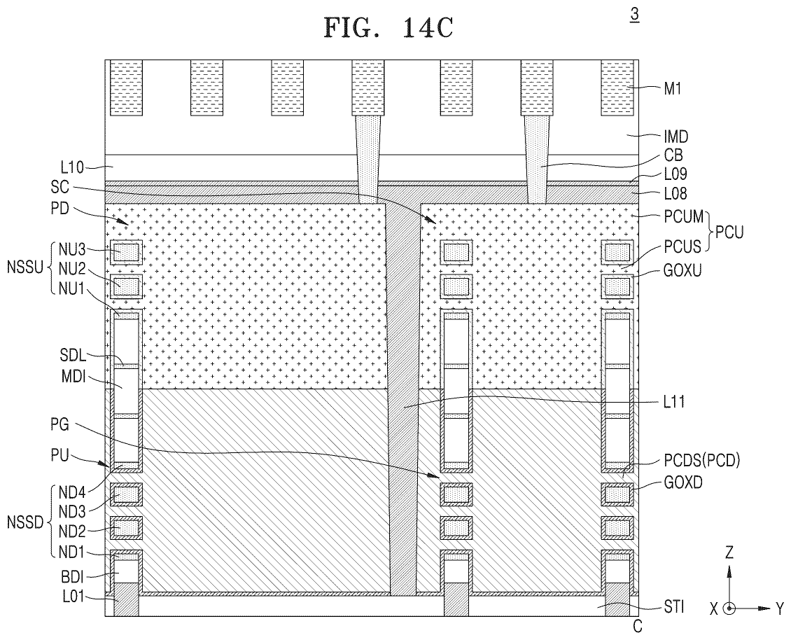

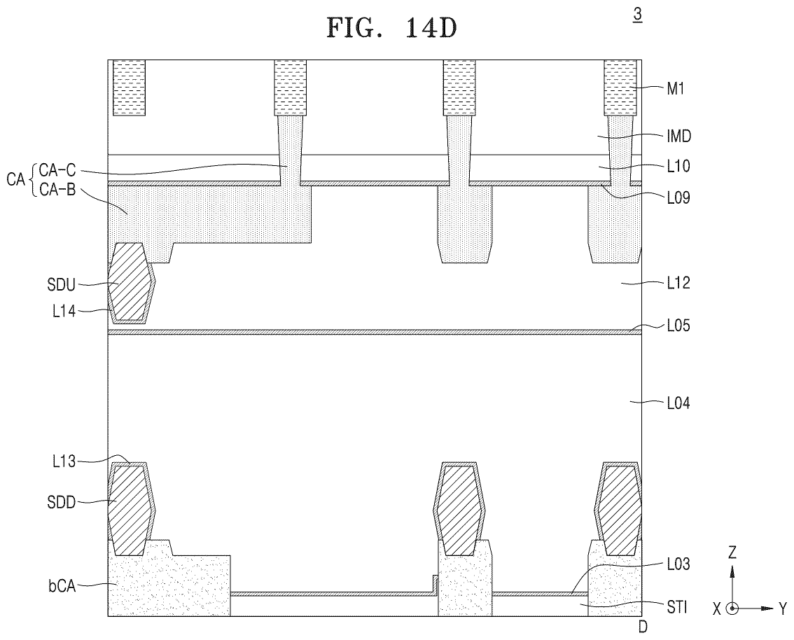

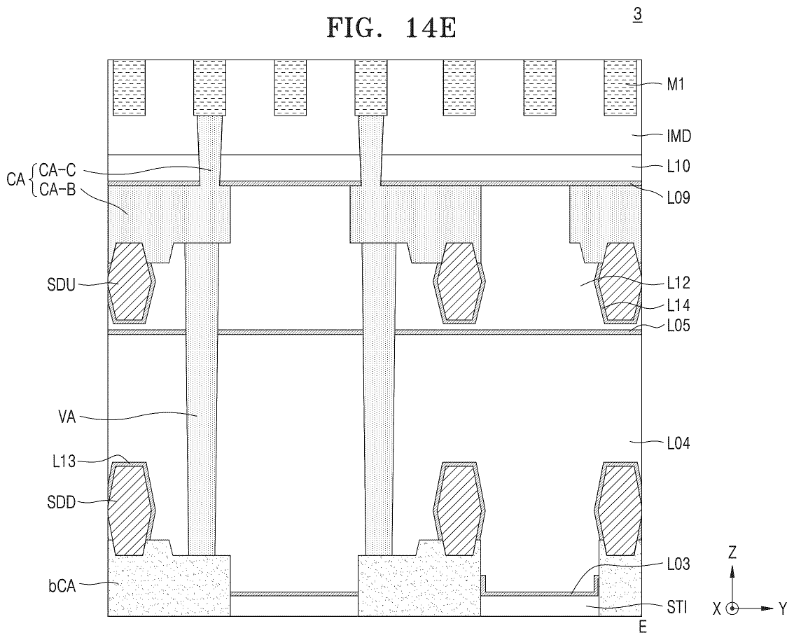

FIGS. 14A to 14E are cross-sectional views illustrating the stacked integrated circuit device 3. In detail, FIGS. 14A to 14E are cross-sectional views respectively taken along at least respective parts of lines A-A, B-B, C-C, D-D, and E-E in FIGS. 13A to 13D.

Referring to FIGS. 14A to 14E, the stacked integrated circuit device 3 may include a lower nanosheet stack structure NSSD, which includes a plurality of lower nanosheets ND1, ND2, ND3, and ND4, and an upper nanosheet stack structure NSSU, which is above the lower nanosheet stack structure NSSD and includes a plurality of upper nanosheets NU1, NU2, and NU3. The lower nanosheet stack structure NSSD may be in the first layer LY1 in FIGS. 12 to 13D, and the upper nanosheet stack structure NSSU may be in the second layer LY2 in FIGS. 12 to 13D.

A lower gate electrode PCD may surround the lower nanosheets ND1, ND2, ND3, and ND4. The lower gate electrode PCD may include a sub lower gate electrode PCDS, which is arranged among the lower nanosheets ND1, ND2, ND3, and ND4, and a main lower gate electrode PCDM, which surrounds the lower nanosheets ND1, ND2, ND3, and ND4 and the sub lower gate electrode PCDS. A lower gate insulating film GOXD may be between the lower gate electrode PCD and each of the lower nanosheets ND1, ND2, ND3, and ND4.

An upper gate electrode PCU may surround the upper nanosheets NU1, NU2, and NU3. The upper gate electrode PCU may include a sub upper gate electrode PCUS, which is arranged among the upper nanosheets NU1, NU2, and NU3, and a main upper gate electrode PCUM, which surrounds the upper nanosheets NU1, NU2, and NU3 and the sub upper gate electrode PCUS. An upper gate insulating film GOXU may be between the upper gate electrode PCU and each of the upper nanosheets NU1, NU2, and NU3.

The lower gate electrode PCD and the upper gate electrode PCU may overlap with each other in the vertical direction (the Z direction). The lower gate electrode PCD and the upper gate electrode PCU overlapping with each other in the vertical direction (the Z direction) may correspond to the gate electrode PC in FIGS. 13A and 13B. A plurality of lower gate electrodes PCD and a plurality of upper gate electrodes PCU respectively overlapping with the lower gate electrodes PCD in the vertical direction (the Z direction), i.e., a plurality of gate electrodes PC, may extend in the second horizontal direction (the Y direction) and may be separated from each other at substantially regular intervals in the first horizontal direction (the X direction). A gate cut region PCCUT may be formed by removing a lower gate electrode PCD and an upper gate electrode PCU of one of the gate electrodes PC, which are arranged at substantially regular intervals in the first horizontal direction (the X direction), the lower gate insulating film GOXD surrounding the lower gate electrode PCD, and the upper gate insulating films GOXU surrounding the upper gate electrode PCU.

Some of a plurality of lower source/drain regions SDD may respectively overlap with a plurality of upper source/drain regions SDU in the vertical direction (the Z direction). An upper source/drain region SDU may not be arranged above each of the other lower source/drain regions SDD. To form the shared contact structure SC described with reference to FIGS. 13A to 13D, at least one upper source/drain region SDU may not be formed in a region above the other lower source/drain regions SDD, wherein upper source/drain regions SDU respectively overlapping with the other lower source/drain regions SDD are not arranged in the region.

The lower nanosheets ND1, ND2, ND3, and ND4 may include impurities of a different conductivity type than the upper nanosheets NU1, NU2, and NU3. For example, the lower nanosheets ND1, ND2, ND3, and ND4 may include impurities of the first conductivity type and the upper nanosheets NU1, NU2, and NU3 may include impurities of the second conductivity type. The lower nanosheet stack structure NSSD including the lower nanosheets ND1, ND2, ND3, and ND4 may constitute a PMOS transistor and the upper nanosheet stack structure NSSU including the upper nanosheets NU1, NU2, and NU3 may constitute an NMOS transistor.

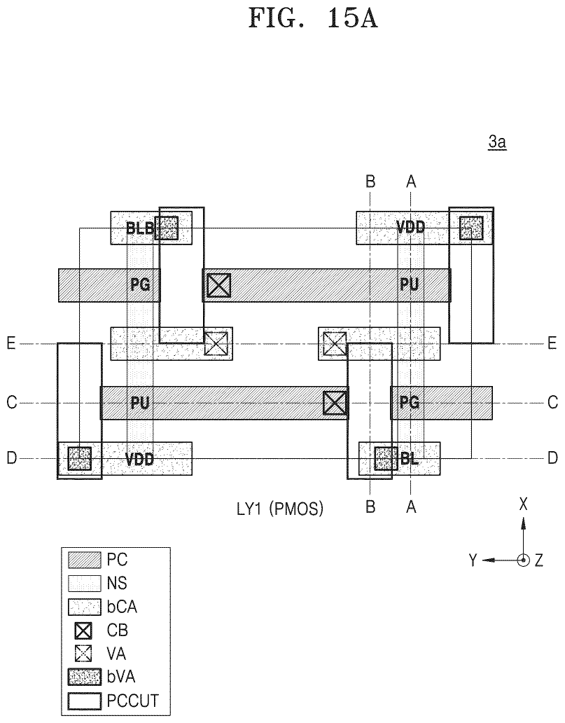

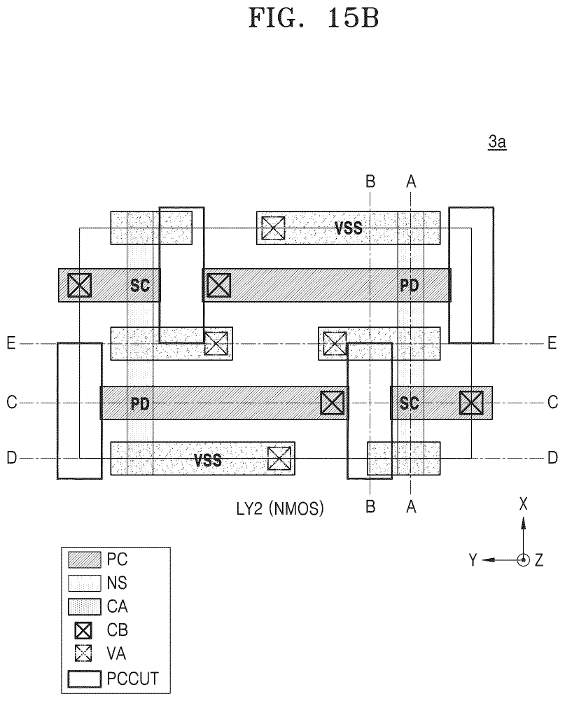

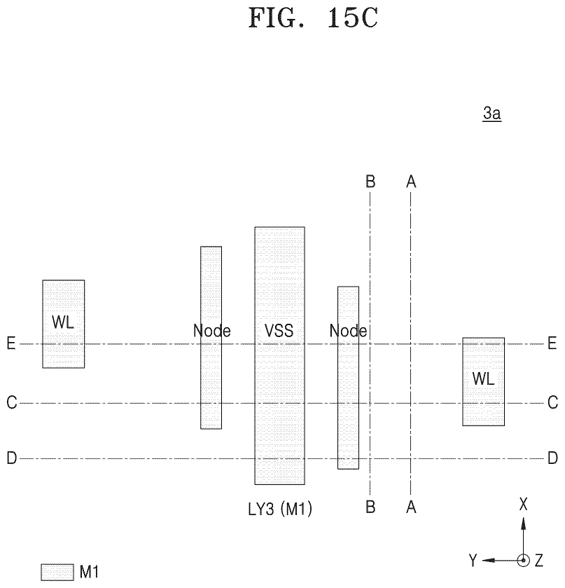

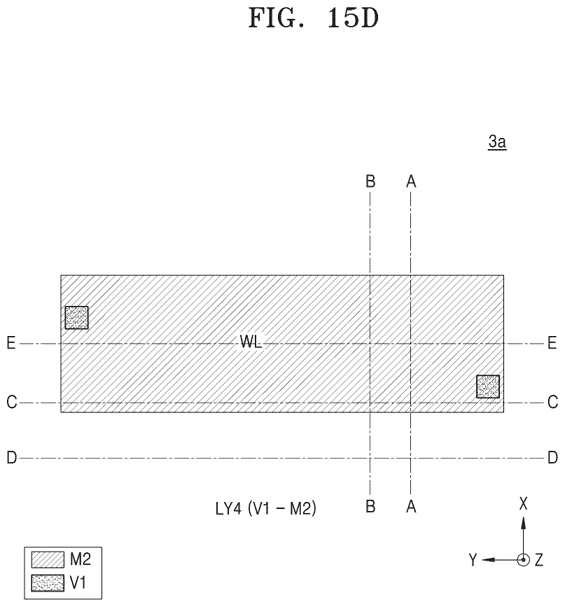

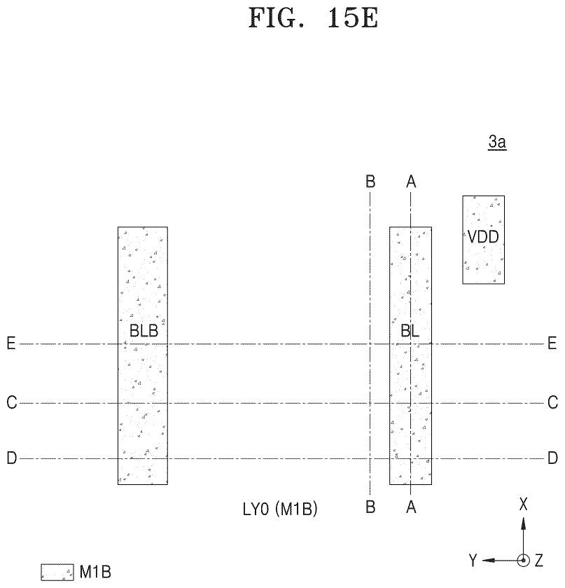

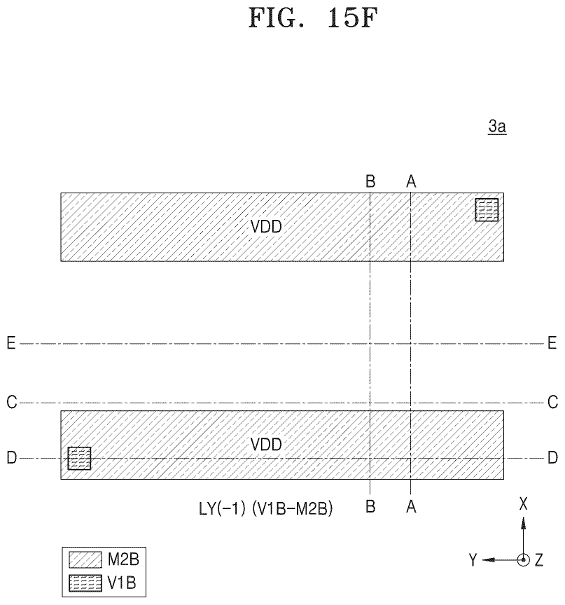

FIGS. 15A to 15F show schematic layouts of an example of a stacked integrated circuit device 3a. Referring to FIGS. 15A to 15F, in the stacked integrated circuit device 3a, a lower via contact bVA may be connected to a lower contact bCA, which is connected to the power supply VDD, the bit line BL, and the complementary bit line BLB. A plurality of first upper wires M1 in the third layer LY3 and a plurality of second upper wires M2 in the fourth layer LY4 may not include a power supply VDD, a bit line BL, and a complementary bit line BLB. The stacked integrated circuit device 3a may include a plurality of first lower wires M1B in the zeroth layer LY0 that is lower than the first layer LY1. The first lower wires M1B may extend in the first horizontal direction (the X direction). Each of the first lower wires M1B may correspond to the power supply VDD, the bit line BL, or the complementary bit line BLB and may be connected to the lower via contact bVA.

A plurality of second lower wires M2B may be in the basement layer LY(-1) that is at a lower vertical level than the zeroth layer LY0. A first lower wire M1B may be connected to a second lower wire M2B by a first lower via V1B. The second lower wires M2B may extend in the second horizontal direction (the Y direction). The second lower wires M2B may correspond to the power supply VDD.

The power supply VDD may be provided from the basement layer LY(-1) in a lower portion of the stacked integrated circuit device 3a and the ground VSS may be provided from the third layer LY3 in an upper portion of the stacked integrated circuit device 3a.

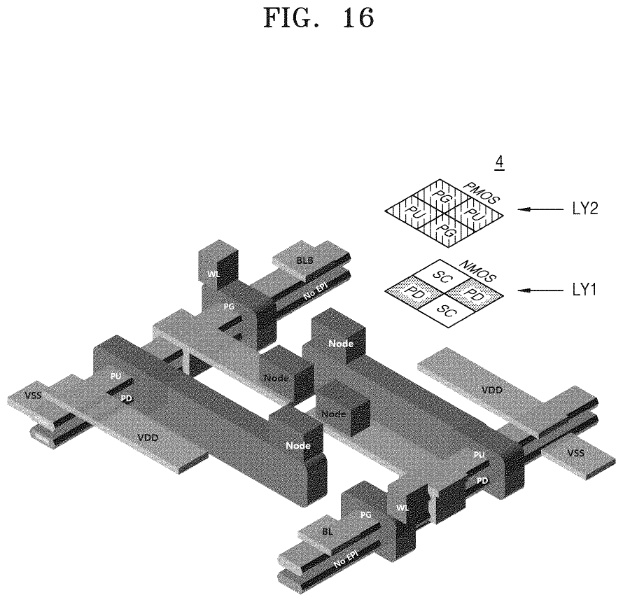

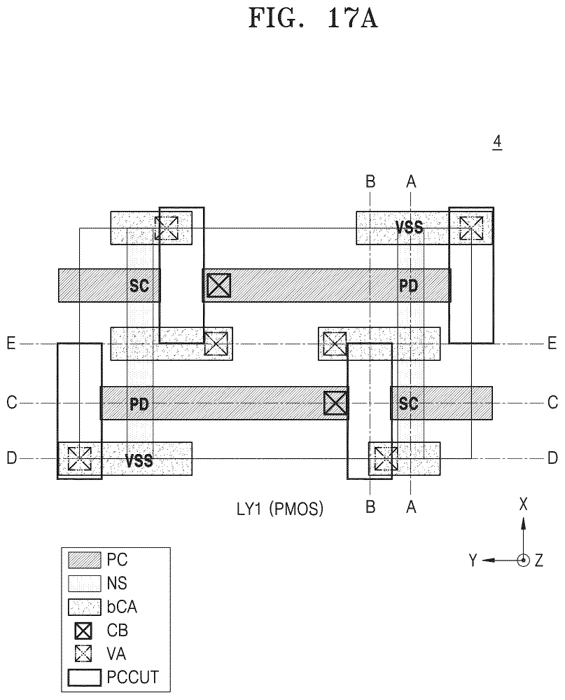

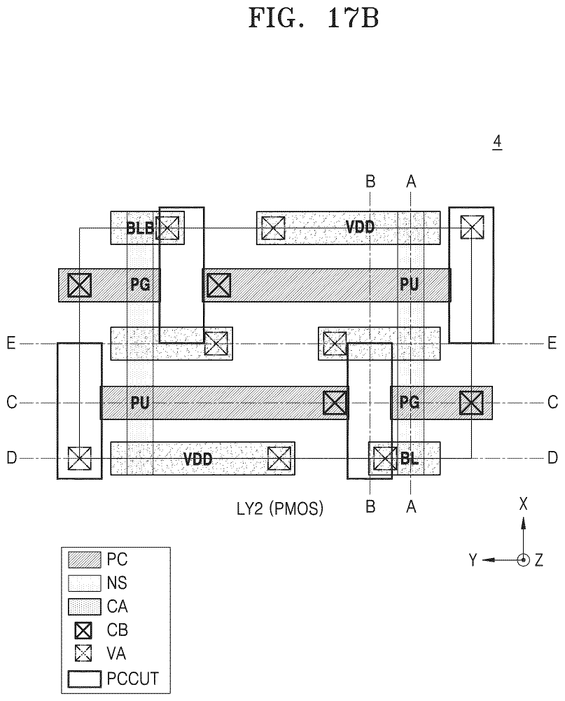

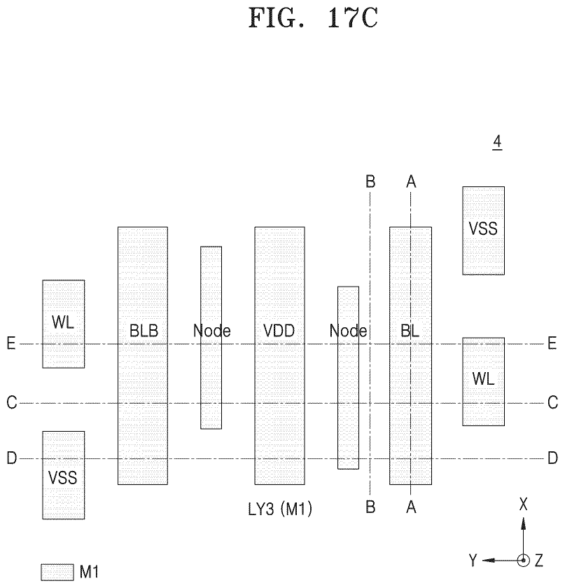

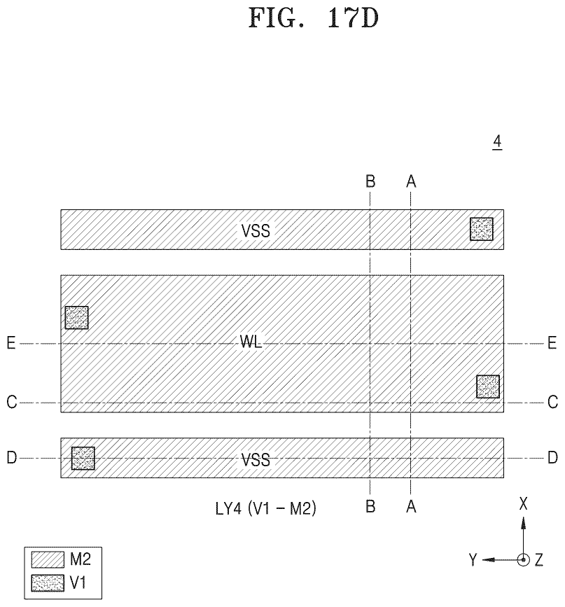

FIG. 16 is a schematic perspective view of the stacked integrated circuit device 4. FIGS. 17A to 17D show schematic layouts of the stacked integrated circuit device 4.

Referring to FIGS. 16 to 17D, the stacked integrated circuit device 4 may include a nanosheet NS, which extends in the first horizontal direction (the X direction), and a gate electrode PC, which extends in the second horizontal direction (the Y direction) that is orthogonal to the first horizontal direction (the X direction). A portion No EPI among portions of the nanosheet NS and portions of the gate electrode PC, which respectively cross the portion of the nanosheet NS, may correspond to a shared contact structure SC that does not have an epitaxial layer forming a source/drain region. The gate electrode PC, which has a portion crossing a portion of the nanosheet NS of the shared contact structure SC and extends in the second horizontal direction (the Y direction), may be divided into at least two parts by a gate cut region PCCUT that extends in the first horizontal direction (the X direction).

An upper contact CA and a lower contact bCA may be connected to source/drain regions of transistors including a pull-up transistor PU, a pull-down transistor PD, and a pass-gate transistor PG. The upper contact CA and the lower contact bCA may extend in the second horizontal direction (the Y direction). The upper contact CA may be connected to the power supply VDD, the bit line BL, and the complementary bit line BLB. The lower contact bCA may be connected to the ground VSS.

A gate contact CB may be connected to the gate electrode PC. A via contact VA may be connected to the upper contact CA and the lower contact bCA, which connect three respective source/drain regions of the pull-up transistor PU, the pull-down transistor PD, and the pass-gate transistor PG.

The via contact VA connected to the upper contact CA, which connects three respective source/drain regions of the pull-up transistor PU, the pull-down transistor PD, and the pass-gate transistor PG, may be aligned with the gate contact CB connected to the gate electrode PC, which is shared by another pull-up transistor PU and another pull-down transistor PD in different layers, in the first horizontal direction (the X direction).

A plurality of first upper wires M1 may be in the third layer LY3 that is at a higher vertical level than the second layer LY2. The first upper wires M1 may extend in the first horizontal direction (the X direction). Each of the first upper wires M1 may correspond to the power supply VDD, the ground VSS, the word line WL, the bit line BL, the complementary bit line BLB, or the shared node Node. A first upper wire M1 corresponding to the shared node Node may connect the via contact VA to the gate contact CB, wherein the via contact VA and the gate contact CB are aligned with each other in the first horizontal direction (the X direction).

A plurality of second upper wires M2 may be in the fourth layer LY4 that is at a higher vertical level than the third layer LY3. A first upper wire M1 may be connected to a second upper wire M2 by a first upper via V1. The second upper wires M2 may extend in the second horizontal direction (the Y direction). Each of the second upper wires M2 may correspond to the ground VSS or the word line WL.

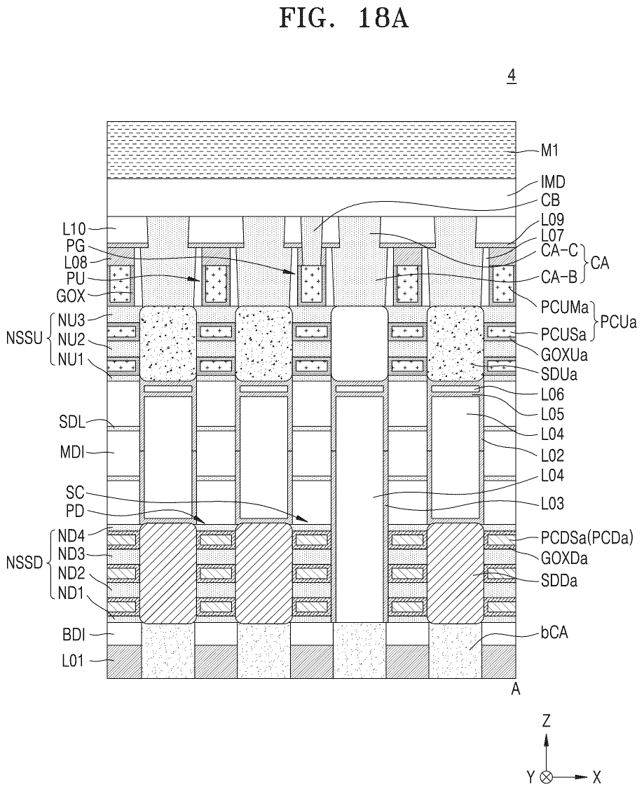

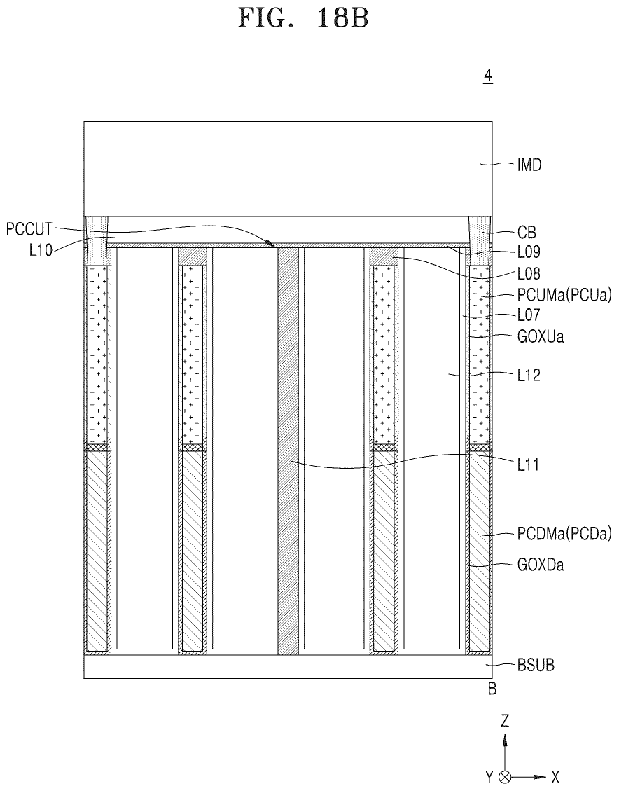

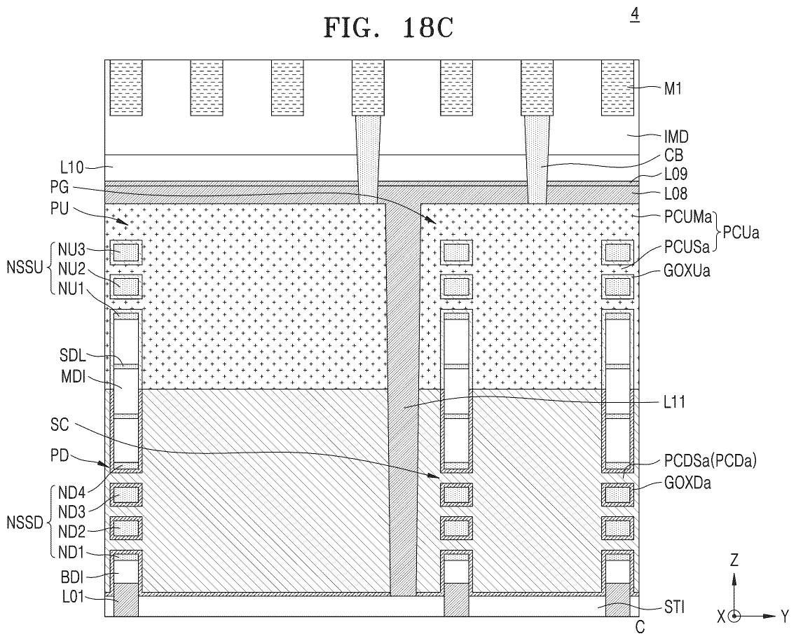

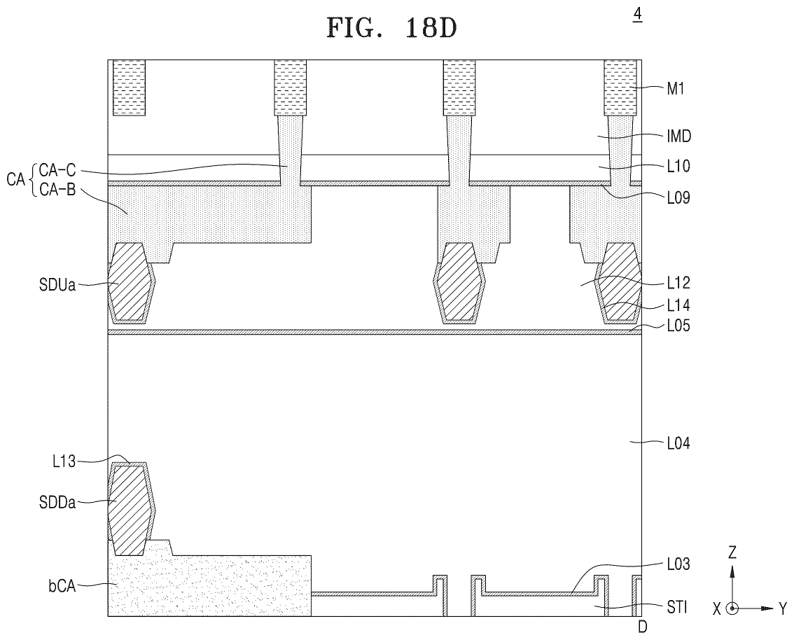

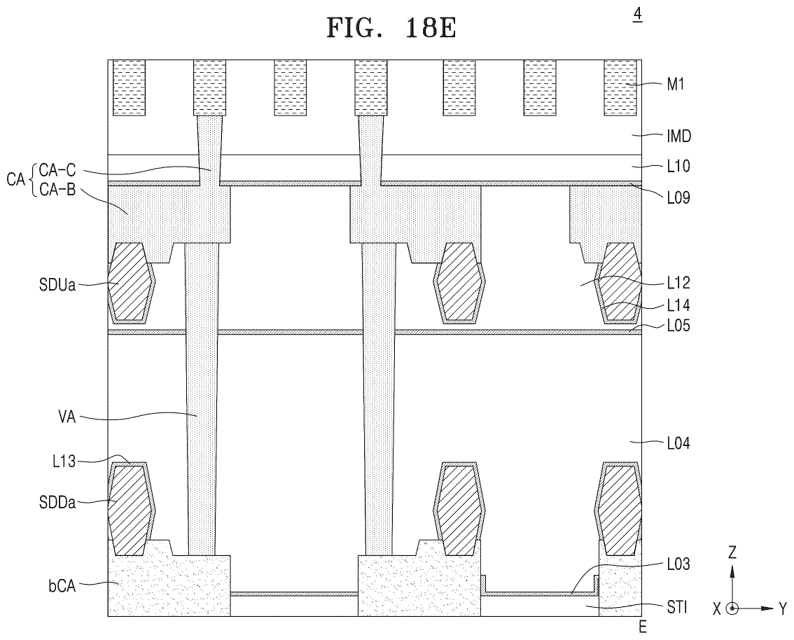

FIGS. 18A to 18E are cross-sectional views illustrating the stacked integrated circuit device 4. In detail, FIGS. 18A to 18E are cross-sectional views respectively taken along at least respective parts of lines A-A, B-B, C-C, D-D, and E-E in FIGS. 17A to 17D.

Referring to FIGS. 18A to 18E, the stacked integrated circuit device 4 may include a lower nanosheet stack structure NSSD, which includes a plurality of lower nanosheets ND1, ND2, ND3, and ND4, and an upper nanosheet stack structure NSSU, which is above the lower nanosheet stack structure NSSD and includes a plurality of upper nanosheets NU1, NU2, and NU3. The lower nanosheet stack structure NSSD may be in the first layer LY1 in FIGS. 16 to 17D, and the upper nanosheet stack structure NSSU may be in the second layer LY2 in FIGS. 16 to 17D.

A lower gate electrode PCDa may surround the lower nanosheets ND1, ND2, ND3, and ND4. The lower gate electrode PCDa may include a sub lower gate electrode PCDSa, which is arranged among the lower nanosheets ND1, ND2, ND3, and ND4, and a main lower gate electrode PCDMa, which surrounds the lower nanosheets ND1, ND2, ND3, and ND4 and the sub lower gate electrode PCDSa. A lower gate insulating film GOXDa may be between the lower gate electrode PCDa and each of the lower nanosheets ND1, ND2, ND3, and ND4.

An upper gate electrode PCUa may surround the upper nanosheets NU1, NU2, and NU3. The upper gate electrode PCUa may include a sub upper gate electrode PCUSa, which is arranged among the upper nanosheets NU1, NU2, and NU3, and a main upper gate electrode PCUMa, which surrounds the upper nanosheets NU1, NU2, and NU3 and the sub upper gate electrode PCUSa. An upper gate insulating film GOXUa may be between the upper gate electrode PCUa and each of the upper nanosheets NU1, NU2, and NU3.

The lower gate electrode PCDa and the upper gate electrode PCUa may overlap with each other in the vertical direction (the Z direction). The lower gate electrode PCDa and the upper gate electrode PCUa overlapping with each other in the vertical direction (the Z direction) may correspond to the gate electrode PC in FIGS. 17A and 17B. A plurality of lower gate electrodes PCDa and a plurality of upper gate electrodes PCUa respectively overlapping with the lower gate electrodes PCDa in the vertical direction (the Z direction), i.e., a plurality of gate electrodes PC, may extend in the second horizontal direction (the Y direction) and may be separated from each other at substantially regular intervals in the first horizontal direction (the X direction). A gate cut region PCCUT may be formed by removing a lower gate electrode PCDa and an upper gate electrode PCUa of one of the gate electrodes PC, which are arranged at substantially regular intervals in the first horizontal direction (the X direction), the lower gate insulating film GOXDa surrounding the lower gate electrode PCDa, and the upper gate insulating films GOXUa surrounding the upper gate electrode PCUa.

Some of a plurality of upper source/drain regions SDU may respectively overlap with a plurality of lower source/drain regions SDD in the vertical direction (the Z direction). A lower source/drain region SDD may not be arranged below each of the other upper source/drain regions SDU. To form a shared contact structure SC described with reference to FIGS. 17A to 17D, at least one lower source/drain region SDD and a source/drain electrode, i.e., the lower contact bCA, which is connected to the lower source/drain region SDD, may not be formed in a region below the other upper source/drain regions SDU, wherein lower source/drain regions SDD respectively overlapping with the other upper source/drain regions SDU are not arranged in the region below the other upper source/drain regions SDU.

The lower nanosheets ND1, ND2, ND3, and ND4 may include impurities of a different conductivity type than the upper nanosheets NU1, NU2, and NU3. For example, the lower nanosheets ND1, ND2, ND3, and ND4 may include impurities of the second conductivity type and the upper nanosheets NU1, NU2, and NU3 may include impurities of the first conductivity type. The lower nanosheet stack structure NSSD including the lower nanosheets ND1, ND2, ND3, and ND4 may constitute an NMOS transistor and the upper nanosheet stack structure NSSU including the upper nanosheets NU1, NU2, and NU3 may constitute a PMOS transistor.

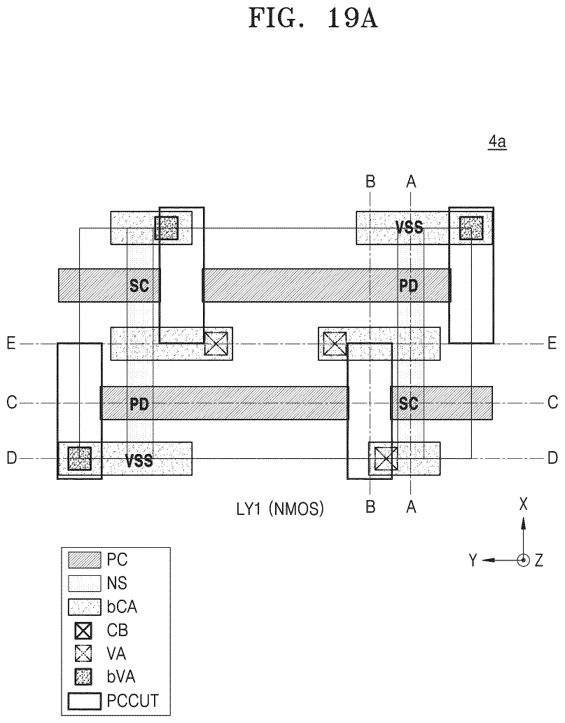

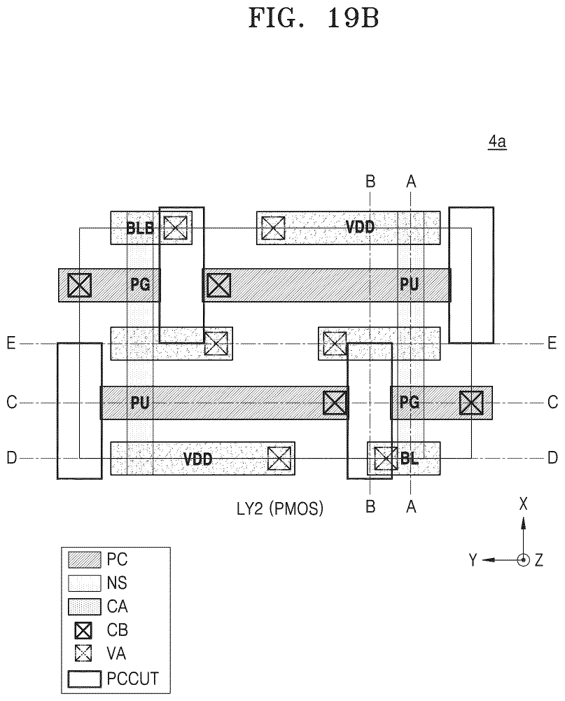

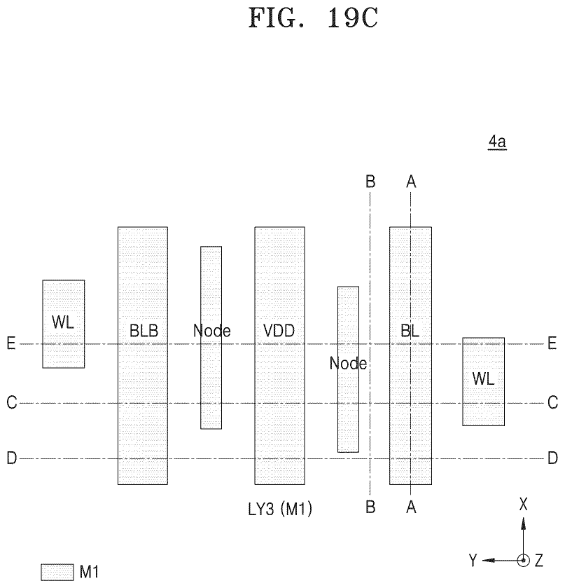

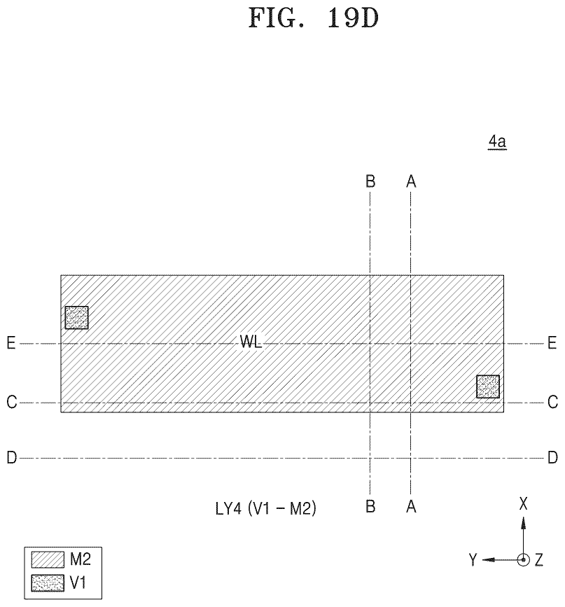

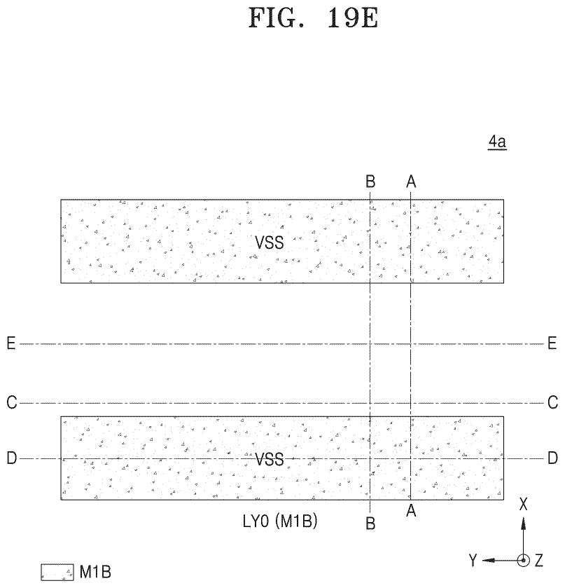

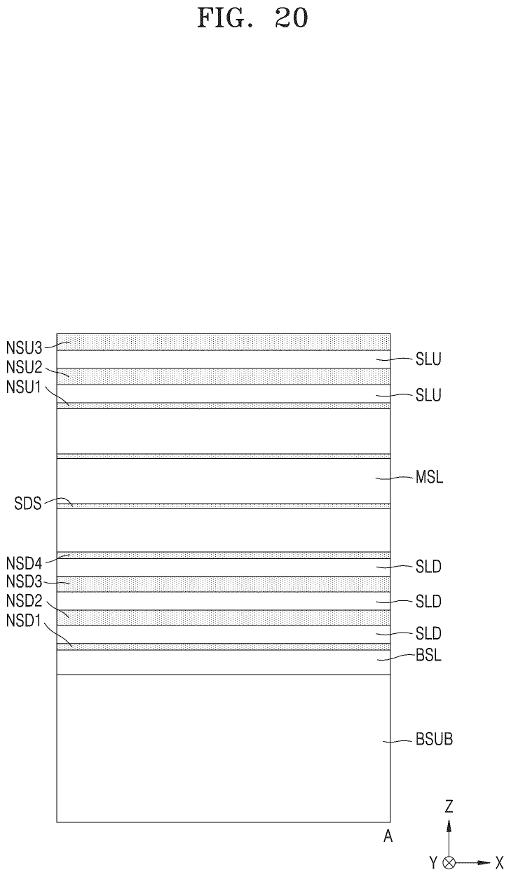

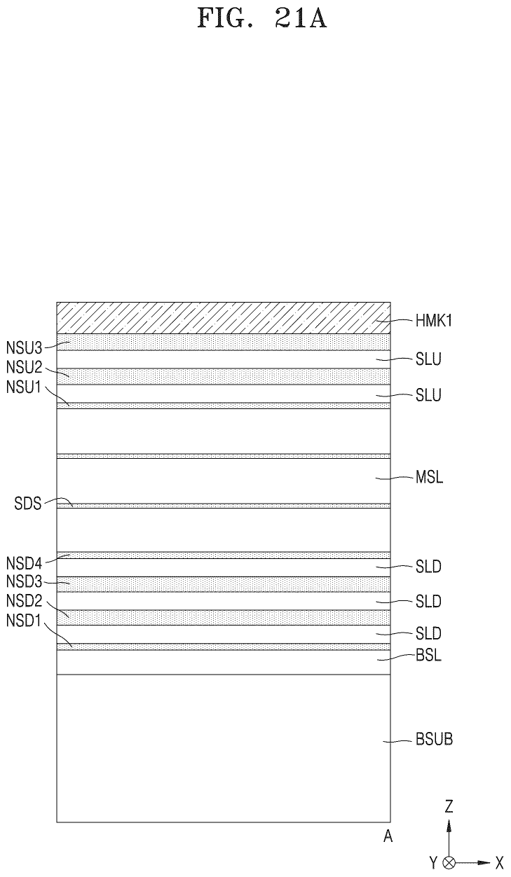

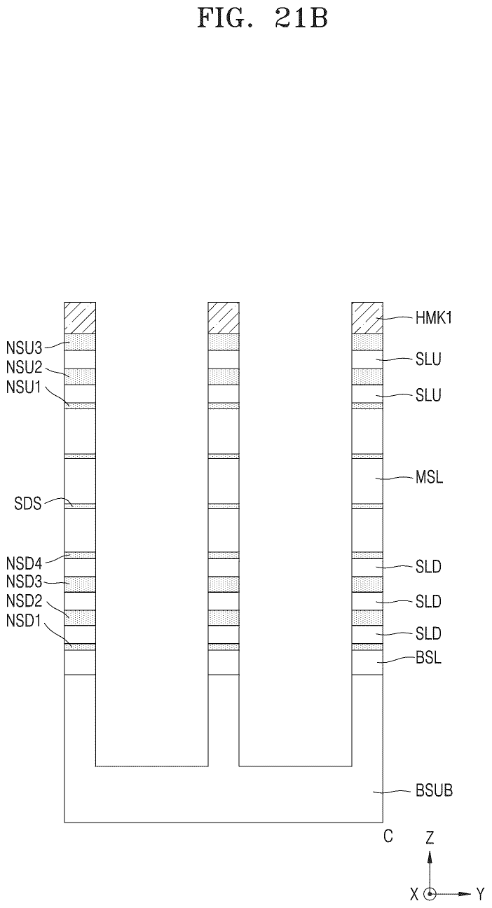

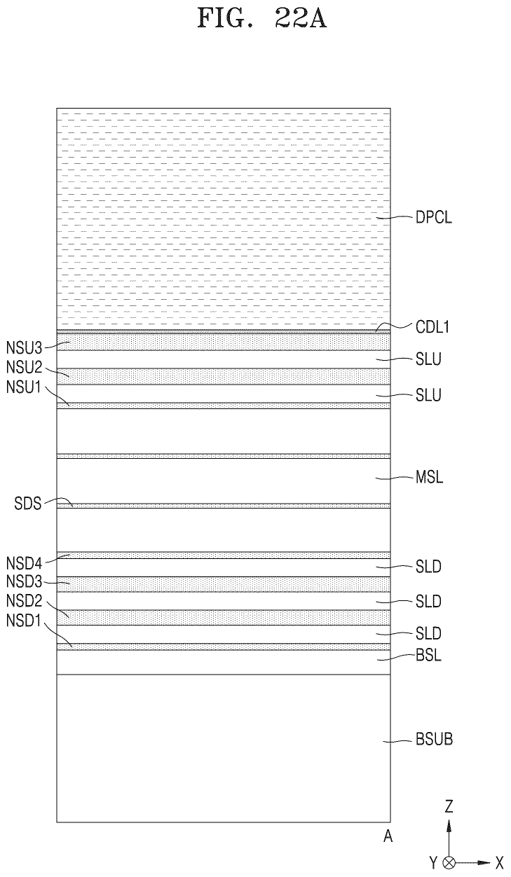

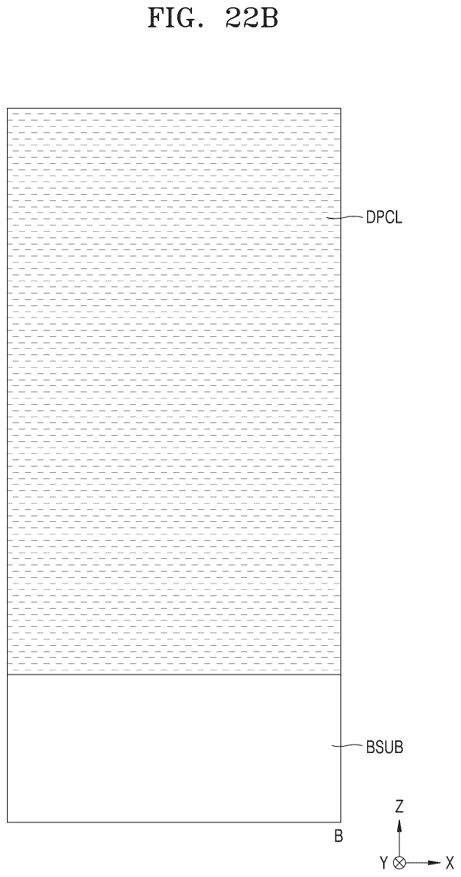

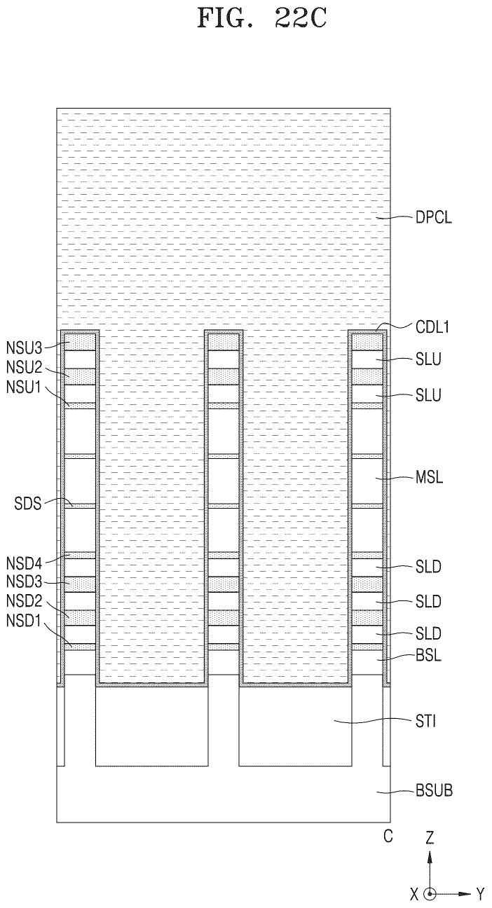

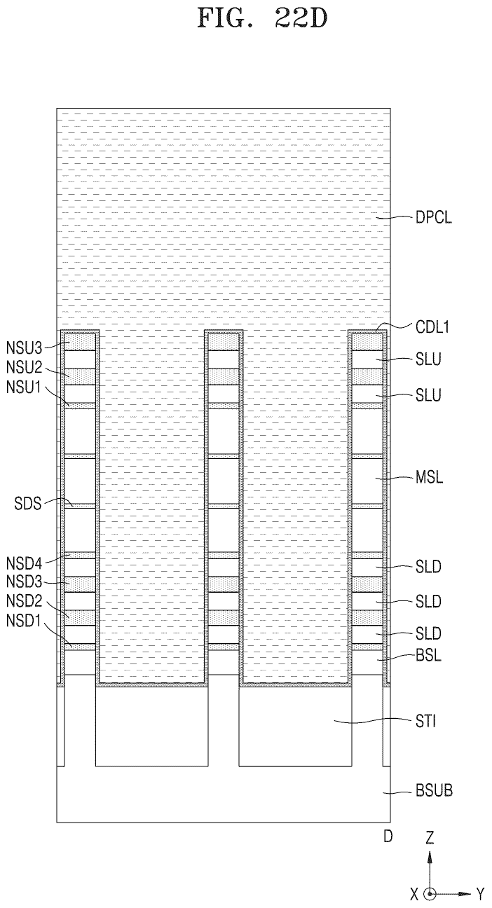

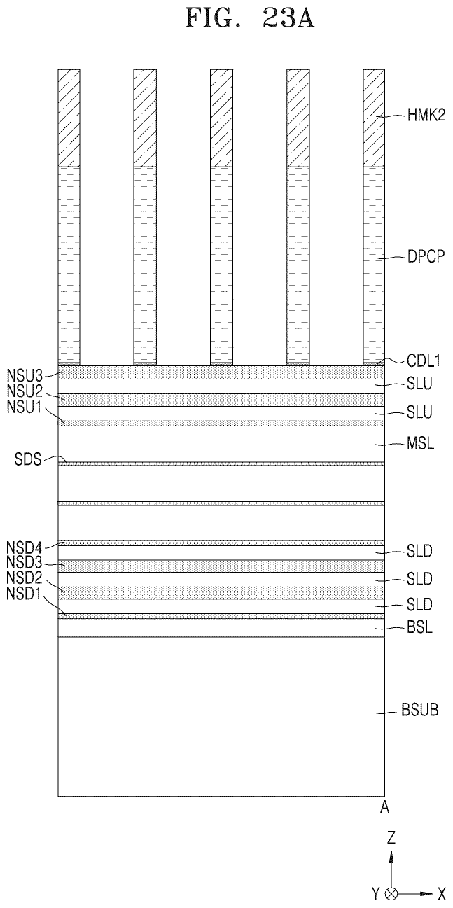

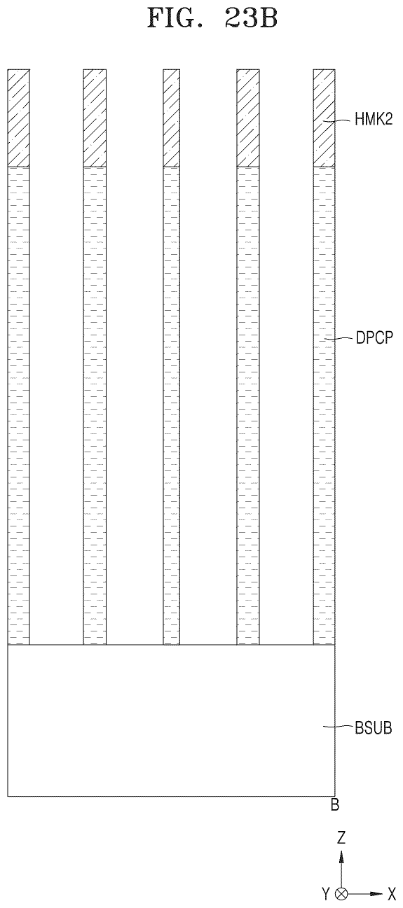

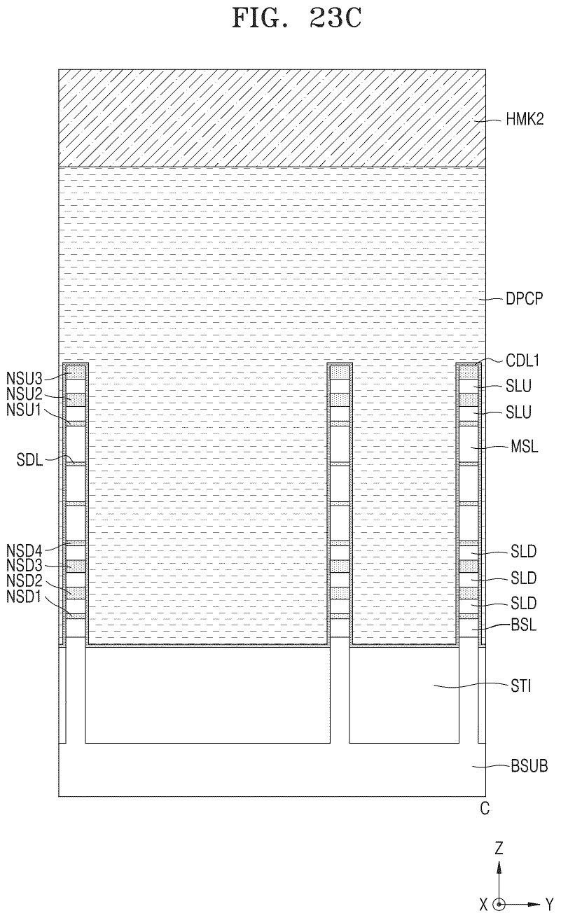

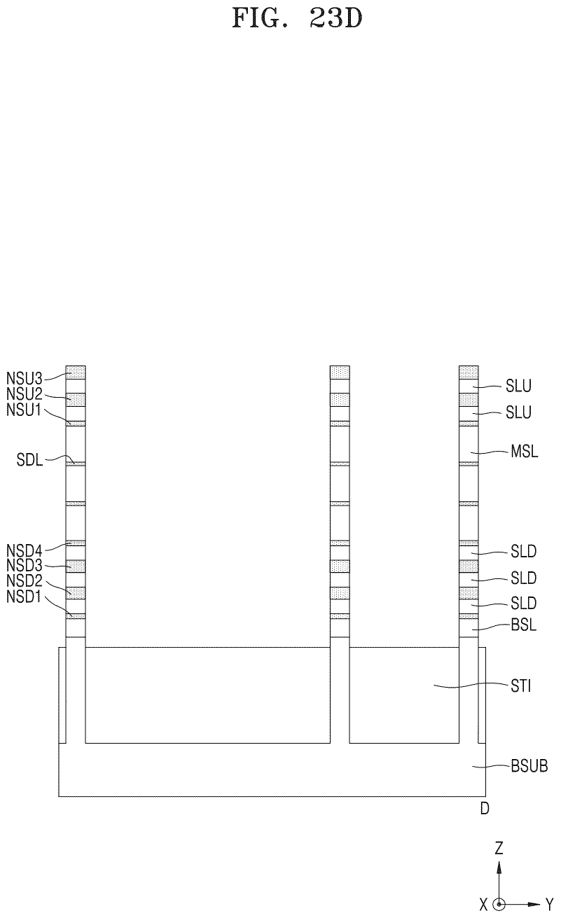

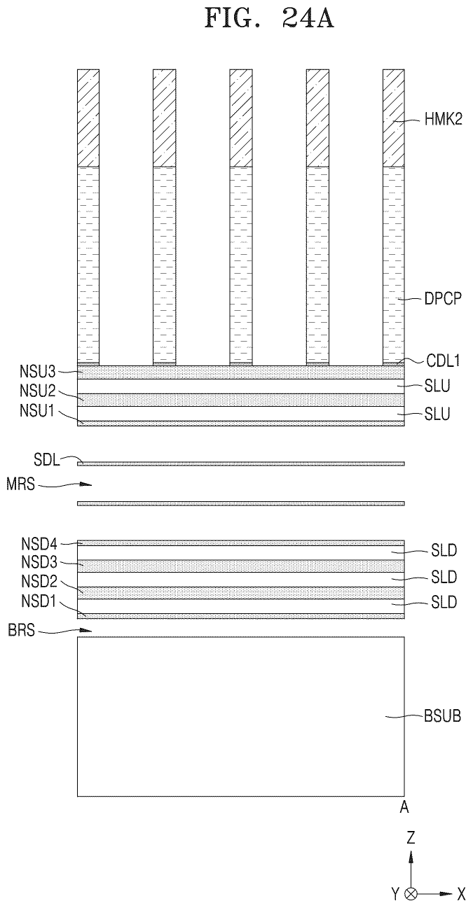

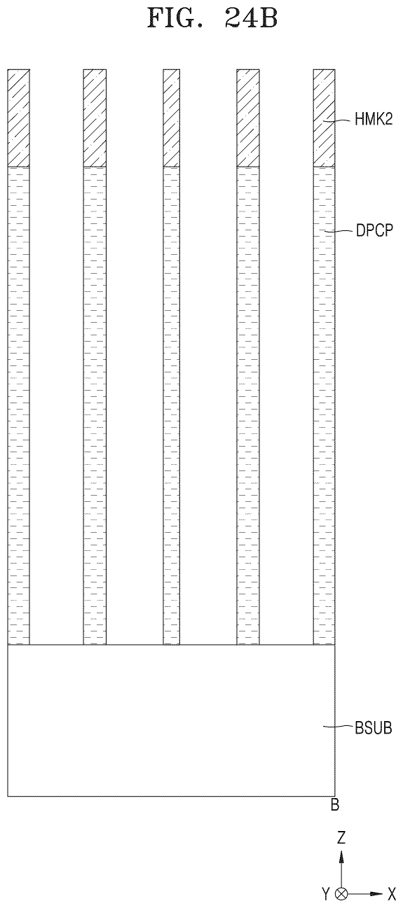

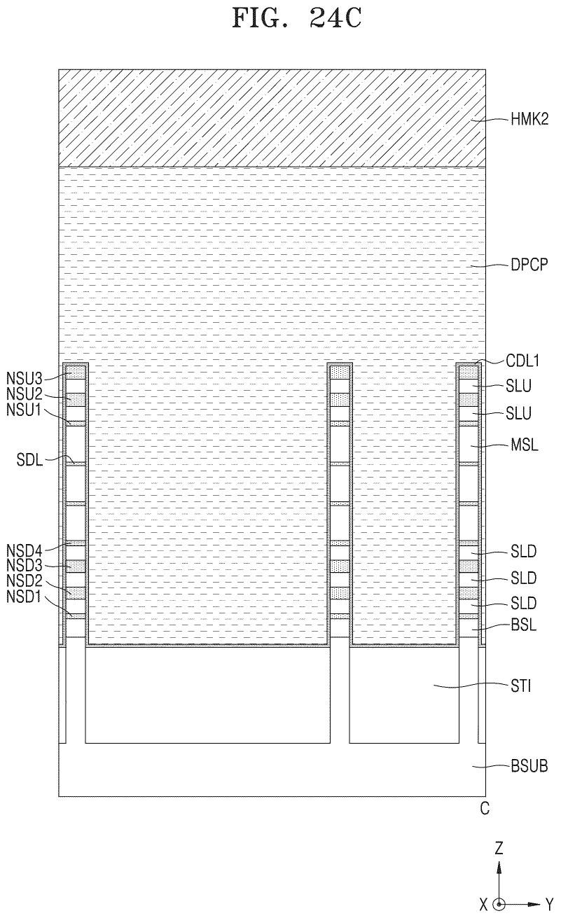

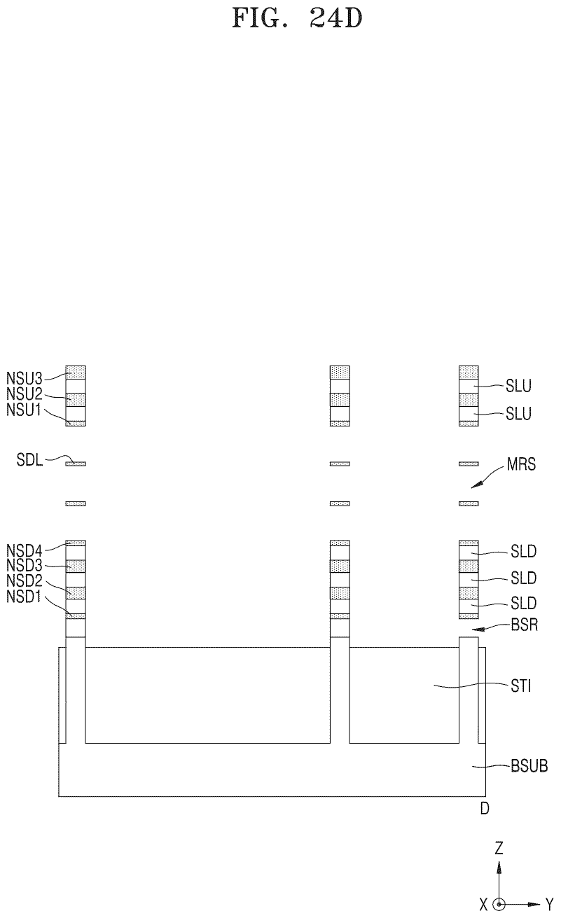

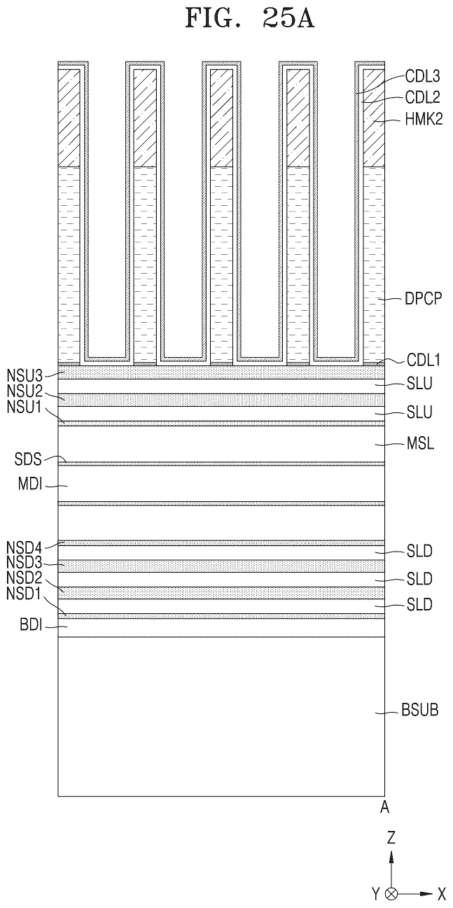

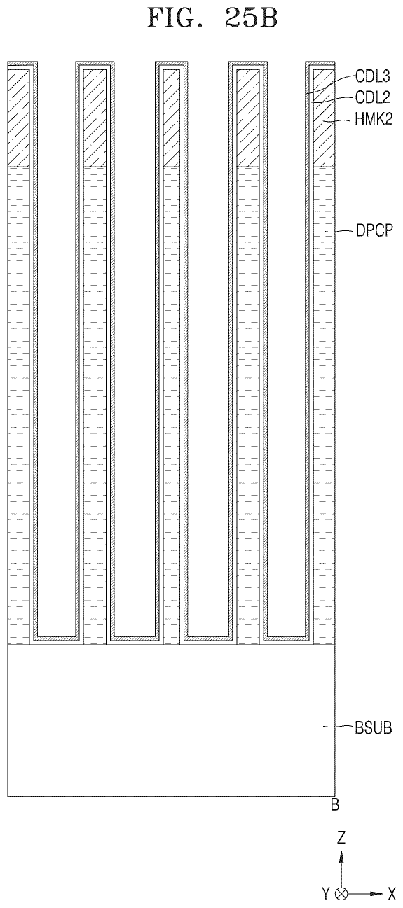

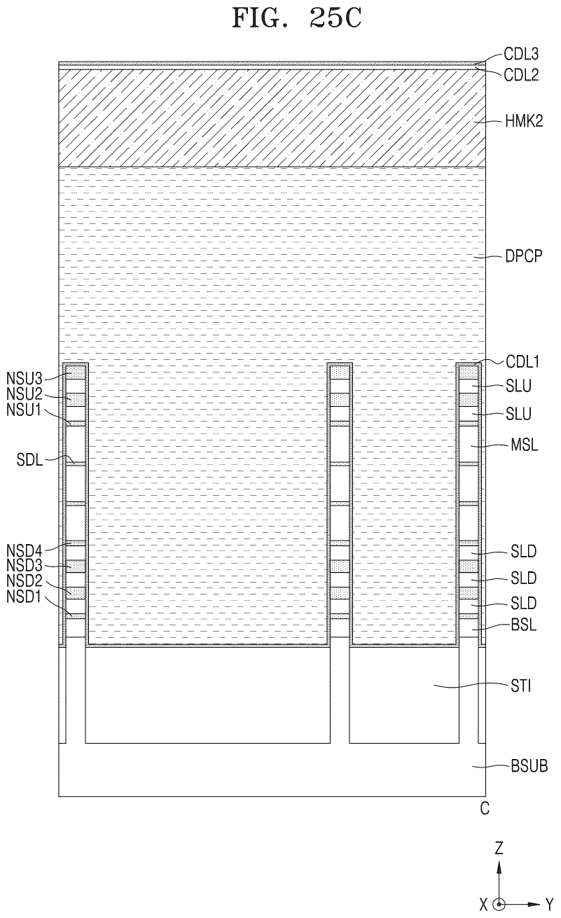

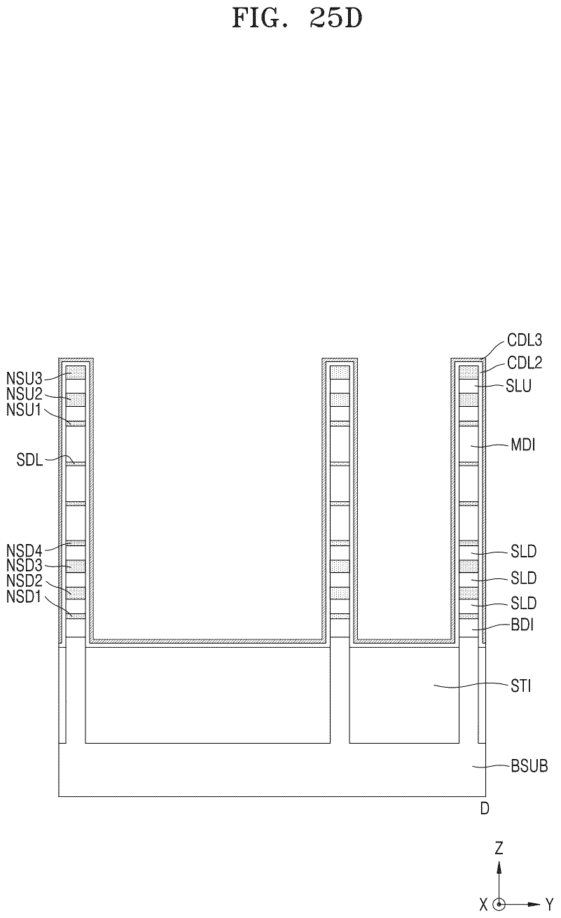

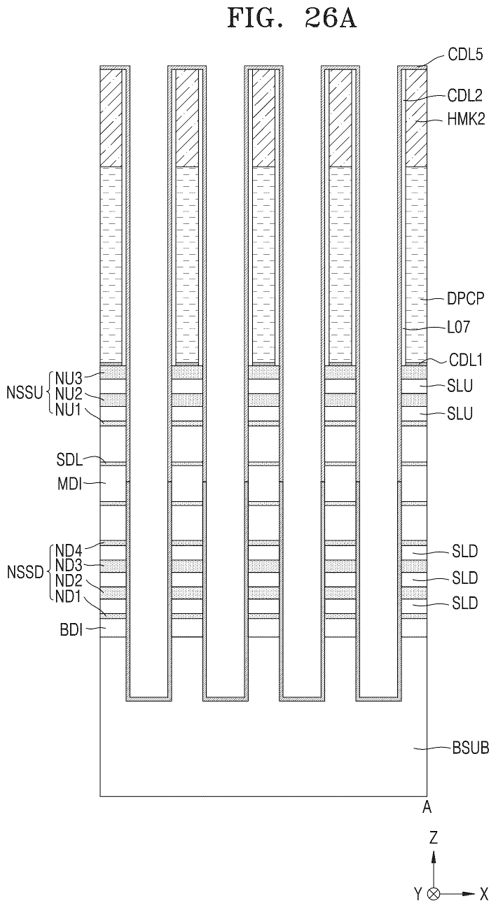

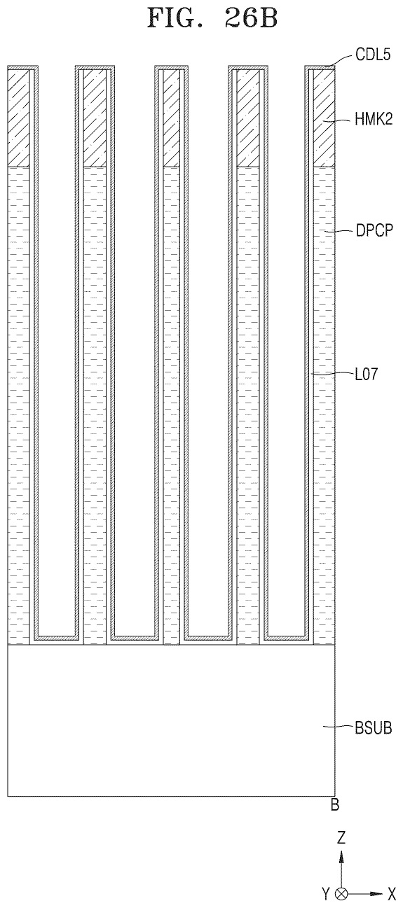

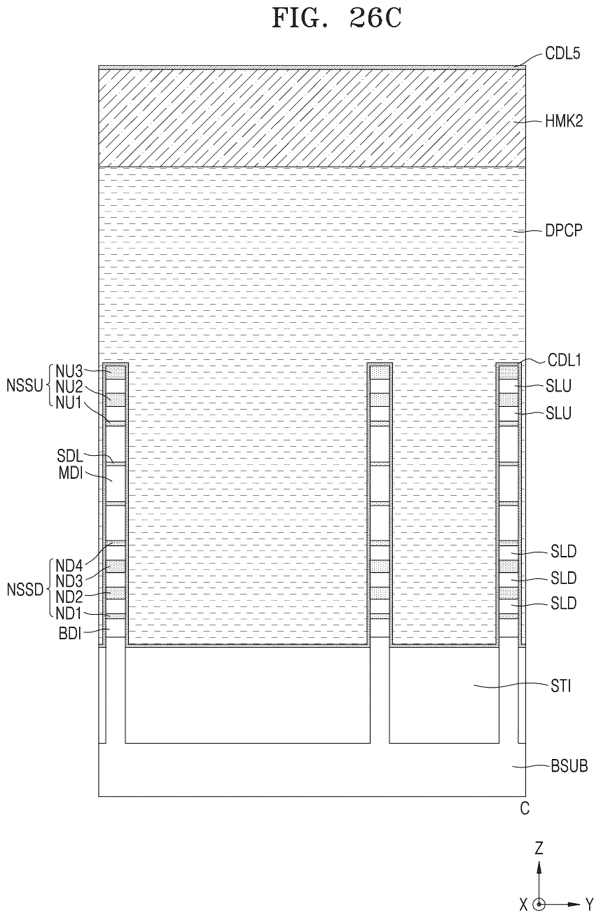

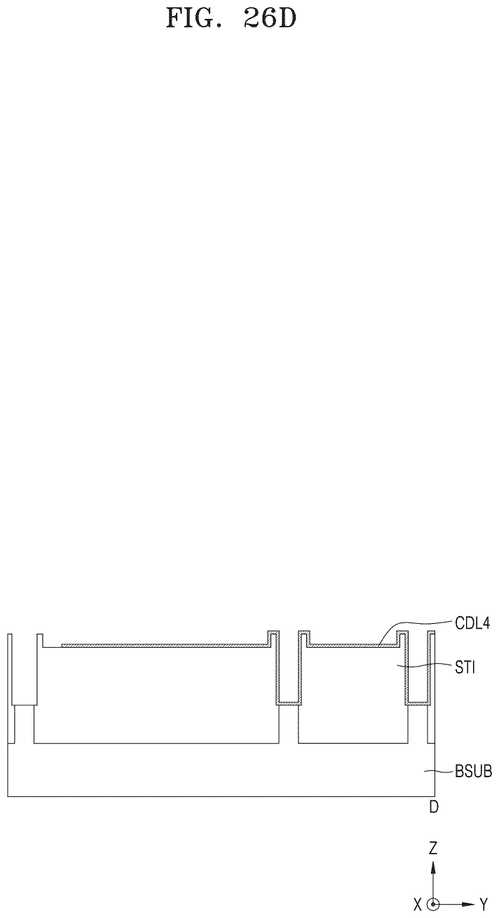

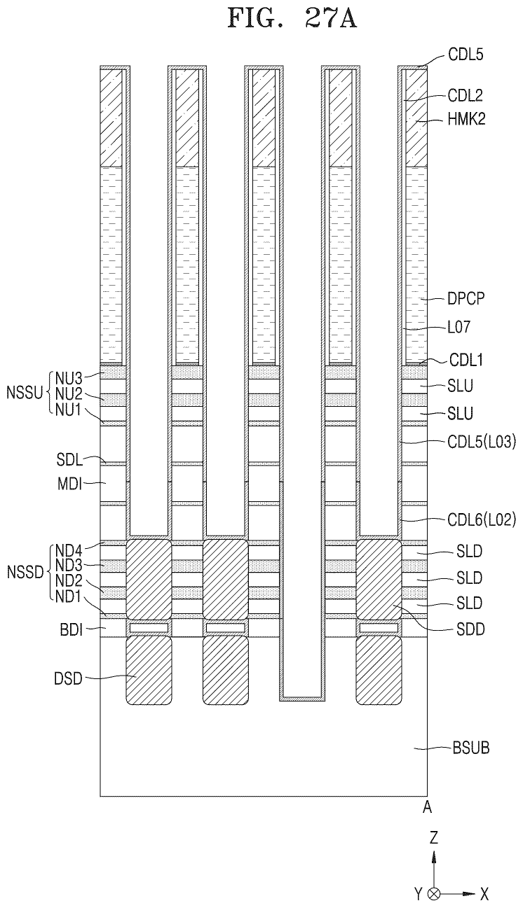

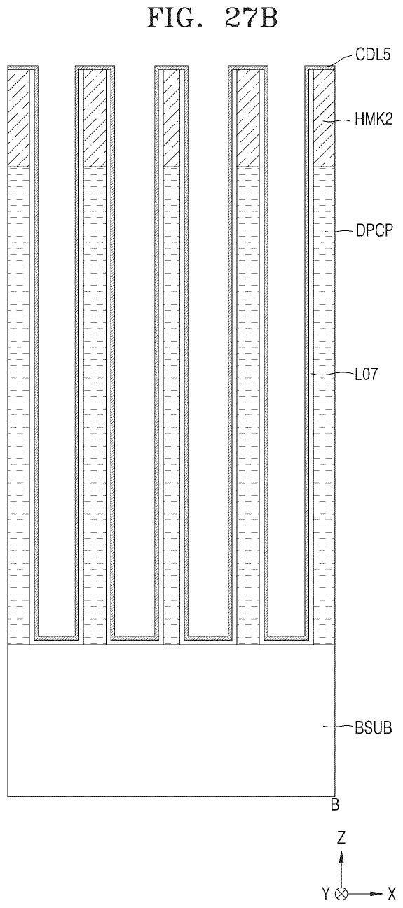

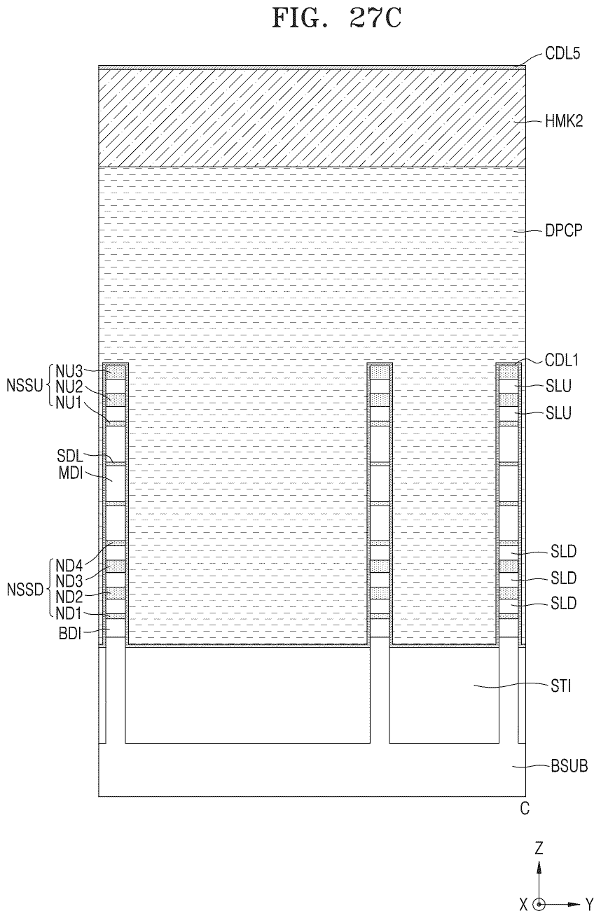

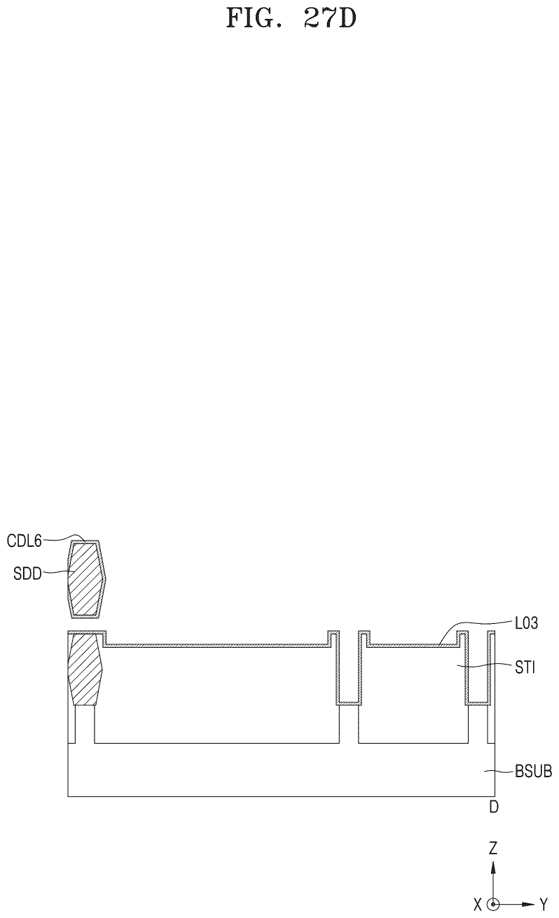

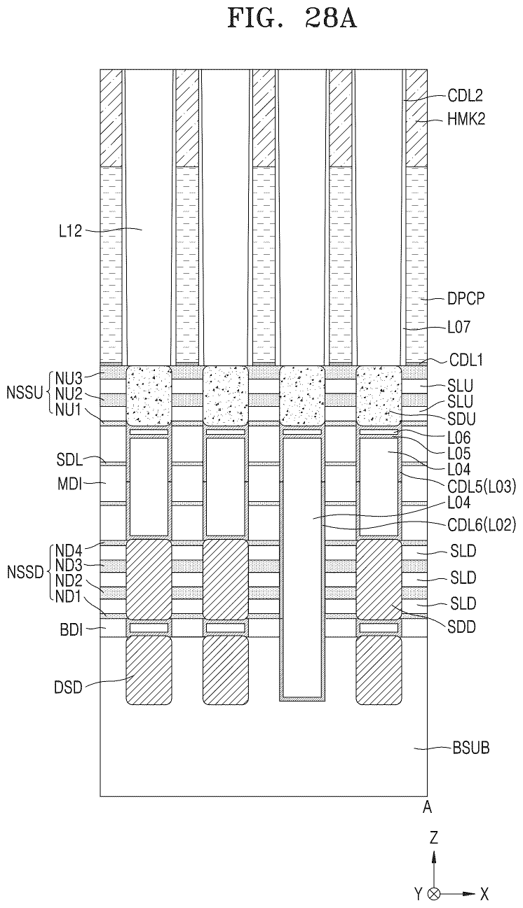

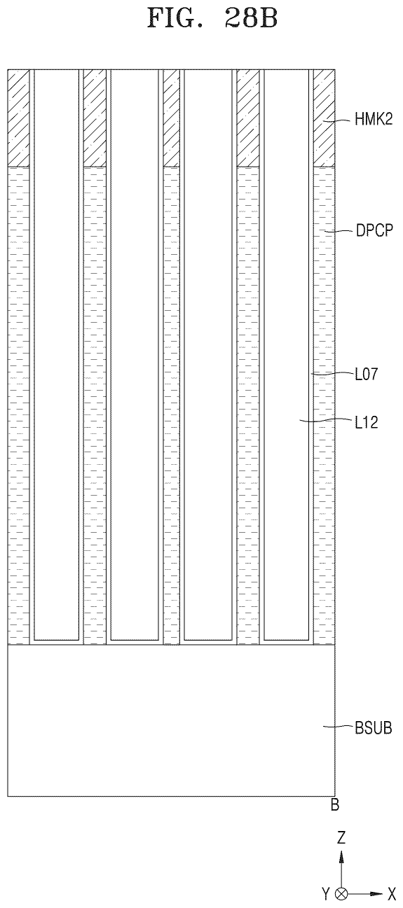

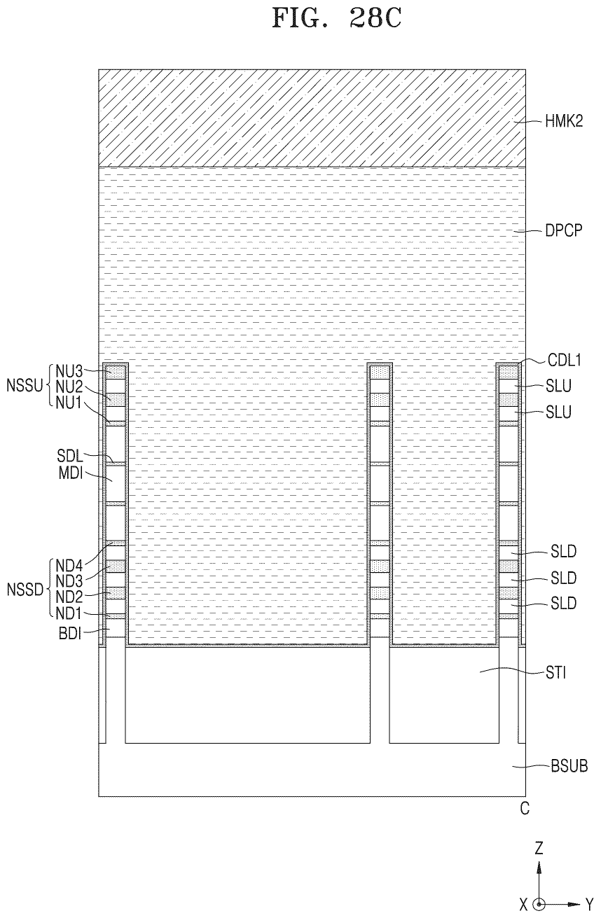

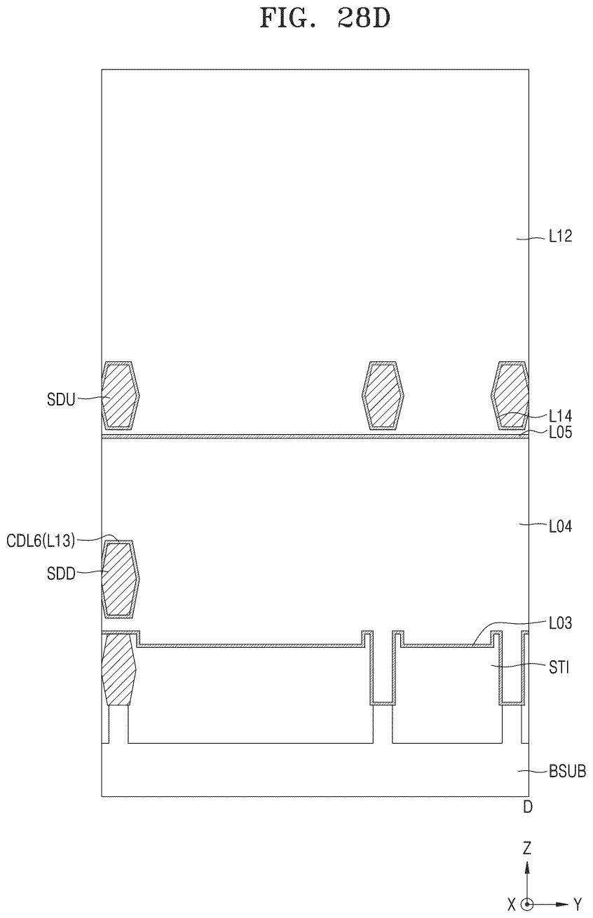

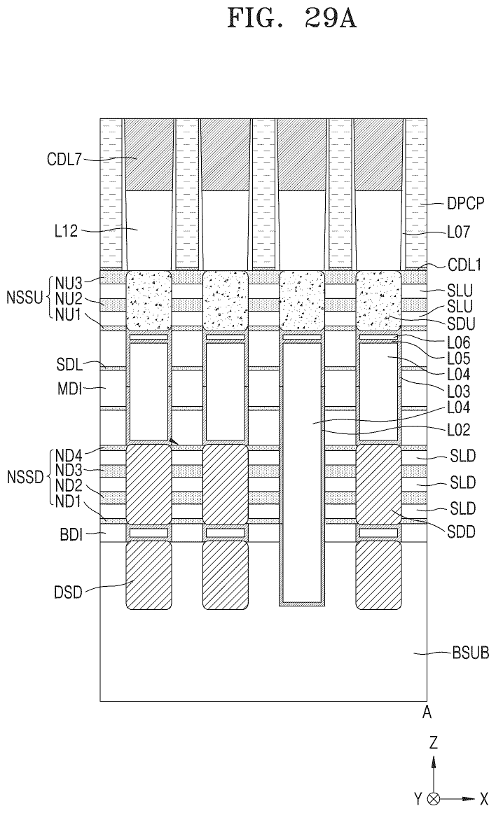

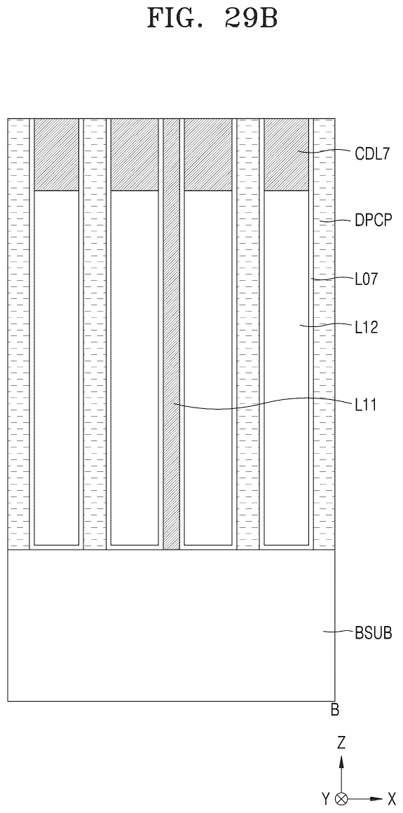

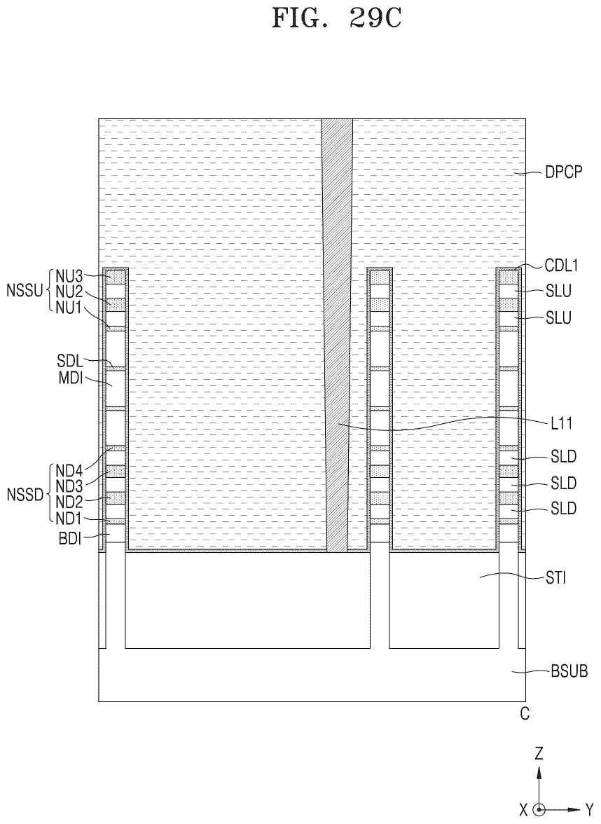

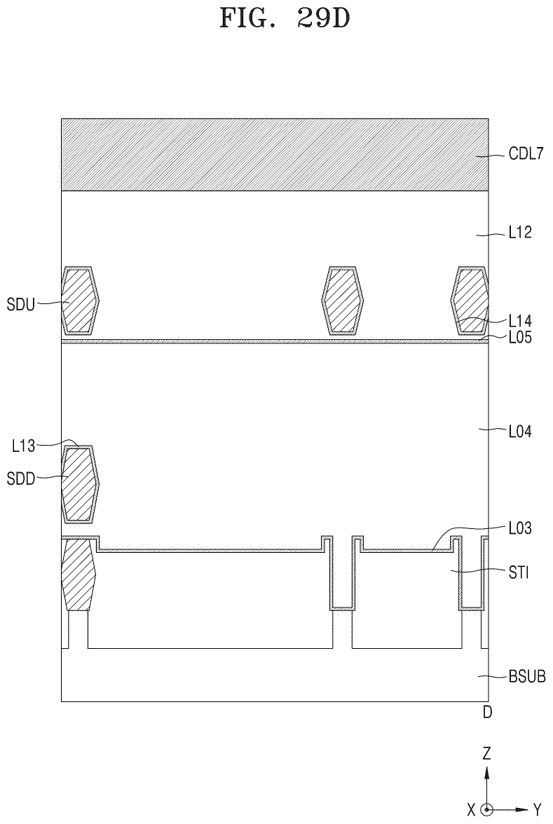

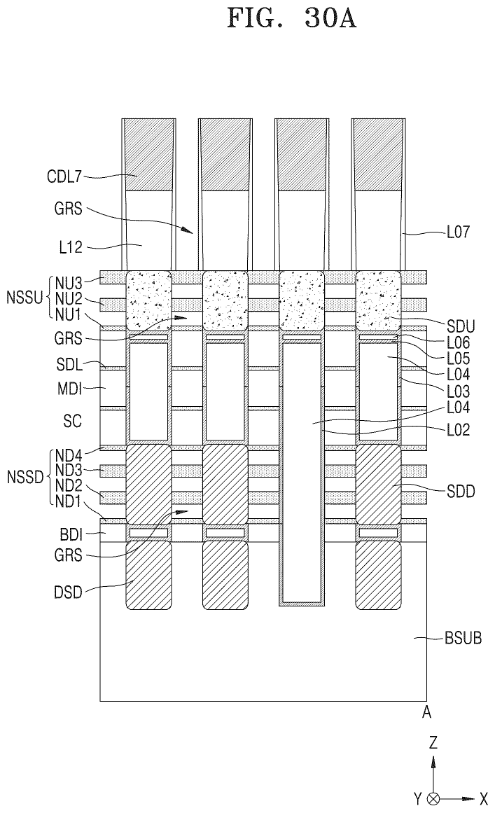

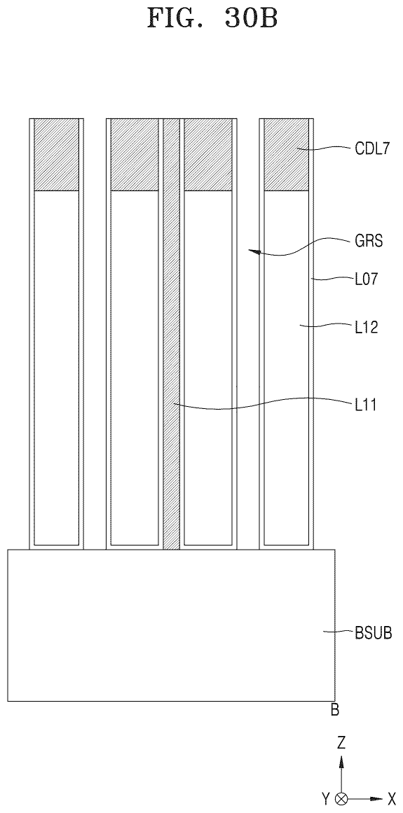

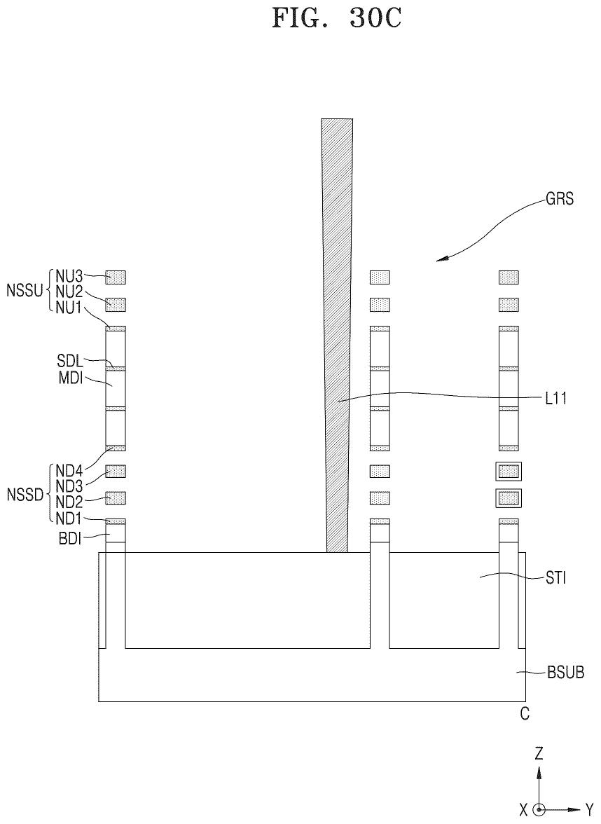

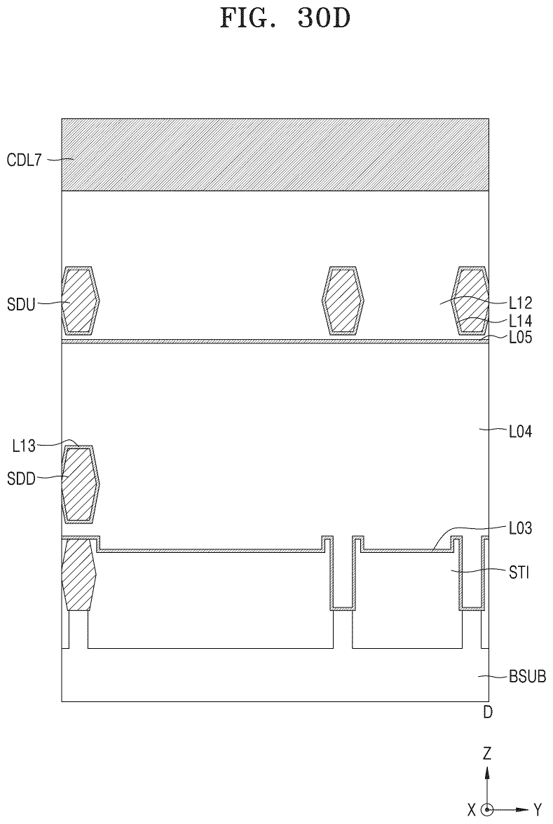

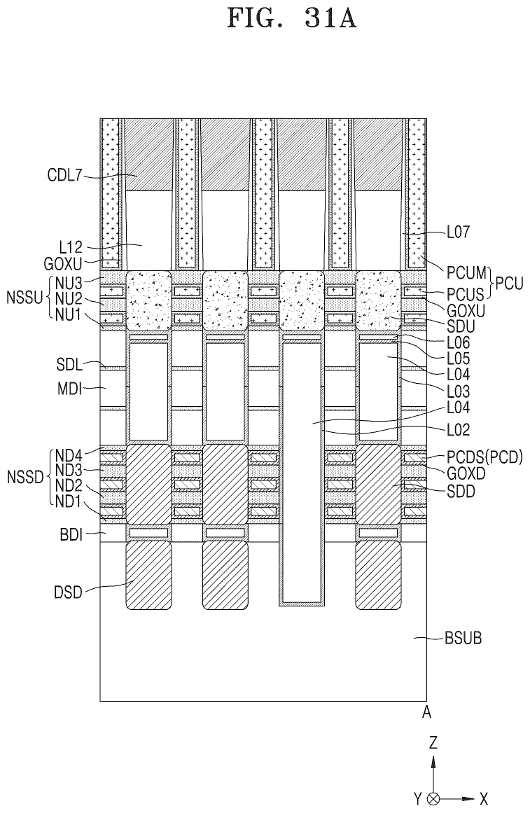

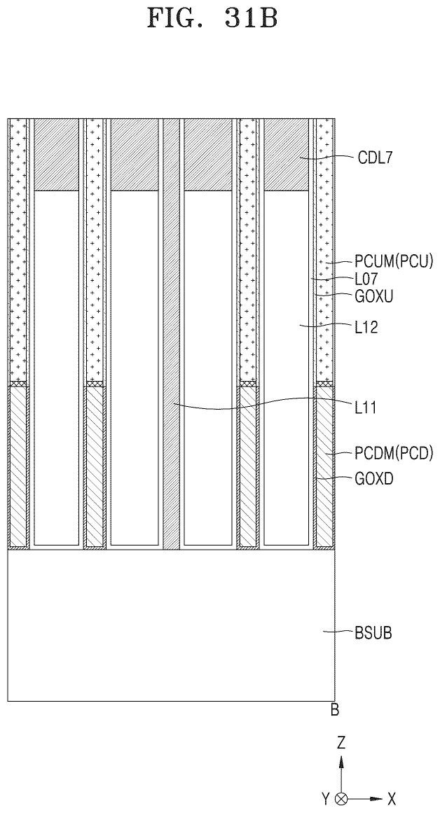

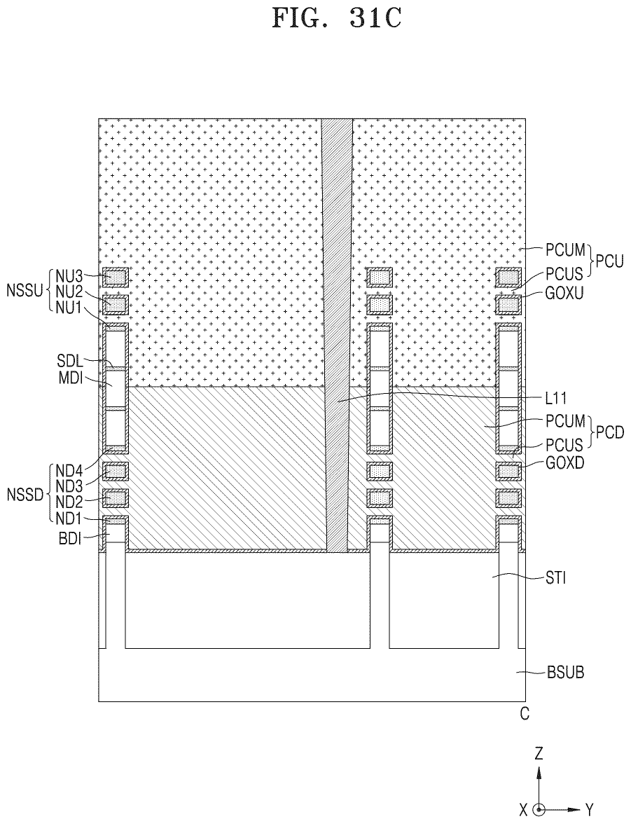

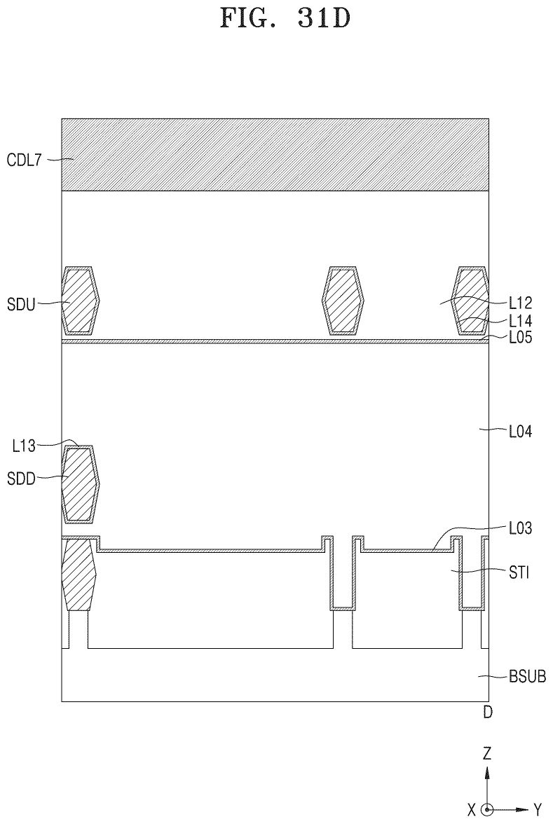

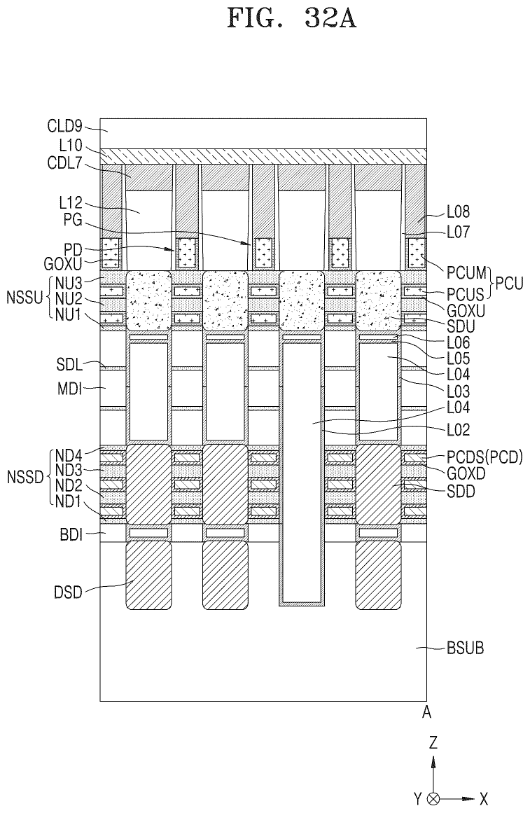

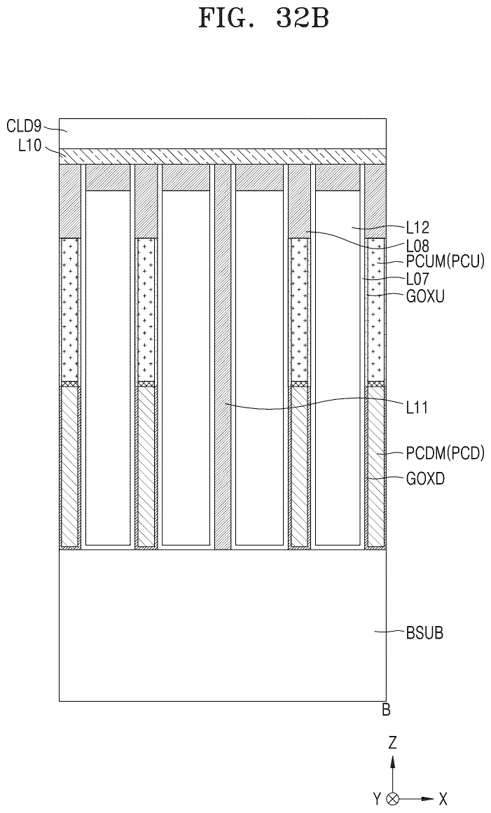

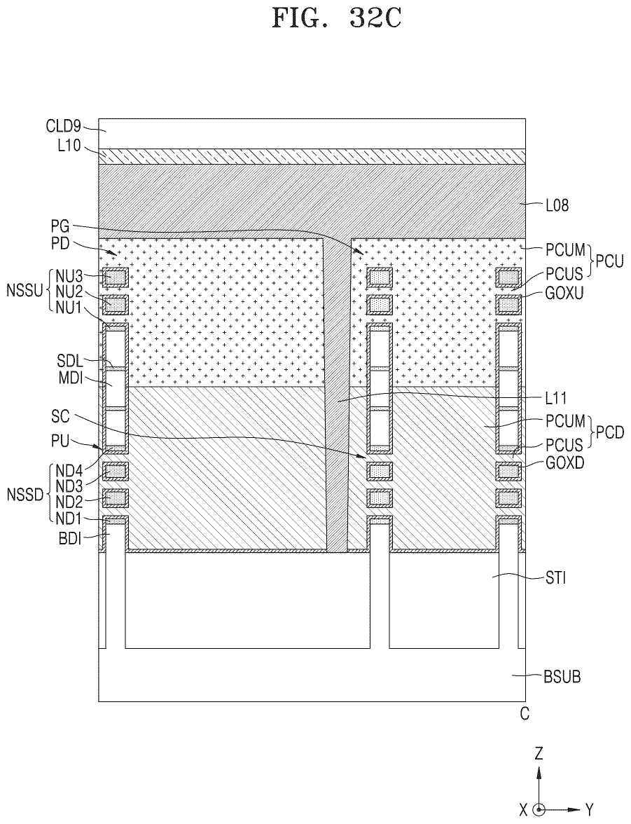

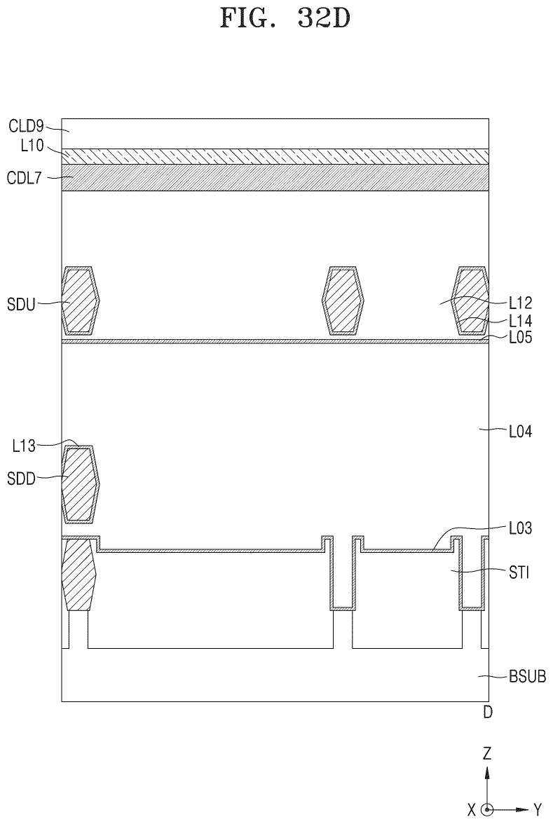

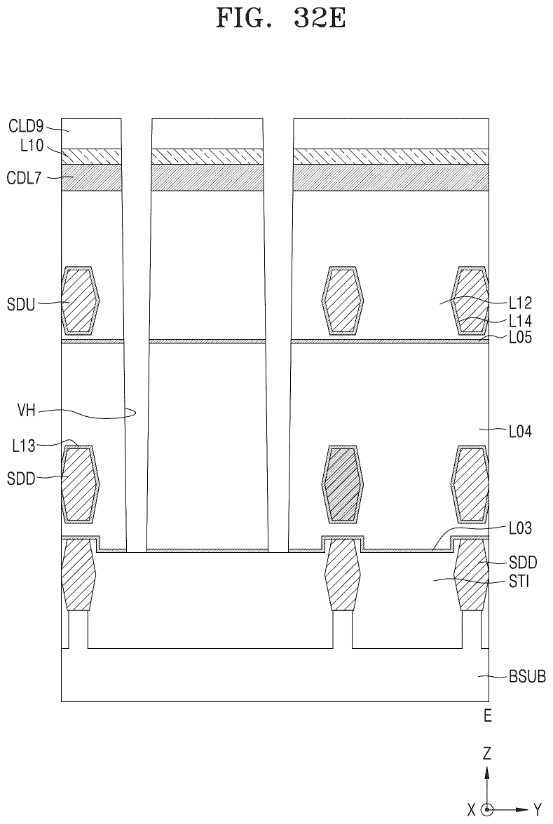

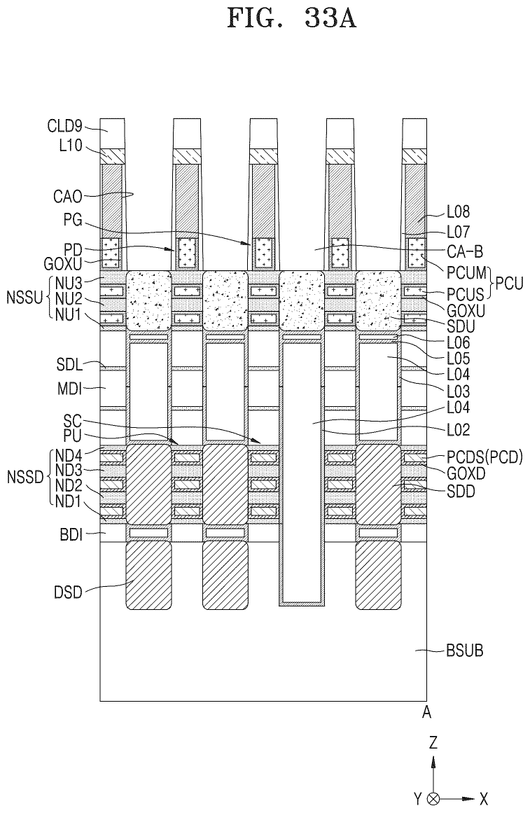

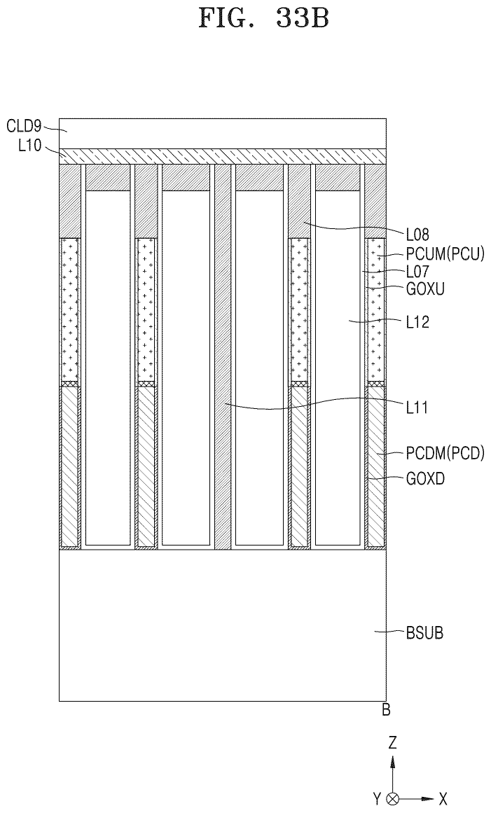

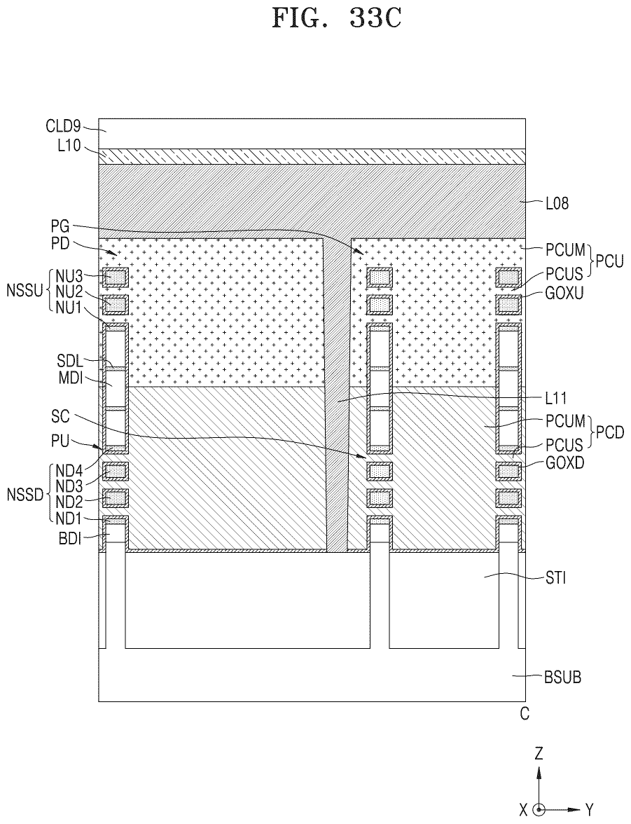

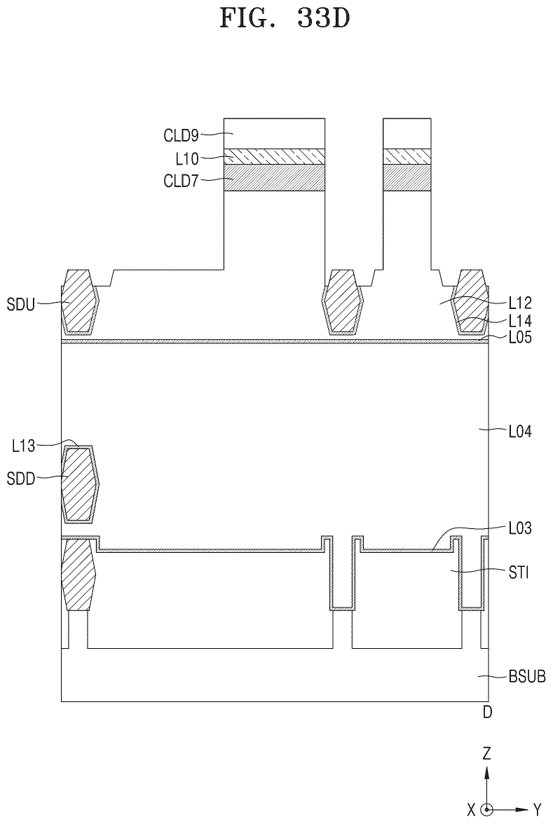

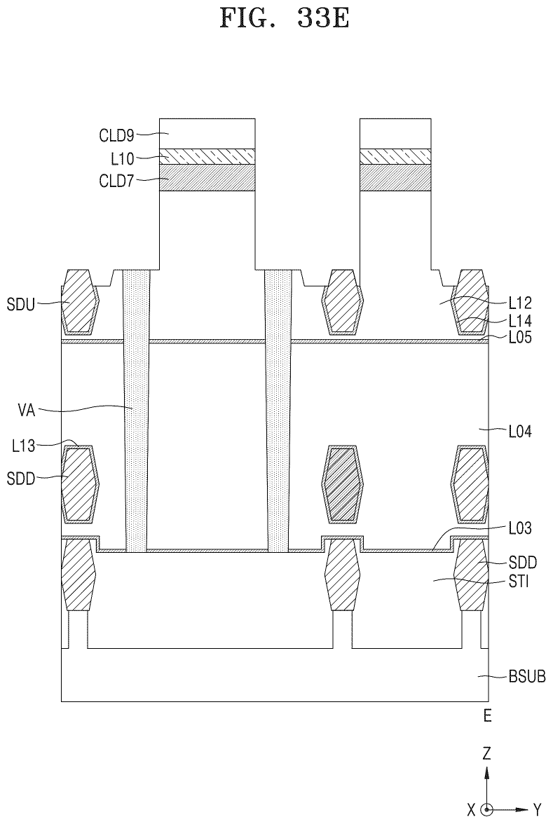

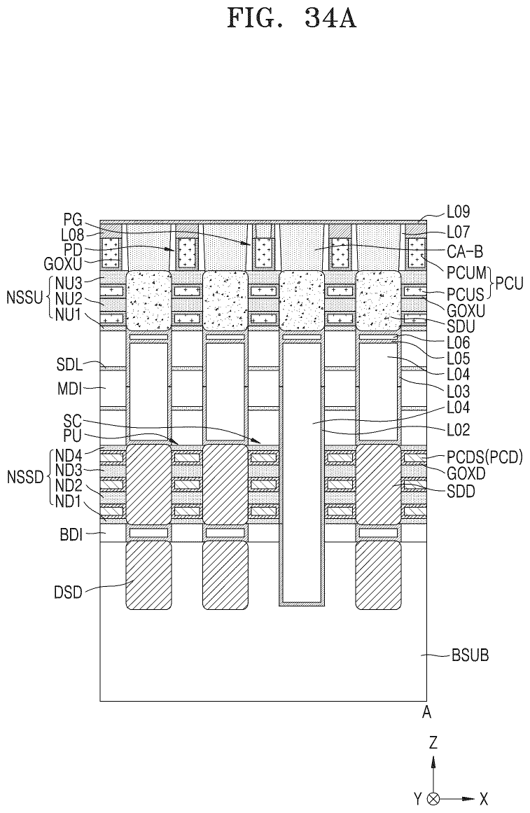

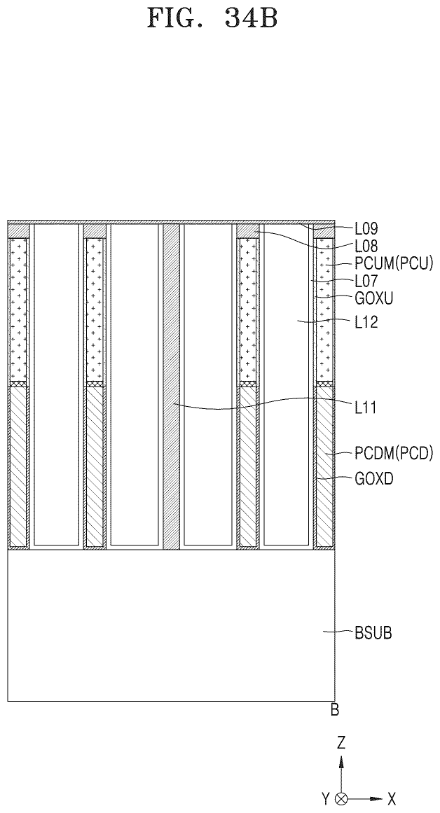

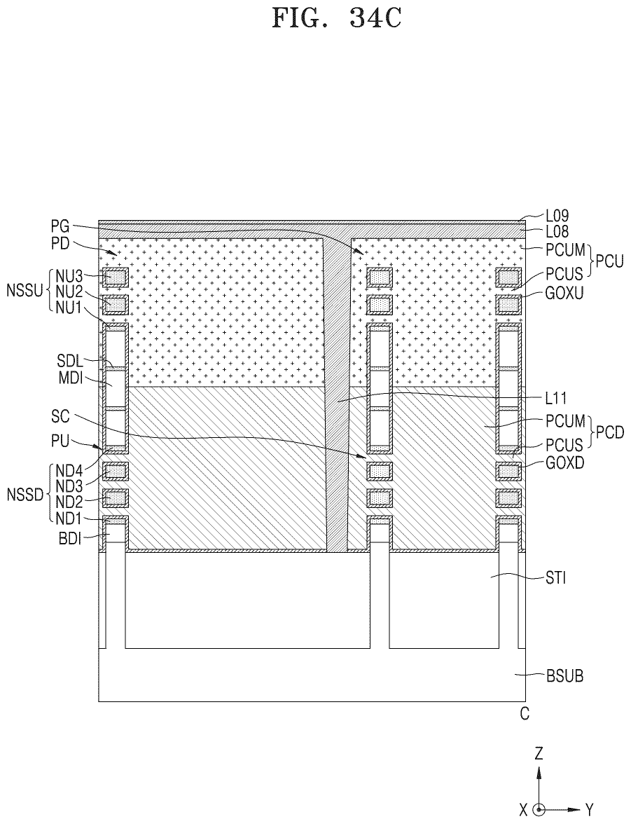

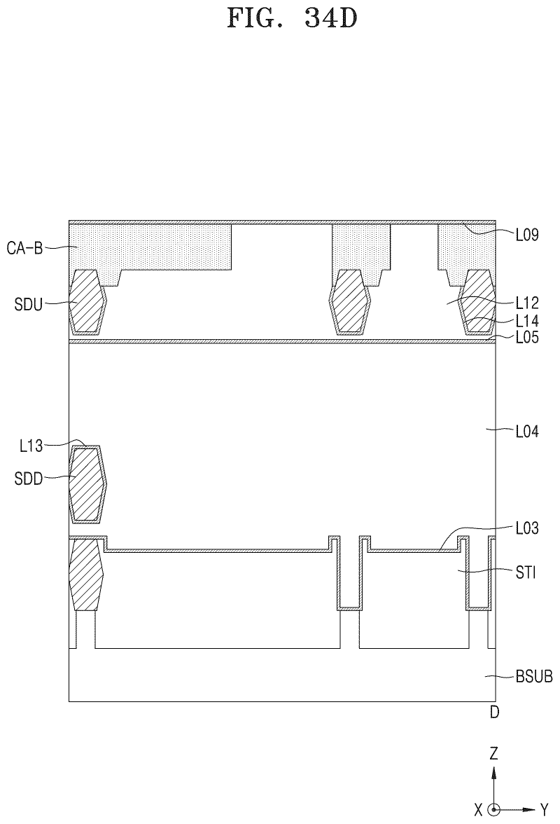

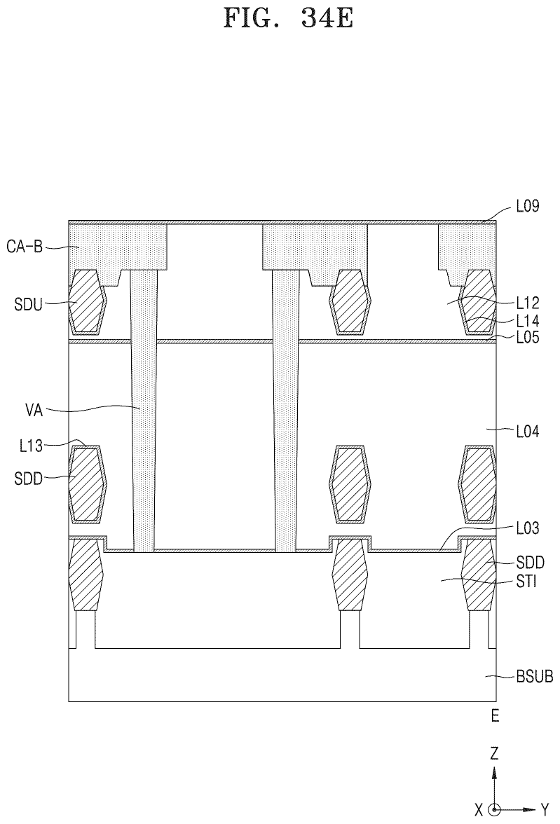

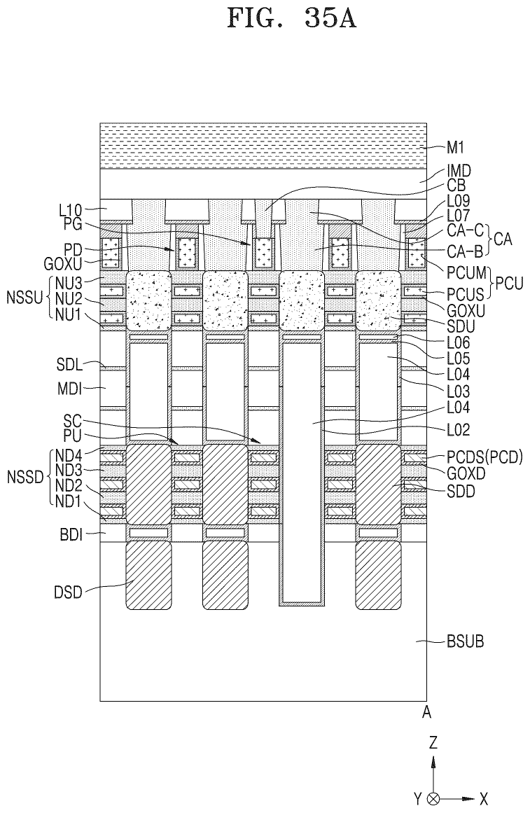

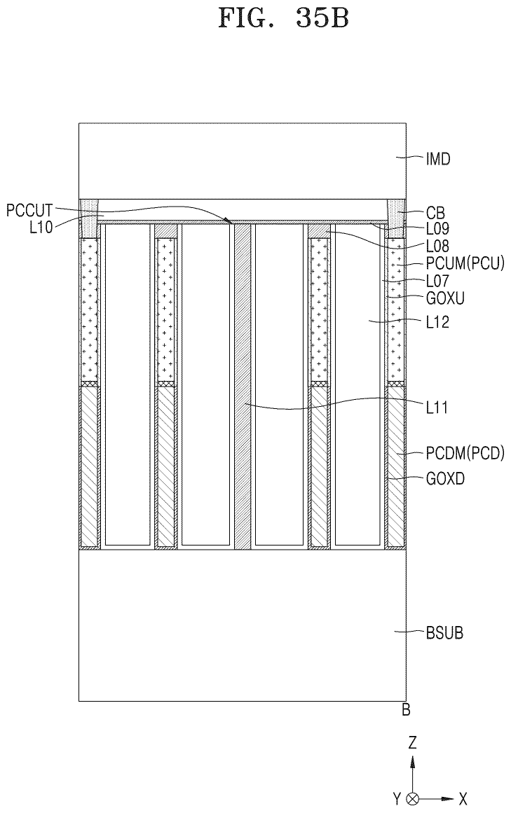

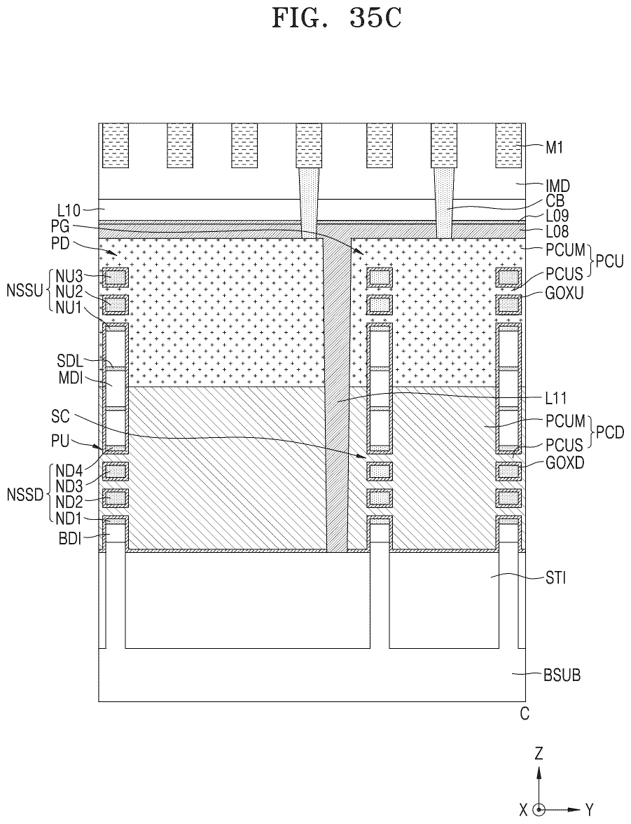

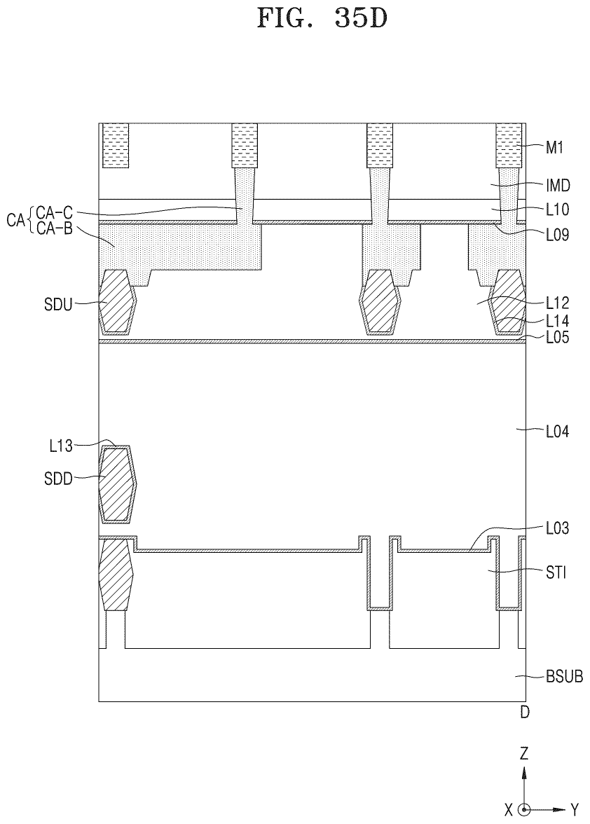

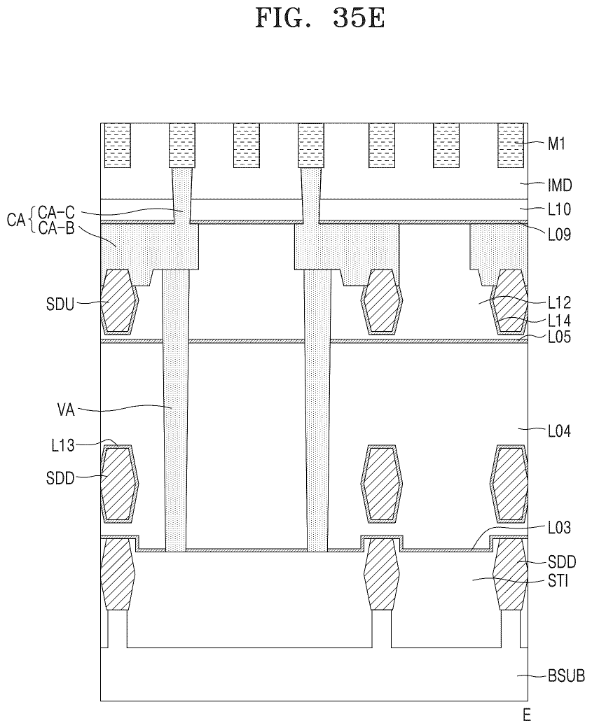

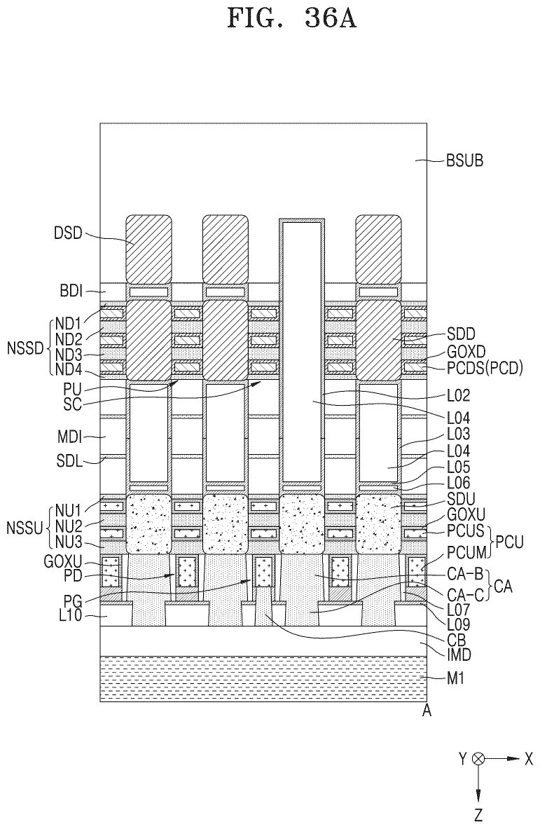

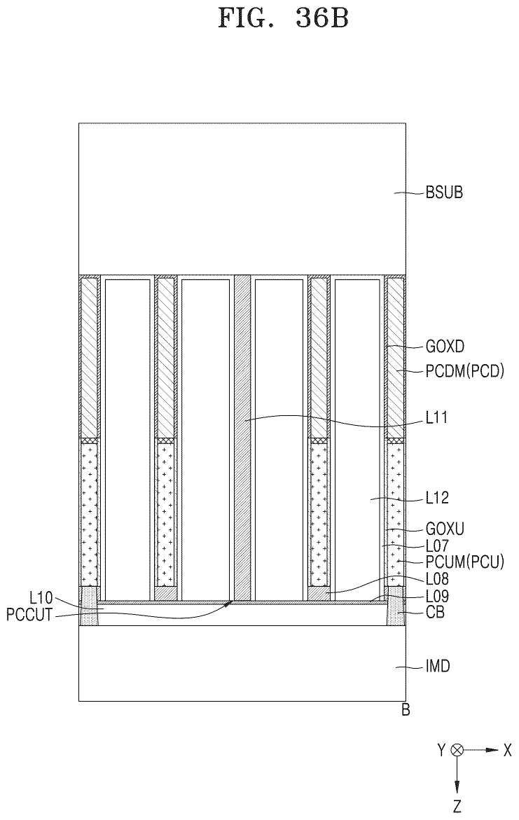

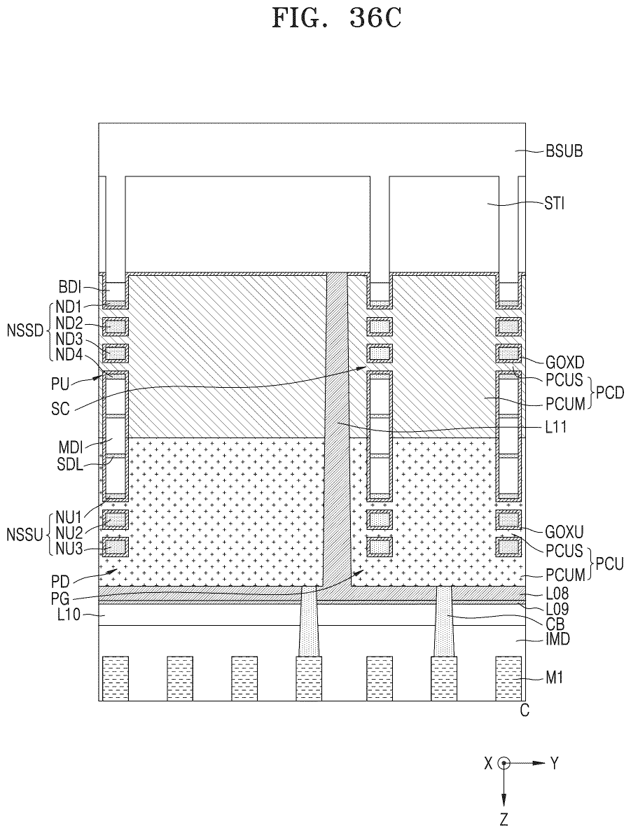

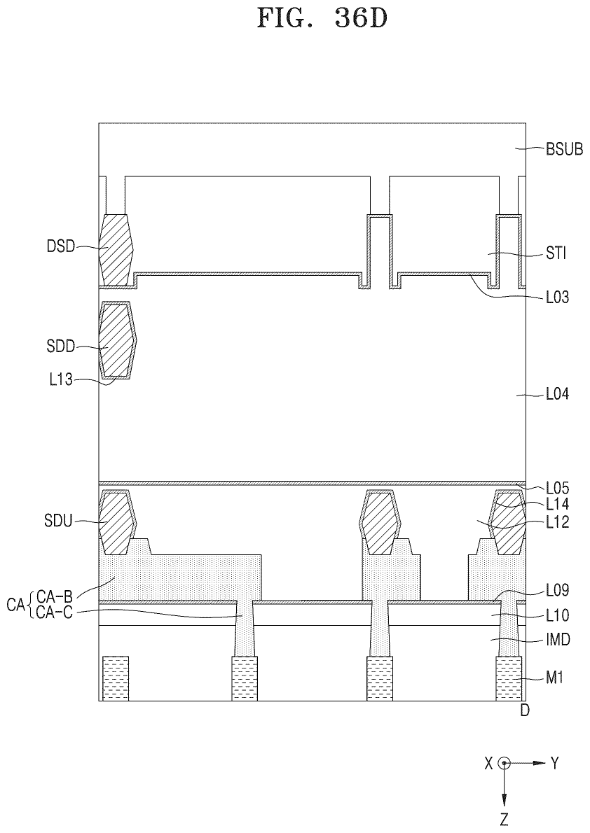

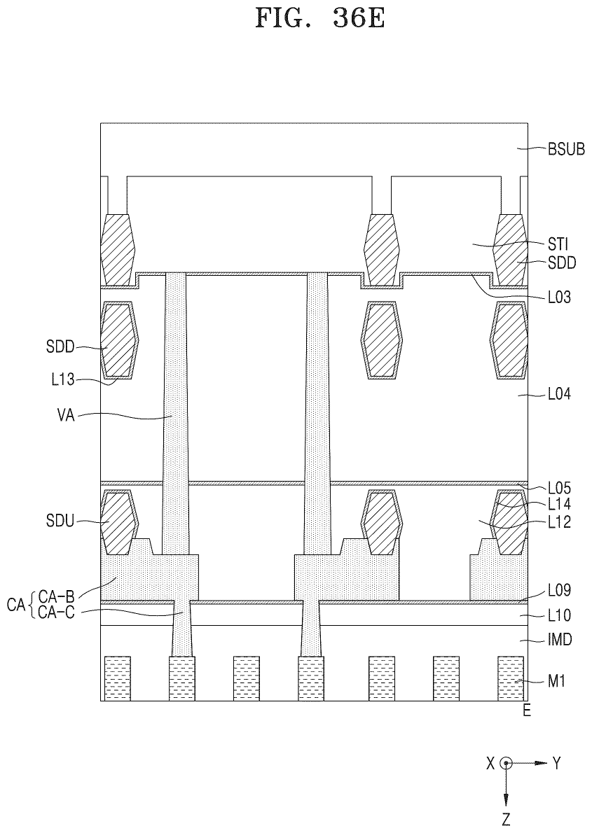

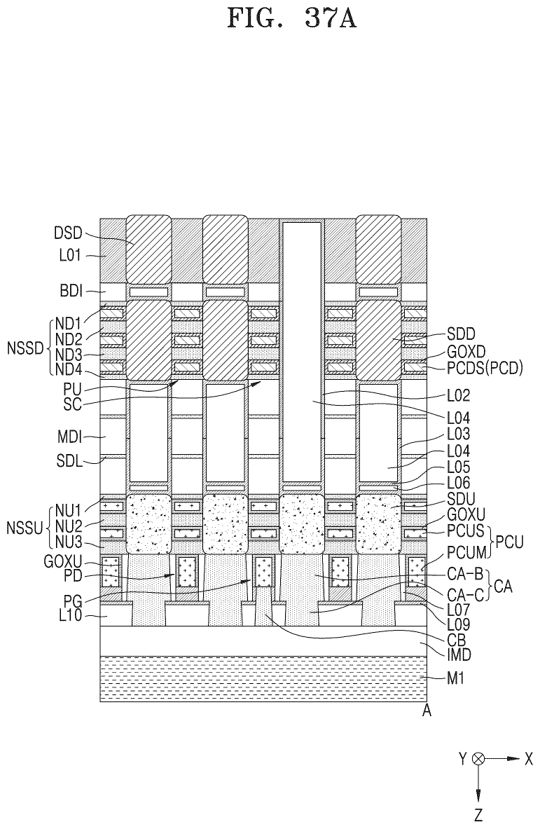

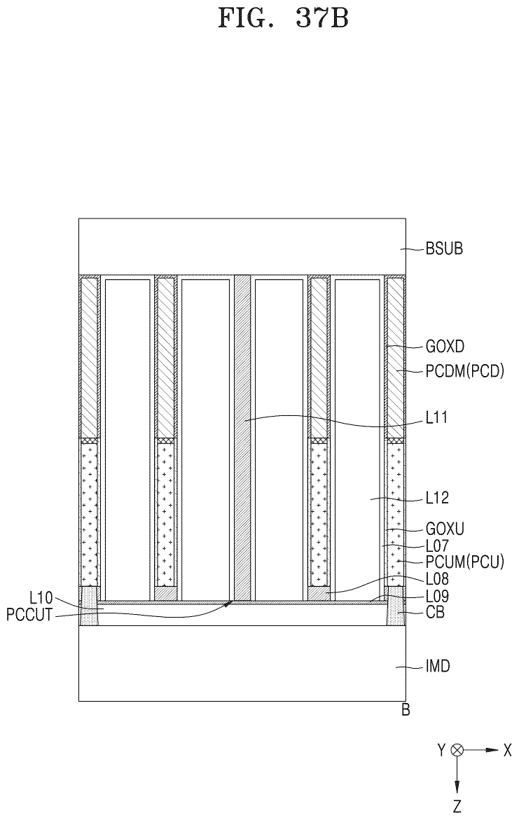

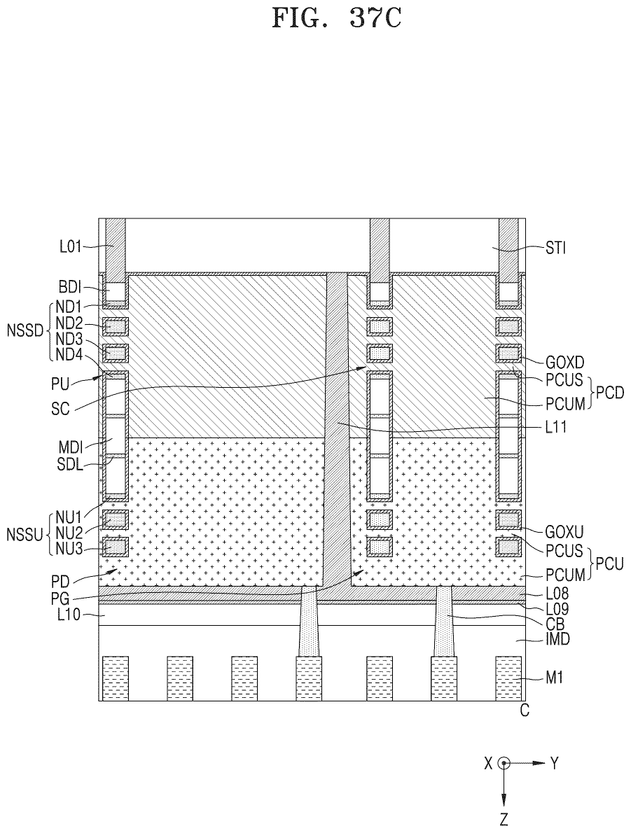

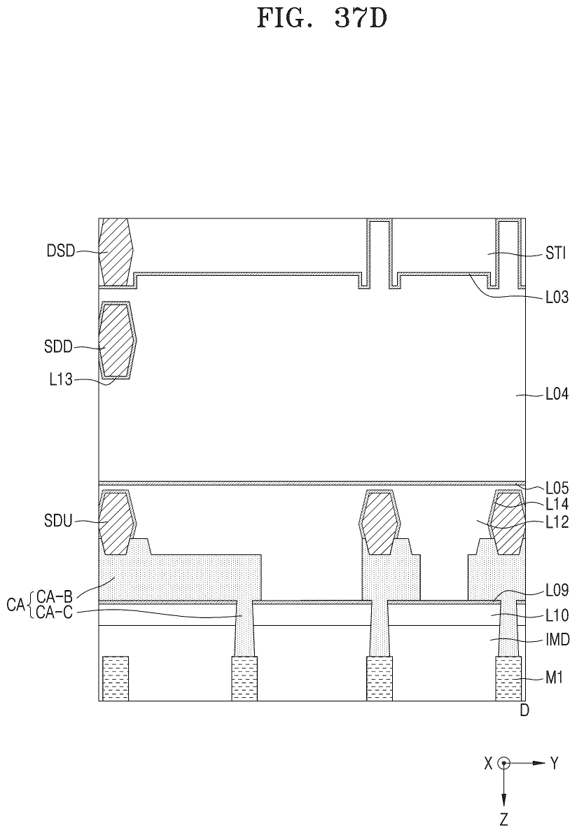

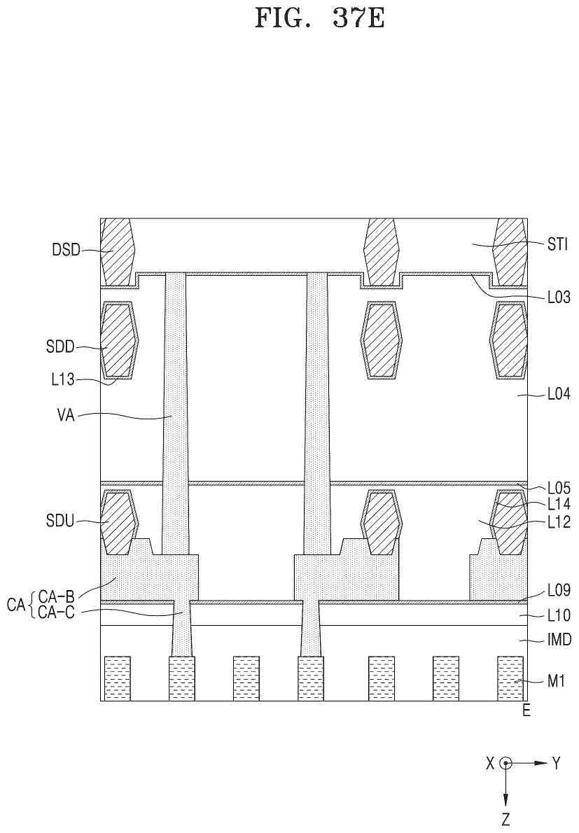

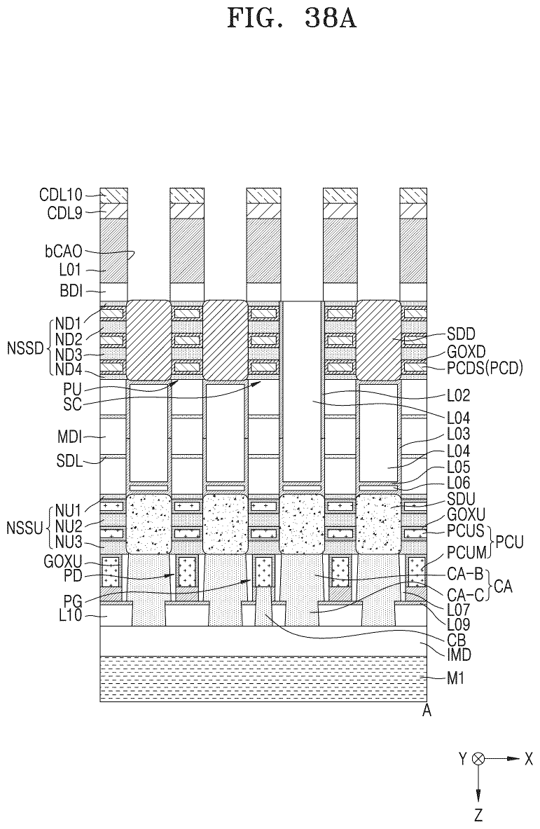

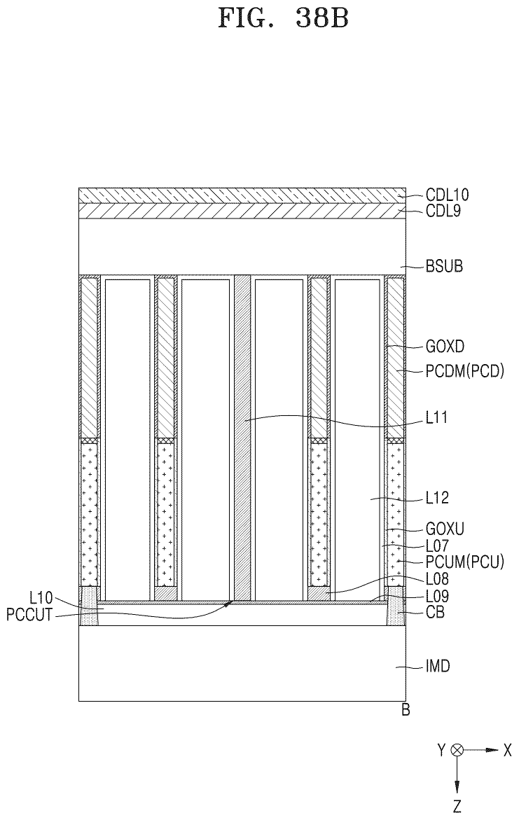

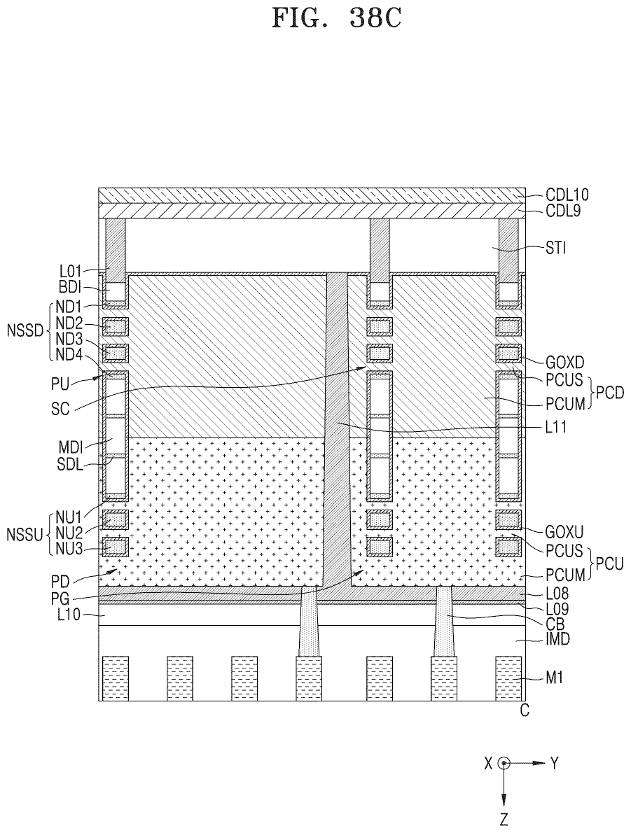

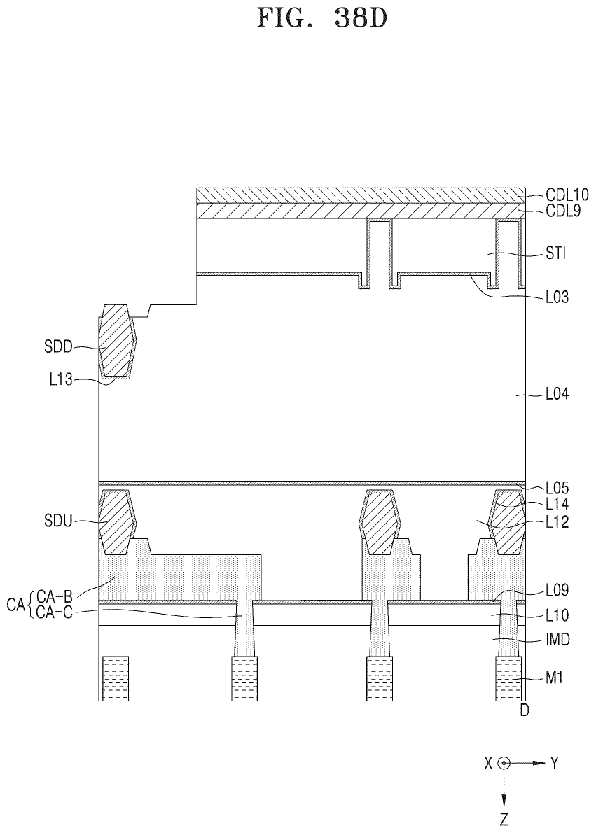

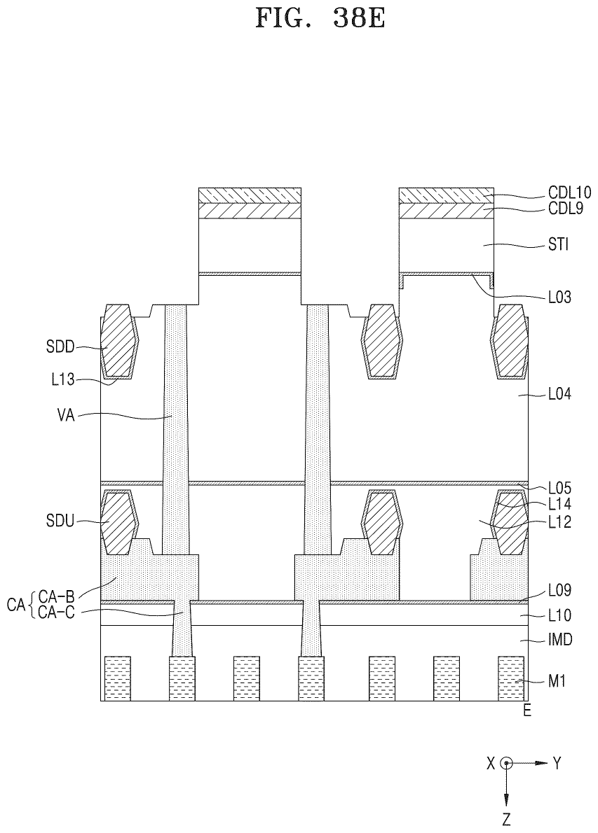

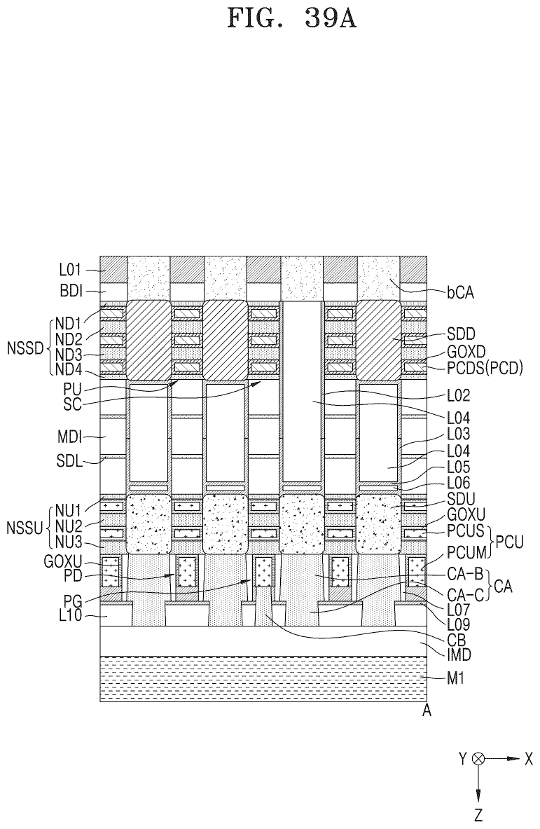

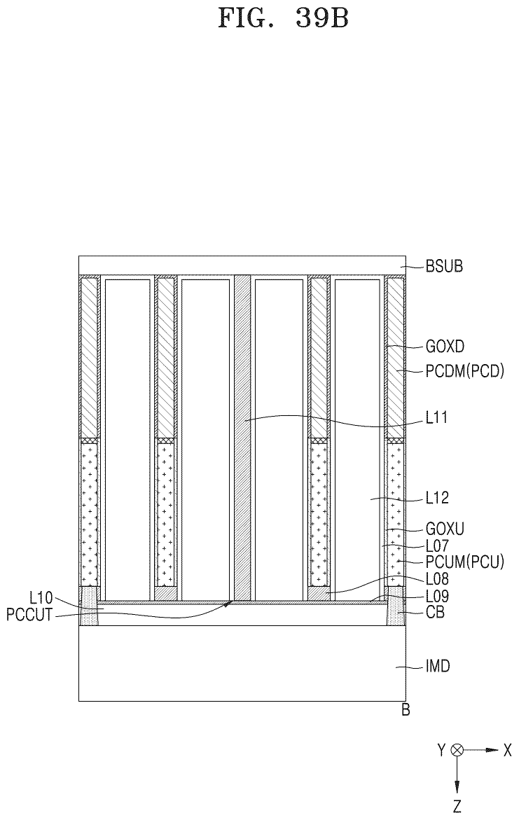

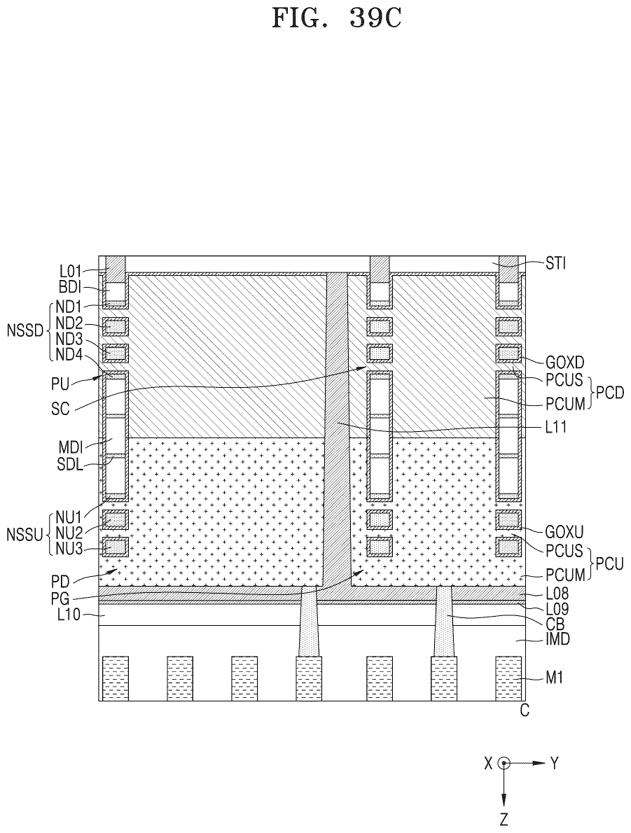

FIGS. 19A to 19E show schematic layouts of an example of a stacked integrated circuit device 4a. Referring to FIGS. 19A to 19E, in the stacked integrated circuit device 4a, a lower via contact bVA may be connected to a lower contact bCA connected to the ground VSS. A plurality of first upper wires M1 in the third layer LY3 and a plurality of second upper wires M2 in the fourth layer LY4 may not include a ground VSS. The stacked integrated circuit device 4a may include a plurality of first lower wires M1B in the zeroth layer LY0 that is lower than the first layer LY1. The first lower wires M1B may extend in the first horizontal direction (the X direction). Each of the first lower wires M1B may correspond to the ground VSS and may be connected to the lower via contact bVA.

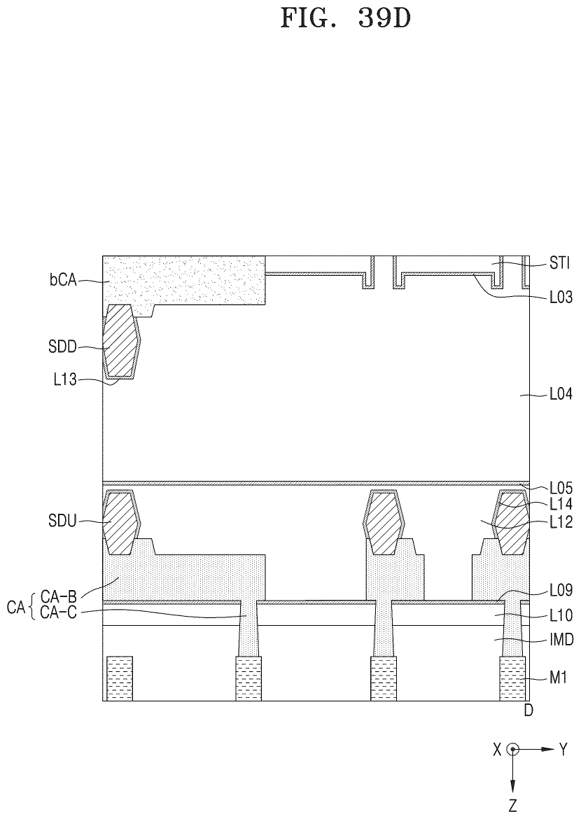

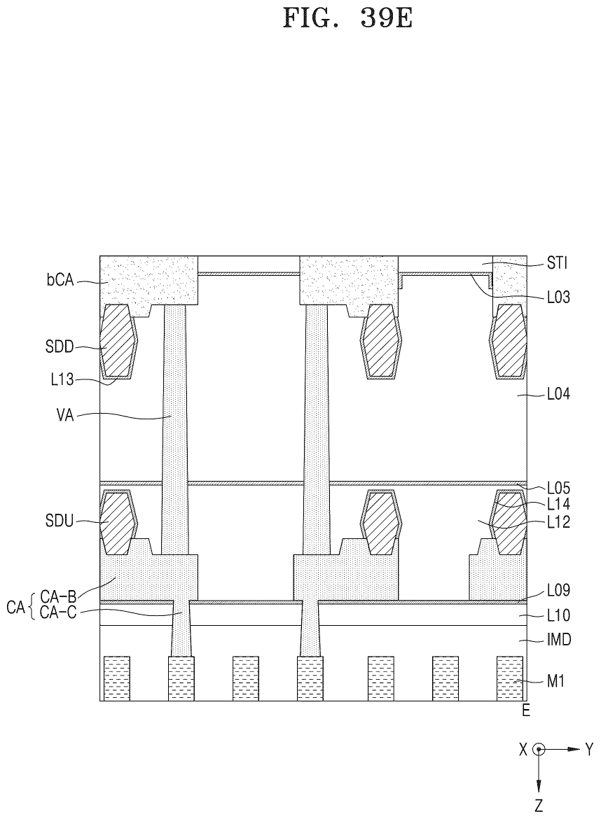

FIG. 20, FIGS. 21A and 21B, FIGS. 22A to 22D, FIGS. 23A to 23D, FIGS. 24A to 24D, FIGS. 25A to 25D, FIGS. 26A to 26D, FIGS. 27A to 27D, FIGS. 28A to 28D, FIGS. 29A to 29D, FIGS. 30A to 30D, FIGS. 31A to 31D, FIGS. 32A to 32E, FIGS. 33A to 33E, FIGS. 34A to 34E, FIGS. 35A to 35E, FIGS. 36A to 36E, FIGS. 37A to 37E, FIGS. 38A to 38E, and FIGS. 39A to 39E are cross-sectional views of stages in a method of manufacturing a stacked integrated circuit device, In detail, FIGS. 20A, 21A, 22A, 23A, 24A, 25A, 26A, 27A, 28A, 29A, 30A, 31A, 32A, 33A, 34A, 35A, 36A, 37A, 38A, and 39A are respectively cross-sectional views taken along at least a part of the line A-A in FIGS. 4A to 4D. FIGS. 22B, 23B, 24B, 25B, 26B, 27B, 28B, 29B, 30B, 31B, 32B, 33B, 34B, 35B, 36B, 37B, 38B, and 39B are respectively cross-sectional views taken along at least a part of the line B-B in FIGS. 4A to 4D. FIGS. 21B, 22C, 23C, 24C, 25C, 26C, 27C, 28C, 29C, 30C, 31C, 32C, 33C, 34C, 35C, 36C, 37C, 38C, and 39C are respectively cross-sectional views taken along at least a part of the line C-C in FIGS. 4A to 4D. FIGS. 22D, 23D, 24D, 25D, 26D, 27D, 28D, 29D, 30D, 31D, 32D, 33D, 34D, 35D, 36D, 37D, 38D, and 39D are respectively cross-sectional views taken along at least a part of the line D-D in FIGS. 4A to 4D. FIGS. 32E, 33E, 34E, 35E, 36E, 37E, 38E, and 39E are respectively cross-sectional views taken along at least a part of the line E-E in FIGS. 4A to 4D.

Referring to FIG. 20, after a base sacrificial layer BSL is formed on a base substrate layer BSUB, a plurality of lower nanosheet semiconductor layers NSD1, NSD2, NSD3, and NSD4 and a plurality of lower sacrificial layers SLD may be alternately stacked on the base sacrificial layer BSL. After a middle sacrificial layer MSL is formed on a stack of the lower nanosheet semiconductor layers NSD1, NSD2, NSD3, and NSD4 and the lower sacrificial layers SLD, a plurality of upper nanosheet semiconductor layers NSU1, NSU2, and NSU3 and a plurality of upper sacrificial layers SLU may be alternately stacked on the middle sacrificial layer MSL. In some implementations, the number of lower nanosheet semiconductor layers NSD1, NSD2, NSD3, and NSD4 may be different from the number of upper nanosheet semiconductor layers NSU1, NSU2, and NSU3. For example, among the lower nanosheet semiconductor layers NSD1, NSD2, NSD3, and NSD4 and the upper nanosheet semiconductor layers NSU1, NSU2, and NSU3, the number of nanosheet semiconductor layers constituting a PMOS transistor may be greater than the number of nanosheet semiconductor layers constituting an NMOS transistor.

In some implementations, the lower nanosheet semiconductor layers NSD1, NSD2, NSD3, and NSD4 and the upper nanosheet semiconductor layers NSU1, NSU2, and NSU3 may include the same material as the base substrate layer BSUB or of a material that has a similar etching characteristic to the base substrate layer BSUB. In some implementations, the lower sacrificial layers SLD may include the same material as the upper sacrificial layers SLU or of a material that has a similar etching characteristic to the upper sacrificial layers SLU. In some implementations, the base sacrificial layer BSL may include the same material as the middle sacrificial layer MSL or of a material that has a similar etching characteristic to the middle sacrificial layer MSL. The base sacrificial layer BSL, the middle sacrificial layer MSL, the lower sacrificial layers SLD, and the upper sacrificial layers SLU may include a material that has an etch selectivity with respect to the lower nanosheet semiconductor layers NSD1, NSD2, NSD3, and NSD4 and the upper nanosheet semiconductor layers NSU1, NSU2, and NSU3. The base sacrificial layer BSL and the middle sacrificial layer MSL may include a material that has an etch selectivity with respect to the lower sacrificial layers SLD and the upper sacrificial layers SLU.

In some implementations, a plurality of middle sacrificial layers MSL may be stacked, and a slit semiconductor sheet SDS may be between the middle sacrificial layers MSL.

Referring to FIGS. 21A and 21B, after a plurality of first hardmask patterns HMK1 are formed on the upper nanosheet semiconductor layers NSU1, NSU2, and NSU3, a stack structure of the base sacrificial layer BSL, the lower nanosheet semiconductor layers NSD1, NSD2, NSD3, and NSD4, the lower sacrificial layers SLD, the middle sacrificial layer MSL, the upper sacrificial layers SLU, and the upper nanosheet semiconductor layers NSU1, NSU2, and NSU3 may be patterned by using the first hardmask patterns HMK1 as etch masks, and a portion of the base substrate layer BSUB exposed between the patterned results may also be removed. The first hardmask patterns HMK1 may extend in the first horizontal direction (the X direction) and may be separated from each other in the second horizontal direction (the Y direction). Thereafter, the first hardmask patterns HMK1 may be removed.

Referring to FIGS. 22A to 22D, after an isolation film STI is formed to fill at least a portion of a space created by removing the portion of the base substrate layer BSUB in FIGS. 21A and 21B, a first material layer CDL1 may be formed to cover the surface of the isolation film STI and the surfaces of the patterned results in FIG. 21B. Thereafter, a preliminary conductive layer DPCL may be formed to cover the first material layer CDL1. The preliminary conductive layer DPCL may be formed to completely fill the space between the patterned results in FIGS. 21A and 21B. In some implementations, the first material layer CDL1 may include oxide and the preliminary conductive layer DPCL may include polysilicon.

Referring to FIGS. 22A to 22D and 23A to 23D, a plurality of second hardmask patterns HMK2 may be formed on the preliminary conductive layer DPCL. Thereafter, conductive patterns DPCP may be formed by patterning the preliminary conductive layer DPCL by using the second hard mask patterns HMK2 as etch masks. The second hard mask patterns HMK2 may extend in the second horizontal direction (the Y direction) and may be separated from each other in the first horizontal direction (the X direction).

Referring to FIGS. 23A to 23D and 24A to 24D, a base-removed space BRS and a middle-removed space MRS may be formed by removing the base sacrificial layer BSL and the middle sacrificial layer MSL.

Referring to FIGS. 24A to 24D and 25A to 25D, a lower insulating structure BDI may be formed to fill the base-removed space BRS and a middle insulating structure MDI may be formed to fill the middle-removed space MRS. Thereafter, a second material layer CDL2 and a third material layer CDL3 may be sequentially formed to conformally cover the resultant structure including the lower insulating structure BDI and the middle insulating structure MDI. In some implementations, the second material layer CDL2 may include oxide and the third material layer CDL3 may include nitride.

Referring to FIGS. 25A to 25D and 26A to 26D, after the third material layer CDL3 is removed, the second material layer CDL2 may be anisotropically etched. Thereafter, a plurality of lower nanosheet stack structures NSSD each including a plurality of lower nanosheets ND1, ND2, ND3, and ND4 and a plurality of upper nanosheet stack structures NSSU each including a plurality of upper nanosheets NU1, NU2, and NU3 may be formed by patterning the upper nanosheet semiconductor layers NSU1, NSU2, and NSU3, the upper sacrificial layers SLU, the middle insulating structure MDI, the lower nanosheet semiconductor layers NSD1, NSD2, NSD3, and NSD4, and the lower sacrificial layers SLD. A portion of the base substrate layer BSUB may also be removed.

Thereafter, a fourth material layer CDL4 may be formed to cover a portion of the top surface of the isolation film STI, a portion of the surface of the base substrate layer BSUB, a side surface of a portion of each of some lower nanosheet stack structures NSSD, and a portion of the side surface of the middle insulating structure MDI. A fifth material layer CDL5 may be formed to cover the surface of the resultant structure of FIGS. 25A to 25D, which is exposed at a higher vertical level than the topmost end of the fourth material layer CDL4. The fifth material layer CDL5 may cover a side surface of a portion of each of the other lower nanosheet stack structures NSSD, a side surface of a lower portion of the conductive pattern DPCP, and a portion of the surface of the base substrate layer BSUB. In some implementations, the fourth material layer CDL4 may include nitride and the fifth material layer CDL5 may include nitride.

Referring to FIGS. 27A to 27D, a lower source/drain region SDD and a dummy source/drain region DSD may be formed by performing epitaxial growth on portions of the lower nanosheet stack structures NSSD and the base substrate layer BSUB, which are not covered with the fifth material layer CDL5. Thereafter, a sixth material layer CDL6 may be formed to cover the surface of the resultant structure including the lower source/drain region SDD and the dummy source/drain region DSD. In some implementations, the sixth material layer CDL6 may include nitride.

Referring to FIGS. 28A to 28D, the fifth material layer CDL5 and the sixth material layer CDL6 may be partially removed such that the residue of the fifth material layer CDL5 may form a second insulating layer L02 and the residue of the sixth material layer CDL6 may form a third insulating layer L03 and a thirteenth insulating layer L13. Thereafter, a fourth insulating layer L04 may be formed to fill the space defined by the second insulating layer L02 and the third insulating layer L03, a fifth insulating layer L05 may be formed on the fourth insulating layer L04, and a sixth insulating layer L06 may be formed to fill the space defined by the fifth insulating layer L05.

Thereafter, an upper source/drain region SDU may be formed by performing epitaxial growth on the upper nanosheet stack structures NSSU. A fourteenth insulating layer L14 may be formed to cover the surface of the upper source/drain region SDU. A twelfth insulating layer L12 may be formed to fill between the conductive patterns DPCP.

Referring to FIGS. 28A to 28D and 29A to 29D, an upper portion of the resultant structure of FIGS. 28A to 28D may be removed such that all of the second hardmask patterns HMK2 are removed. Thereafter, a portion of the conductive pattern DPCP may be removed and then filled with an eleventh insulating layer L11. Thereafter, a portion of the twelfth insulating layer L12 may be removed and then filled with a seventh material layers CDL7. In some implementations, the seventh material layer CDL7 may include nitride.

Referring to FIGS. 29A to 29D and 30A to 30D, a gate-removed space GRS may be formed by removing the conductive pattern DPCP.

Referring to FIGS. 30A to 30D and 31A to 31D, a lower gate insulating film GOXD, a lower gate electrode PCD, an upper gate insulating film GOXU, and an upper gate electrode PCU may be formed in the gate-removed space GRS.

Referring to FIGS. 31A to 31D and 32A to 32E, a portion of the upper gate electrode PCU may be removed and then filled with an eighth insulating layer L08. Thereafter, a tenth insulating layer L10 and a ninth material layer CDL9 may be formed and a via hole VH may be formed to pass through the ninth material layer CDL9, the tenth insulating layer L10, the seventh material layer CDL7, the twelfth insulating layer L12, the fifth insulating layer L05, the fourth insulating layer L04, and the third insulating layer L03 and expose the isolation film STI on the bottom thereof.

Referring to FIGS. 32A to 32E and 33A to 33E, at least a portion of each of the ninth material layer CDL9, the tenth insulating layer L10, the seventh material layer CDL7, and the twelfth insulating layer L12 may be removed so that an upper contact hole CAO may be formed to expose the upper source/drain region SDU.

Referring to FIGS. 33A to 33E and 34A to 34E, a base part CA-B may be formed to fill the upper contact hole CAO and a via contact VA may be formed to fill the via hole VH. Thereafter, an upper portion of the resultant structure including the base part CA-B and the via contact VA may be removed to expose the twelfth insulating layer L12 and the eighth insulating layer L08, and then a ninth insulating layer L09 may be formed.

Referring to FIGS. 35A to 35E, an inter-wire insulating layer IMD may be formed to cover the resultant structure of FIGS. 34A to 34E. Thereafter, a contact part CA-C connected to the base part CA-B, a gate contact CB connected to the upper gate electrode PCU, and a first upper wire M1 connected to the contact part CA-C and the gate contact CB may be formed. The inter-wire insulating layer IMD may surround the contact part CA-C, the gate contact CB, and the first upper wire M1.

Referring to FIGS. 36A to 36E, the resultant structure of FIGS. 35A to 35E may be turned upside down so that the base substrate layer BSUB is in the upper portion of the resultant structure.

Referring to FIGS. 37A to 37E, the base substrate layer BSUB may be partially removed to expose the dummy source/drain region DSD and the isolation film STI. Thereafter, a first insulating layer L01 may be formed to surround the dummy source/drain region DSD. The respective top surfaces of the dummy source/drain region DSD, the first insulating layer L01, and the isolation film STI may be at the same vertical level as one another.

Referring to FIGS. 37A to 37E and FIGS. 38A to 38E, a ninth material layer CDL9 and a tenth material layer CDL10 may be sequentially formed to cover the resultant structure of FIGS. 37A to 37E. Thereafter, the ninth material layer CDL9 and the tenth material layer CDL10 may be partially removed to expose the dummy source/drain region DSD, and a lower contact hole bCAO may be formed to expose the lower source/drain region SDD by removing the dummy source/drain region DSD.

Referring to FIGS. 38A to 38E and FIGS. 39A to 39E, the lower contact hole bCAO may be filled with a conductive material and the tenth material layer CDL10 and the ninth material layer CDL9 may be removed to expose the first insulating layer L01 and the base substrate layer BSUB. Respective upper portions of the first insulating layer L01, the base substrate layer BSUB, the isolation film STI, and the conductive material may be removed so that the residue of the conductive material forms a lower contact bCA.

Thereafter, the resultant structure of FIGS. 39A to 39E may be turned upside down, thereby forming the stacked integrated circuit device 1 of FIGS. 4A to 4E.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While this disclosure has been particularly shown and described with reference to embodiments thereof, it will be understood that various changes in form and details may be made therein without departing from the spirit and scope of the following claims.

What is claimed is:

1. A stacked integrated circuit device comprising:
a plurality of transistors including a pair of pull-up transistors in a first layer, a pair of pull-down transistors in a second layer that is at a different vertical level than the first layer, and a pair of pass-gate transistors in one of the first layer and the second layer;
a source/drain contact configured to electrically connect a source/drain region of a first pull-up transistor of the pair of pull-up transistors, a source/drain region of a first pull-down transistor of the pair of pull-down transistors, and a source/drain region of a first pass-gate transistor of the pair of pass-gate transistors to one another;
a gate contact configured to connect a gate electrode of a second pull-up transistor of the pair of pull-up transistors to a gate electrode of a second pull-down transistor of the pair of pull-down transistors; and
an upper wire on the source/drain contact and the gate contact, the upper wire extending in a first horizontal direction and connected to the source/drain contact and the gate contact.

2. The stacked integrated circuit device of claim 1, further comprising a plurality of gate electrodes constituting respective gate electrodes of the plurality of transistors and extending in a second horizontal direction that is orthogonal to the first horizontal direction.

3. The stacked integrated circuit device of claim 2, wherein at least some of the plurality of gate electrodes are divided into two parts by a plurality of gate cut regions, respectively, and
the plurality of gate cut regions are arranged in a zigzag form in the first horizontal direction.

4. The stacked integrated circuit device of claim 1, wherein the pair of pass-gate transistors are in the second layer.

5. The stacked integrated circuit device of claim 4, wherein each of the pair of pull-up transistors comprises a p-type metal-oxide semiconductor (PMOS) transistor, and
each of the pair of pull-down transistors and the pair of pass-gate transistors comprises an n-type MOS (NMOS) transistor.

6. The stacked integrated circuit device of claim 1, wherein the pair of pass-gate transistors are in the first layer.

7. The stacked integrated circuit device of claim 6, wherein each of the pair of pull-down transistors and the pair of pass-gate transistors comprises a p-type metal-oxide semiconductor (PMOS) transistor, and
each of the pair of pull-up transistors comprises an n-type MOS (NMOS) transistor.

8. The stacked integrated circuit device of claim 1, wherein the second layer is at a higher vertical level than the first layer.

9. The stacked integrated circuit device of claim 1, wherein the first layer is at a higher vertical level than the second layer.

10. The stacked integrated circuit device of claim 1, wherein the pair of pull-up transistors respectively overlap with the pair of pull-down transistors in a vertical direction.

11. A stacked integrated circuit device comprising:
a plurality of nanosheets extending in a first horizontal direction;
a plurality of gate electrodes extending in a second horizontal direction that is orthogonal to the first horizontal direction;
a plurality of transistors respectively formed at intersections between the plurality of nanosheets and the plurality of gate electrodes, the plurality of transistors including
a pair of first transistors in a first layer, a pair of second transistors in a second layer that is at a higher vertical level than the first layer, and
a pair of third transistors in one of the first layer and the second layer;
a plurality of lower contacts connected to respective source/drain regions of transistors in the first layer among the plurality of transistors;
a plurality of upper contacts connected to respective source/drain regions of transistors in the second layer among the plurality of transistors;
a plurality of gate contacts connected to the plurality of gate electrodes;
a plurality of via contacts configured to connect the plurality of lower contacts to the plurality of upper contacts overlapping with the plurality of lower contacts in a vertical direction; and
a plurality of upper wires connected to the plurality of upper contacts and the plurality of gate contacts,
wherein a source/drain region of one first transistor of the pair of first transistors is connected to a lower contact among the plurality of lower contacts, a source/drain region of one second transistor of the pair of second transistors is connected to an upper contact among the plurality of upper contacts, a source/drain region of one third transistor of the pair of third transistors is connected to either the lower contact or the upper contact, the lower contact and the upper contact are electrically connected to each other by a via contact among the plurality of via contacts,
wherein portions of a gate electrode among the plurality of gate electrodes form a gate electrode of the other first transistor of the pair of first transistors and a gate electrode of the other second transistor of the pair of second transistors and are connected to a single gate contact among the plurality of gate contacts, and
the upper contact and the single gate contact are connected to an upper wire among the plurality of upper wires.

12. The stacked integrated circuit device of claim 11, wherein the plurality of upper wires extend in the first horizontal direction.

13. The stacked integrated circuit device of claim 11, wherein the plurality of upper wires is in a third layer that is at a higher vertical level than the second layer.

14. The stacked integrated circuit device of claim 11, wherein each of the plurality of nanosheets includes:
a lower nanosheet stack structure including a plurality of lower nanosheets forming each of the transistors in the first layer among the plurality of transistors; and
an upper nanosheet stack structure including a plurality of upper nanosheets forming each of the transistors in the second layer among the plurality of transistors, and
a total number of lower nanosheets included in the lower nanosheet stack structure is different from a total number of upper nanosheets included in the upper nanosheet stack structure.

15. The stacked integrated circuit device of claim 14, wherein the number of lower nanosheets included in the lower nanosheet stack structure is greater than the number of upper nanosheets included in the upper nanosheet stack structure,
each of the transistors in the first layer among the plurality of transistors comprises a p-type metal-oxide semiconductor (PMOS) transistor, and
each of the transistors in the second layer among the plurality of transistors comprises an n-type MOS (NMOS) transistor.

16. The stacked integrated circuit device of claim 11, wherein at least some of the plurality of transistors form static random access memory (SRAM),
each of the pair of first transistors comprises a pull-up transistor, each of the pair of second transistors comprises a pull-down transistor, and each of the pair of third transistors comprises a pass-gate transistor.

17. The stacked integrated circuit device of claim 16, wherein the pair of third transistors are in the first layer.

18. A stacked integrated circuit device comprising:
a plurality of nanosheets extending in a first horizontal direction;
a plurality of gate electrodes extending in a second horizontal direction that is orthogonal to the first horizontal direction;
a plurality of transistors respectively formed at intersections between the plurality of nanosheets and the plurality of gate electrodes, the plurality of transistors including
a pair of pull-up transistors in a first layer,
a pair of pull-down transistors in a second layer that is at a higher vertical level than the first layer, and
a pair of pass-gate transistors in the second layer, and some of the plurality of transistors forming static random access memory (SRAM);
a plurality of lower contacts connected to respective source/drain regions of the pair of pull-up transistors;
a plurality of upper contacts connected to respective source/drain regions of the pair of pull-down transistors and the pair of pass-gate transistors;
a plurality of gate contacts connected to the plurality of gate electrodes;
a plurality of via contacts configured to connect a first lower contact among the plurality of lower contacts to a first upper contact among the plurality of upper contacts, the first lower contact overlapping with the first upper contact in a vertical direction; and
a plurality of upper wires connected to the plurality of upper contacts and the plurality of gate contacts, the plurality of upper wires extending in the first horizontal direction and being in a third layer that is at a higher vertical level than the second layer,
wherein a source/drain region of a first pull-up transistor of the pair of pull-up transistors is connected to a lower contact among the plurality of lower contacts, a source/drain region of a first pull-down transistor of the pair of pull-down transistors and a source/drain region of a first pass-gate transistor of the pair of pass-gate transistors are connected to an upper contact among the plurality of upper contacts, the lower contact and the upper contact are electrically connected to each other by a via contact among the plurality of via contacts,
wherein portions of a gate electrode among the plurality of gate electrodes form a gate electrode of a second pull-up transistor of the pair of pull-up transistors and a gate electrode of a second pull-down transistor of the pair of pull-down transistors, and are connected to a single gate contact among the plurality of gate contacts, and
the upper contact and the single gate contact are connected to an upper wire among the plurality of upper wires.

19. The stacked integrated circuit device of claim 18, wherein each pull-up transistors of the pair of pull-up transistors comprises a p-type metal-oxide semiconductor (PMOS) transistor,
each pull-down transistor of the pair of pull-down transistors and each pass-gate transistor of the pair of pass-gate transistors comprises an n-type MOS (NMOS) transistor, and
the pair of pull-up transistors respectively overlap with the pair of pull-down transistors in the vertical direction.

20. The stacked integrated circuit device of claim 18, wherein at least some of the plurality of gate electrodes are divided into two parts by a plurality of gate cut regions, respectively, and
the plurality of gate cut regions are arranged in a zigzag form in the first horizontal direction and in line in the second horizontal direction.
